(19) United States
(12) Patent Application Publication
(10) Pub. No.: US 2015/0340621 A1
(43) Pub. Date: Nov. 26, 2015

(54) ORGANIC ELECTROLUMINESCENT DEVICE

(71) Applicant: MERCK PATENT GMBH, Darmstadt (DE)

(72) Inventors: Amir Hossain PARHAM, Frankfurt Am Main (DE); Christof PFLUMM, Darmstadt (DE); Anja JATSCH, Frankfurt Am Main (DE); Thomas EBERLE, Landau (DE); Philipp STOESSEL, Frankfurt Am Main (DE); Jonas Valentin KROEBER, Frankfurt Am Main (DE); Joachim KAISER, Darmstadt (DE)

(73) Assignee: MERCK PATENT GMBH, Darmstadt (DE)

(21) Appl. No.: 14/653,343

(22) PCT Filed: Nov. 27, 2013
(86) PCT No.: PCT/EP2013/003584

§ 371 Date: Jun. 18, 2015

(30) Foreign Application Priority Data
Dec. 18, 2012 (EP) 12008419.9

(51) Int. Cl. H01L 51/00; C09K 11/02

(52) U.S. Cl. CPC H01L 51/0067; C09K 11/025; H01L 51/0072; H01L 51/0073; H01L 51/0074; H01L 51/5072

(57) ABSTRACT

The present invention relates to organic electroluminescent devices which comprise mixtures of at least two electron-conducting materials, in particular as matrix for phosphorescent emitters.

The present invention relates to organic electroluminescent devices which comprise mixtures of at least two electron-conducting materials, in particular as matrix for phosphorescent emitters.

The structure of organic electroluminescent devices (OLEDs) in which organic semiconductors are employed as functional materials is described, for example, in U.S. Pat. No. 4,539,507, U.S. Pat. No. 5,151,629, EP 0676461 and WO 98/27136. The emitting materials employed here are increasingly organometallic complexes which exhibit phosphorescence instead of fluorescence (M. A. Baldo et al., Appl. Phys. Lett 1999, 75, 4-6). For quantum-mechanical reasons, an up to four-fold increase in the energy and power efficiency is possible using organometallic compounds as phosphorescence emitters. In general, however, there is still a need for improvement in OLEDs, in particular also in OLEDs which exhibit triplet emission (phosphorescence), for example with respect to efficiency, operating voltage and lifetime. This applies, in particular, to OLEDs which emit in the relatively short-wave region, for example green.

The properties of phosphorescent OLEDs are not determined only by the triplet emitters employed. The other materials used, in particular also the matrix materials, are also of particular importance here. Improvements in these materials can thus also result in significant improvements in the OLED properties.

In accordance with the prior art, not only single materials, but also mixtures of two or more materials, are used as matrix for phosphorescent emitters. The mixtures here generally comprise either a hole-transporting matrix material and an electron-transporting matrix material, as described, for example, in WO 2002/047457, or they comprise a charge-transporting matrix material and a further matrix material which, due to a large band gap, does not participate in charge transport, or only does so to an insignificant extent, as described, for example, in WO 2010/108579.

Besides further classes of material which can be employed as matrix materials for phosphorescent emitters, lactams are also known as matrix materials, for example in accordance with WO 2011/116865 or WO 2011/137951.

However, improvements are still desirable with the above-mentioned materials and device structures, in particular with respect to the lifetime and the operating voltage.

The object of the present invention is thus the provision of organic electroluminescent devices which have an improved lifetime and/or an improved operating voltage.

Surprisingly, it has been found that organic electroluminescent devices which comprise a mixture of a certain lactam derivative and a further electron-transporting material in a layer, in particular as matrix materials for the phosphorescent emitter, achieve this object and result in significant improvements in the organic electroluminescent device, in particular with respect to the lifetime and the operating voltage. This applies, in particular, to green- to red-phosphorescent electroluminescent devices. The present invention therefore relates to organic electroluminescent devices of this type.

The present invention relates to an organic electroluminescent device comprising cathode, anode and at least one layer which comprises the following compounds:
(A) at least one electron-transporting compound which has an LUMO ≦−2.4 eV; and
(B) at least one compound of the following formula (1) or (1a),

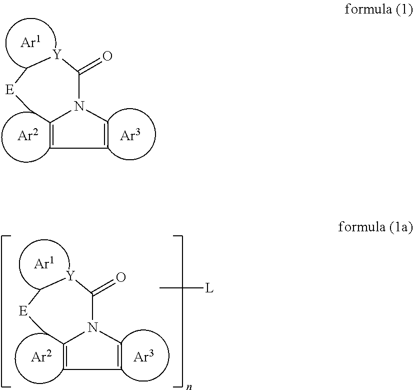

where the following applies to the symbols and indices used
E is a single bond or NAr⁴;
Y is C if Ar¹ represents a 6-membered aryl ring group or 6-membered heteroaryl ring group or is C or N if Ar¹ represents a 5-membered heteroaryl ring group;
Ar¹ is, together with the group Y and the carbon atom explicitly depicted, an aromatic or heteroaromatic ring system having 5 to 30 aromatic ring atoms, which may be substituted by one or more radicals R;
Ar², Ar³ are, identically or differently on each occurrence, together with the carbon atoms explicitly depicted, an aromatic or heteroaromatic ring system having 5 to 30 aromatic ring atoms, which may be substituted by one or more radicals R;
Ar⁴ is an aromatic or heteroaromatic ring system having 5 to 30 aromatic ring atoms, which may be substituted by one or more radicals R; Ar⁴ here may also be linked to Ar² or Ar¹ by a single bond;
L is, for n=2, a single bond or a divalent group or, for n=3, a trivalent group or, for n=4, a tetravalent group, each of which is bonded to Ar¹, Ar², Ar³ or Ar⁴ at any desired position;
R is selected on each occurrence, identically or differently, from the group consisting of H, D, F, Cl, Br, I, CN, NO₂, N(Ar⁵)₂, N(R¹)₂, C(═O)Ar⁵, C(═O)R¹, P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R¹, where one or more non-adjacent CH₂ groups may be replaced by R¹C═CR¹, C≡C, Si(R¹)₂, Ge(R¹)₂, Sn(R¹)₂, C═O, C═S, C═Se, C═NR¹, P(═O)(R¹), SO, SO₂, NR¹, O, S or CONR¹ and where one or more H atoms may be replaced by D, F, Cl, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which may be substituted by one or more radicals R¹, or a combination of these systems, where two or more adjacent substituents R may optionally form a monocyclic or polycyclic, aliphatic, aromatic or heteroaromatic ring system, which may be substituted by one or more radicals R¹;
R¹ is selected on each occurrence, identically or differently, from the group consisting of H, D, F, Cl, Br, I, CN, NO₂, N(Ar⁵)₂, N(R²)₂, C(═O)Ar⁵, C(═O)R², P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which may be substituted by one or more radicals R², where one or more non-adjacent CH₂ groups may be replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms may be replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which may be substituted by one or more radicals R², or a combination of these systems, where two or more adjacent substituents R may optionally form a monocyclic or polycyclic, aliphatic, aromatic or heteroaromatic ring system, which may be substituted by one or more radicals R²;
Ar⁵ is on each occurrence, identically or differently, an aromatic or heteroaromatic ring system having 5-30 aromatic ring atoms, which may be substituted by one or more non-aromatic radicals R²; two radicals Ar⁵ here which are bonded to the same N atom or P atom may also be bridged to one another by a single bond or a bridge selected from N(R²), C(R²)₂ or O;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms may be replaced by D, F, Cl, Br, I or CN, where two or more adjacent substituents R² may form a mono- or polycyclic, aliphatic, aromatic or heteroaromatic ring system with one another;
n is 2, 3 or 4.

6-membered aryl ring group or 6-membered heteroaryl ring group or 5-membered heteroaryl ring group in the definition of Y means that the ring which contains the carbon atom explicitly depicted and the group Y is a ring of this type. Further aromatic or heteroaromatic groups may also be condensed onto this ring.

An aryl group in the sense of this invention contains 6 to 60 C atoms; a heteroaryl group in the sense of this invention contains 2 to 60 C atoms and at least one heteroatom, with the proviso that the sum of C atoms and heteroatoms is at least 5. The heteroatoms are preferably selected from N, O and/or S. An aryl group or heteroaryl group here is taken to mean either a simple aromatic ring, i.e. benzene, or a simple heteroaromatic ring, for example pyridine, pyrimidine, thiophene, etc., or a condensed (fused) aryl or heteroaryl group, for example naphthalene, anthracene, phenanthrene, quinoline, isoquinoline, etc. Aromatic rings linked to one another by a single bond, such as, for example, biphenyl, are, by contrast, not referred to as an aryl or heteroaryl group, but instead as an aromatic ring system.

An aromatic ring system in the sense of this invention contains 6 to 80 C atoms in the ring system. A heteroaromatic ring system in the sense of this invention contains 2 to 60 C atoms and at least one heteroatom in the ring system, with the proviso that the sum of C atoms and heteroatoms is at least 5. The heteroatoms are preferably selected from N, O and/or S. An aromatic or heteroaromatic ring system in the sense of this invention is intended to be taken to mean a system which does not necessarily contain only aryl or heteroaryl groups, but instead in which, in addition, a plurality of aryl or heteroaryl groups may be connected by a non-aromatic unit, such as, for example, a C, N or O atom. Thus, for example, systems such as fluorene, 9,9′-spirobifluorene, 9,9-diarylfluorene, triarylamine, diaryl ether, stilbene, etc., are also intended to be taken to be aromatic ring systems in the sense of this invention, as are systems in which two or more aryl groups are connected, for example, by a short alkyl group.

For the purposes of the present invention, an aliphatic hydrocarbon radical or an alkyl group or an alkenyl or alkynyl group, which may contain 1 to 40 C atoms, and in which, in addition, individual H atoms or CH₂ groups may be substituted by the above-mentioned groups, is preferably taken to mean the radicals methyl, ethyl, n-propyl, i-propyl, n-butyl, i-butyl, s-butyl, t-butyl, 2-methylbutyl, n-pentyl, s-pentyl, neopentyl, cyclopentyl, n-hexyl, neohexyl, cyclohexyl, n-heptyl, cycloheptyl, n-octyl, cyclooctyl, 2-ethylhexyl, trifluoromethyl, pentafluoroethyl, 2,2,2-trifluoroethyl, ethenyl, propenyl, butenyl, pentenyl, cyclopentenyl, hexenyl, cyclohexenyl, heptenyl, cycloheptenyl, octenyl, cyclooctenyl, ethynyl, propynyl, butynyl, pentynyl, hexynyl, heptynyl or octynyl. An alkoxy group having 1 to 40 C atoms is preferably taken to mean methoxy, trifluoromethoxy, ethoxy, n-propoxy, i-propoxy, n-butoxy, i-butoxy, s-butoxy, t-butoxy, n-pentoxy, s-pentoxy, 2-methylbutoxy, n-hexoxy, cyclohexyloxy, n-heptoxy, cycloheptyloxy, n-octyloxy, cyclooctyloxy, 2-ethylhexyloxy, pentafluoroethoxy and 2,2,2-trifluoroethoxy. A thioalkyl group having 1 to 40 C atoms is taken to mean, in particular, methylthio, ethylthio, n-propylthio, i-propylthio, n-butylthio, i-butylthio, s-butylthio, t-butylthio, n-pentylthio, s-pentylthio, n-hexylthio, cyclohexylthio, n-heptylthio, cycloheptylthio, n-octylthio, cyclooctylthio, 2-ethylhexylthio, trifluoromethylthio, pentafluoroethylthio, 2,2,2-trifluoroethylthio, ethenylthio, propenyfthio, butenylthio, pentenylthio, cyclopentenylthio, hexenylthio, cyclohexenylthio, heptenylthio, cycloheptenylthio, octenylthio, cyclooctenylthio, ethynylthio, propynylthio, butynylthio, pentynylthio, hexynyl-thio, heptynylthio or octynylthio. In general, alkyl, alkoxy or thioalkyl groups in accordance with the present invention may be straight-chain, branched or cyclic, where one or more non-adjacent CH₂ groups may be replaced by the above-mentioned groups; furthermore, one or more H atoms may also be replaced by D, F, Cl, Br, I, CN or NO₂, preferably F, Cl or CN, further preferably F or CN, particularly preferably CN.

An aromatic or heteroaromatic ring system having 5-30 or 5-60 aromatic ring atoms, which may also in each case be substituted by the above-mentioned radicals R, R¹ or R², is taken to mean, in particular, groups derived from benzene, naphthalene, anthracene, benzanthracene, phenanthrene, pyrene, chrysene, perylene, fluoranthene, naphthacene, pentacene, benzopyrene, biphenyl, biphenylene, terphenyl, triphenylene, fluorene, spirobifluorene, dihydrophenanthrene, dihydropyrene, tetrahydropyrene, cis- or trans-indenofluorene, cis- or trans-indenocarbazole, cis- or trans-indolocarbazole, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, hexaazatri-phenylene, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubin, naphthyridine, aza-carbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole or groups derived from combination of these systems.

An electron-transporting compound in the sense of the present invention, as is present in the organic electroluminescent device according to the invention, is a compound which has an LUMO of less than or equal to −2.4 eV. The LUMO here is the lowest unoccupied molecular orbital. The value of the LUMO of the compound is determined by quantum-chemical calculation, as described in general terms below in the example part.

The layer which comprises the electron-transporting compound having an LUMO ≦−2.4 eV and the compound of the formula (1) or (1a) is, in particular, an emitting layer, an electron-transport or electron-injection layer or a hole-blocking layer, preferably an emitting layer or an electron-transport or electron-injection layer and particularly preferably an emitting layer. In the case of an emitting layer, this is then preferably a phosphorescent layer which is characterised in that it comprises a phosphorescent compound in addition to the electron-transporting compound having an LUMO ≦−2.4 eV and the compound of the formula (1) or (1a). In this case, the electron-transporting compound having an LUMO of ≦−2.4 eV and the compound of the formula (1) or (1a) are matrix materials for the phosphorescent compound, i.e. do not themselves participate in the light emission or only do so to an insignificant extent.

A phosphorescent compound in the sense of the present invention is a compound which exhibits luminescence from an excited state having relatively high spin multiplicity, i.e. a spin state >1, in particular from an excited triplet state. For the purposes of this application, all luminescent complexes containing transition metals or lanthanides, in particular all iridium, platinum and copper complexes, are to be regarded as phosphorescent compounds.

The preferred ratio of the electron-transporting compound having an LUMO ≦−2.4 eV and the compound of the formula (1) or (1a) depends on the precise structure of the materials and precise application. Preference is generally given to a ratio of the electron-transporting compound having an LUMO ≦−2.4 eV to the compound of the formula (1) or (1a) between 10:90 and 90:10, preferably between 20:80 and 80:20, particularly preferably between 30:70 and 70:30 and very particularly preferably between 40:60 and 60:40. The ratio here is usually based on the volume if the layer is produced by a vapour-deposition process or is based on the weight if the layer is produced from solution. The best ratio in each case cannot be indicated independently of the materials, but can be determined by the person skilled in the art in routine experiments without making an inventive step. This applies both if the mixture is employed as matrix materials for a phosphorescent compound in an emitting layer and also if the mixture is employed as electron-transport materials in an electron-transport layer.

If the electron-transporting compound having an LUMO ≦−2.4 eV and the compound of the formula (1) or (1a) are employed as matrix materials for a phosphorescent compound, it is preferred for their triplet energy to be not significantly less than the triplet energy of the phosphorescent emitter. The triplet level T₁(emitter)−T₁(matrix) is preferably ≦0.2 eV, particularly preferably ≦0.15 eV, very particularly preferably ≦0.1 eV. T₁(matrix) here is the triplet level of the matrix material in the emission layer, where this condition applies to each of the two matrix materials, and T₁(emitter) is the triplet level of the phosphorescent emitter. If the emission layer comprises more than two matrix materials, the above-mentioned relationship preferably also applies to each further matrix material.

The mixture of the phosphorescent compound and the matrix materials, i.e. the electron-transporting compound having an LUMO ≦−2.4 eV and the compound of the formula (1) or (1a), in the emitting layer comprises in total between 99 and 1% by vol., preferably between 98 and 10% by vol., particularly preferably between 97 and 60% by vol., in particular between 95 and 80% by vol., of the matrix materials, based on the entire mixture comprising emitter and matrix materials. Correspondingly, the mixture comprises between 1 and 99% by vol., preferably between 2 and 90% by vol., particularly preferably between 3 and 40% by vol., in particular between 5 and 20% by vol., of the emitter, based on the entire mixture comprising emitter and matrix materials.

Preferred embodiments of the compound of the formula (1) or (1a) are described below.

In a preferred embodiment of the invention, the group Ar¹ stands for a group of the following formula (2), (3), (4), (5) or (6),

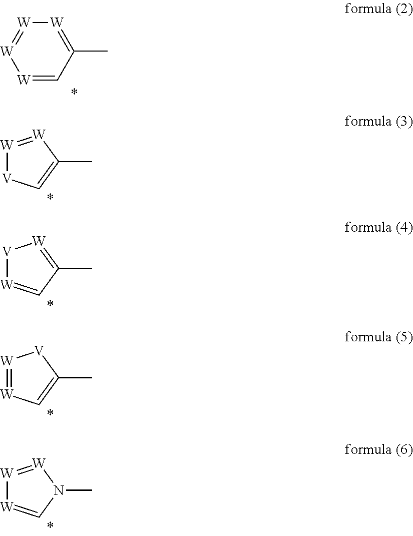

where the dashed bond indicates the link to the carbonyl group, * indicates the position of the link to E, and furthermore:
W is, identically or differently on each occurrence, CR or N; or two adjacent groups W stand for a group of the following formula (7) or (8),

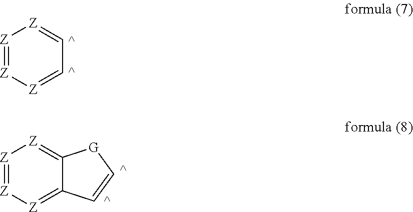

where G stands for CR₂, NR, O or S, Z stands, identically or differently on each occurrence, for CR or N, and A indicates the corresponding adjacent groups W in the formulae (2) to (6);
V is NR, O or S.

In a further preferred embodiment of the invention, the group Ar² stands for a group of one of the following formulae (9), (10) or (11),

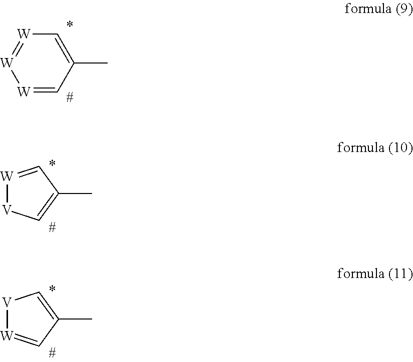

where the dashed bond indicates the link to N, # indicates the position of the link to Ar³, * indicates the link to E, and W and V have the meanings given above.

In a further preferred embodiment of the invention, the group Ar³ stands for a group of one of the following formulae (12), (13), (14) or (15),

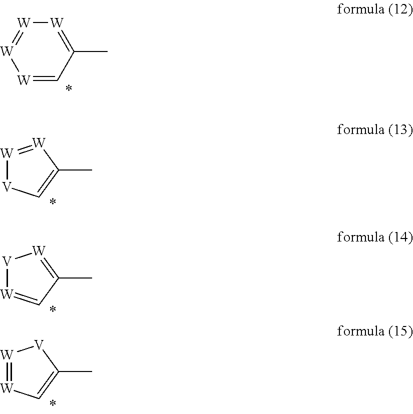

where the dashed bond indicates the link to N, * indicates the link to Ar², and W and V have the meanings given above.

The preferred groups Ar¹, Ar² and Ar³ mentioned above can be combined with one another as desired.

In a further preferred embodiment of the invention, E stands for a single bond.

In a preferred embodiment of the invention, the preferences mentioned above occur simultaneously. Particular preference is therefore given to compounds of the formula (1) or (1a) for which:
E is a single bond;
Ar¹ is selected from the groups of the formula (2), (3), (4), (5) or (6) indicated above;
Ar² is selected from the groups of the formulae (9), (10) or (11) indicated above;
Ar³ is selected from the groups of the formulae (12), (13), (14) or (15) indicated above.

Particularly preferably, at least two of the groups Ar¹, Ar² and Ar³ stand for a 6-membered aryl ring group or 6-membered heteroaryl ring group. Particularly preferably, Ar¹ thus stands for a group of the formula (2) and at the same time Ar² stands for a group of the formula (9), or Ar¹ stands for a group of the formula (2) and at the same time Ar³ stands for a group of the formula (12), or Ar² stands for a group of the formula (9) and at the same time Ar³ stands for a group of the formula (12).

Particularly preferred embodiments of the formula (1) are therefore the compounds of the following formulae (16) to (26),

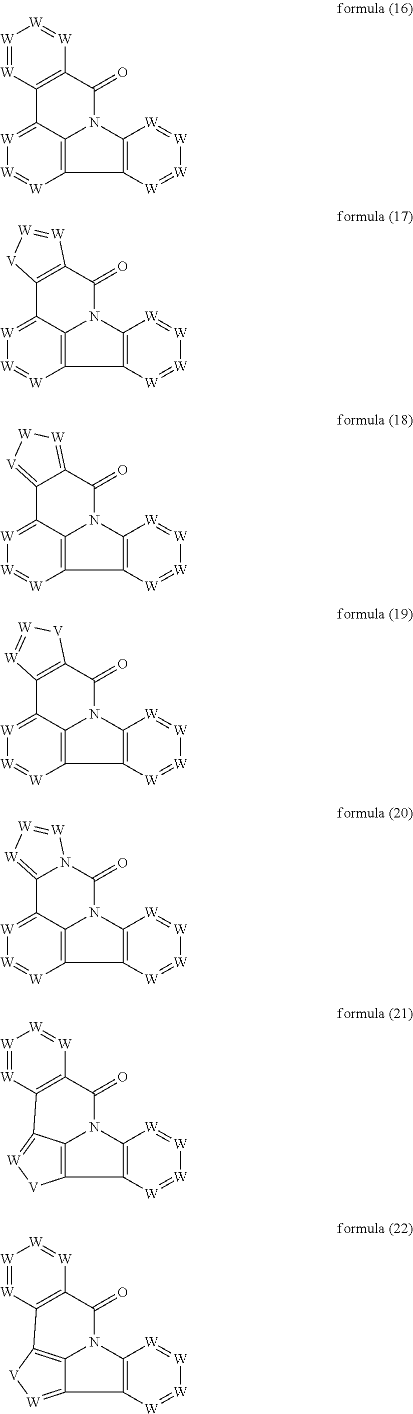

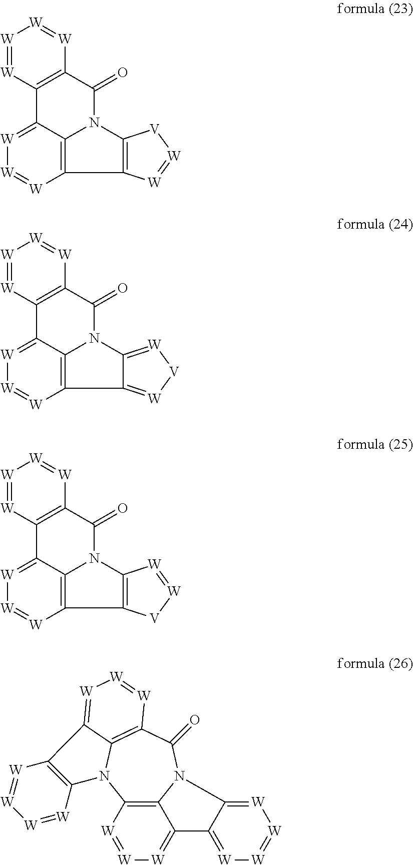

where the symbols used have the meanings given above.

It is furthermore preferred for W to stand for CR or N and not for a group of the formula (7) or (8). In a preferred embodiment of the compounds of the formulae (16) to (26), in total a maximum of one symbol W per ring stands for N, and the remaining symbols W stand for CR. In a particularly preferred embodiment of the invention, all symbols W stand for CR. Particular preference is therefore given to the compounds of the following formulae (16a) to (26a),

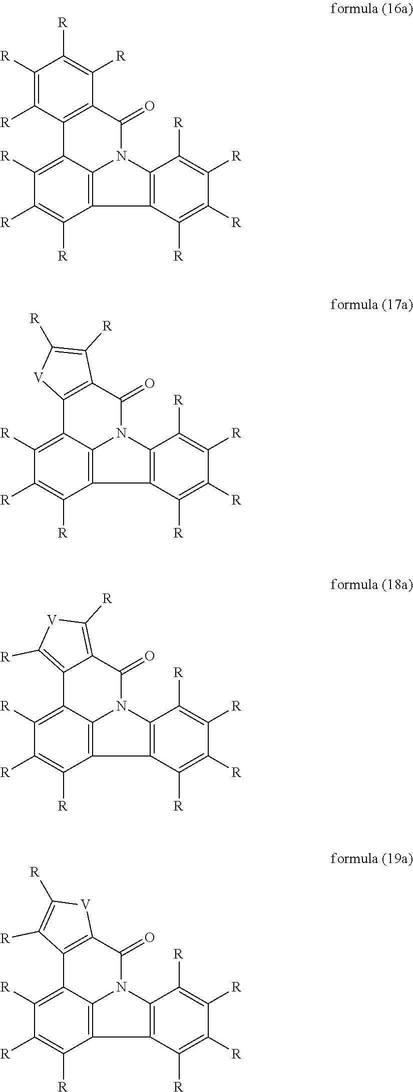

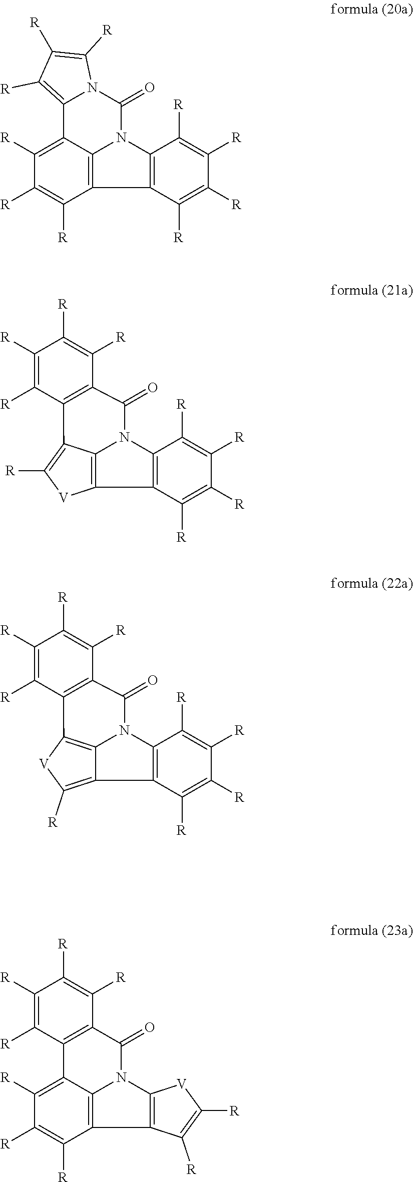

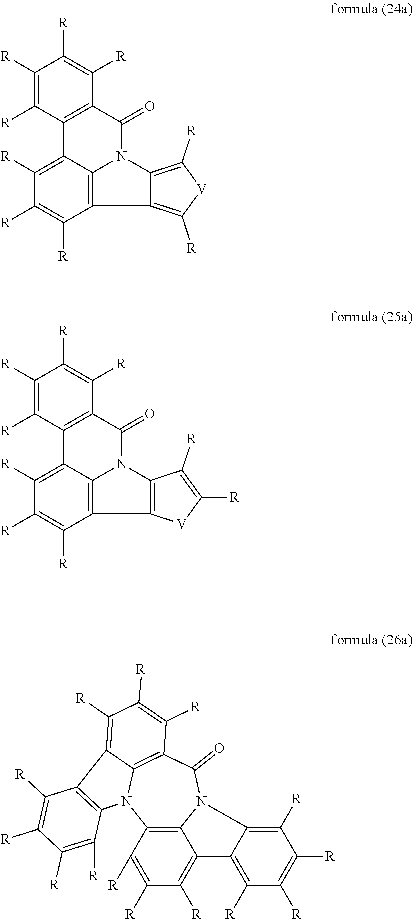

where the symbols used have the meanings given above.

Very particular preference is given to the structures of the formulae (16b) to (26b),

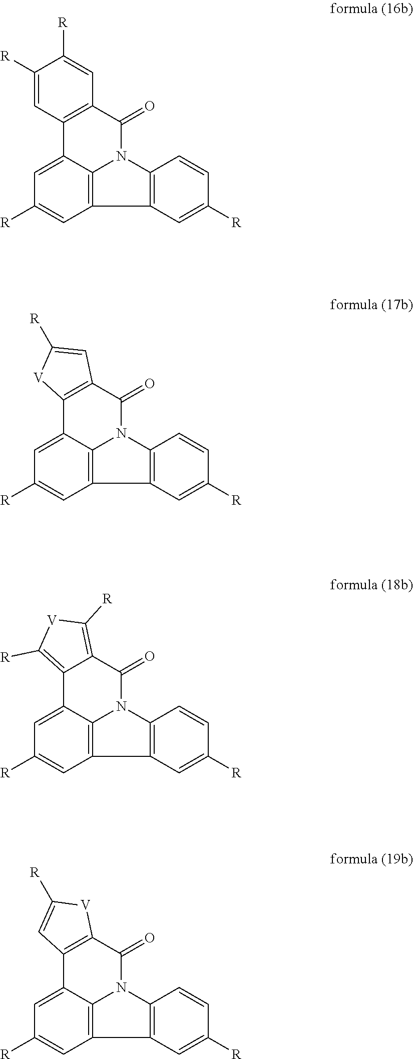

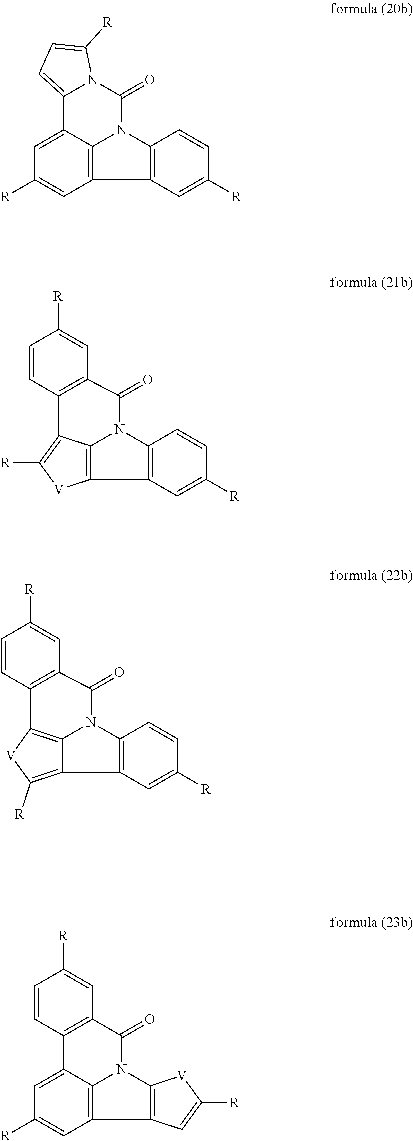

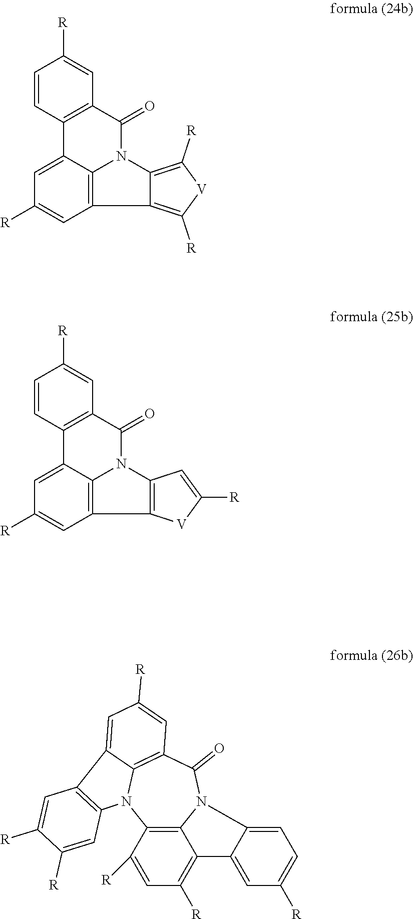

where the symbols used have the meanings given above.

Very particular preference is given to the compounds of the formula (16) or (16a) or (16b).

In a further preferred embodiment of the invention, Ar³ stands for a group of the formula (12) and two adjacent groups W in this group Ar³ stand for a group of the formula (8) and the other groups W in this group Ar³ stand, identically or differently, for CR or N, in particular for CR. The group of the formula (8) here can be condensed on in any possible position. Particularly preferably, Ar¹ stands for a group of the formula (2) in which W stands, identically or differently, for CR or N, in particular for CR, and at the same time Ar² stands for a group of the formula (9) in which W stands, identically or differently, for CR or N, in particular for CR. Preferred embodiments of the compounds of the formula (1) are thus furthermore the compounds of the following formulae (27) to (32),

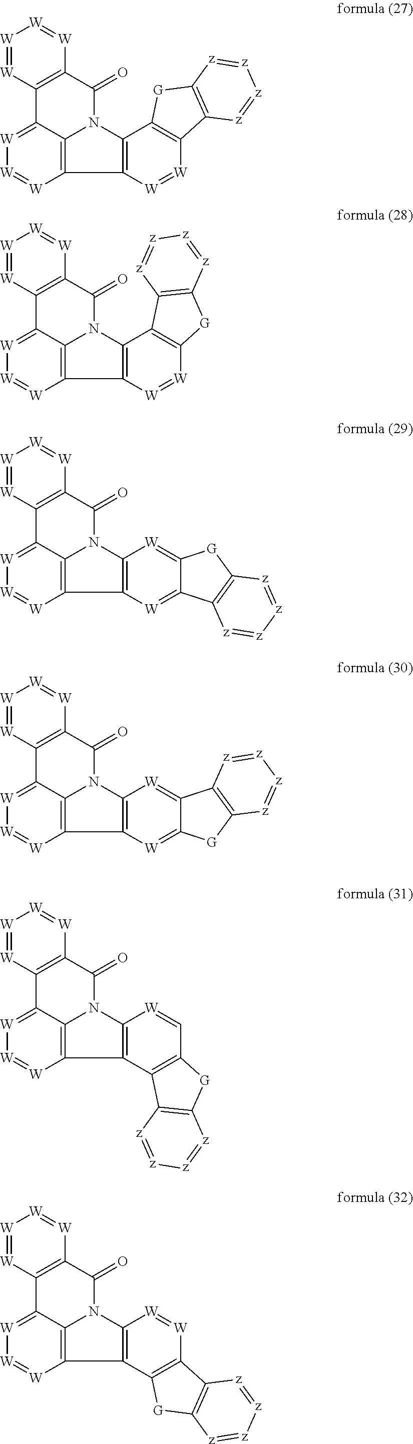

where G and Z have the meanings given above and W stands, identically or differently on each occurrence, for CR or N.

In a preferred embodiment of the invention, a maximum of one group W or Z per ring in each of the compounds of the formulae (27) to (32) stands for N and the other groups W or Z stand for CR. Particularly preferably, all groups W and Z stand for CR.

In a further preferred embodiment of the invention, G stands for CR₂, NR or O, particularly preferably for CR₂ or NR and very particularly preferably for CR₂.

In a particularly preferred embodiment of the invention, all groups W and Z stand for CR and at the same time G stands for CR₂, NR or O, particularly preferably for CR₂ or NR and in particular for CR₂.

Preferred compounds of the formulae (27) to (32) are thus the compounds of the following formulae (27a) to (32a),

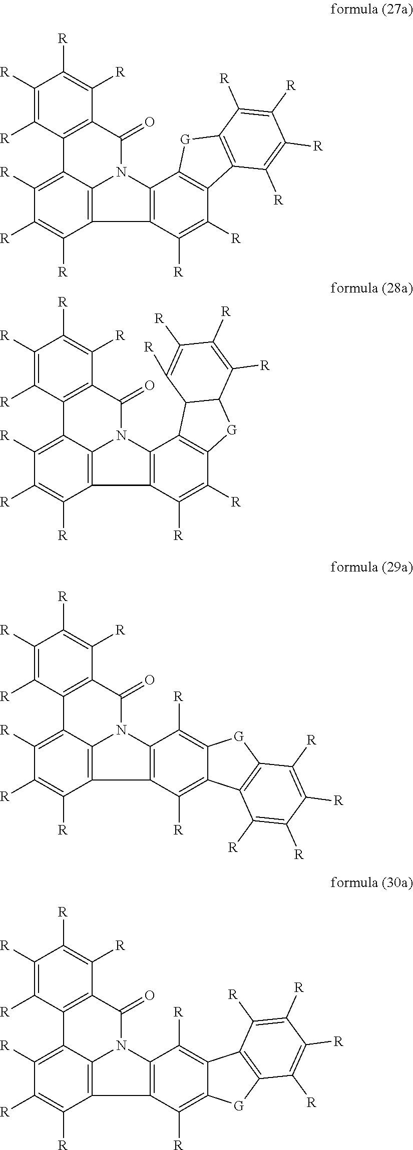

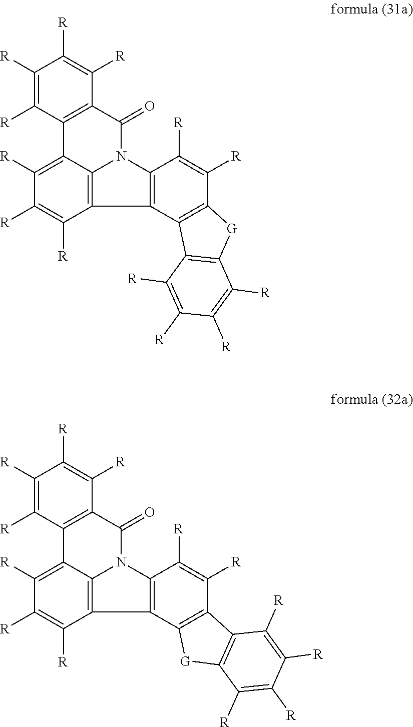

where the symbols used have the meanings given above.

The following compounds of the formulae (27b) to (32b) are particularly preferred:

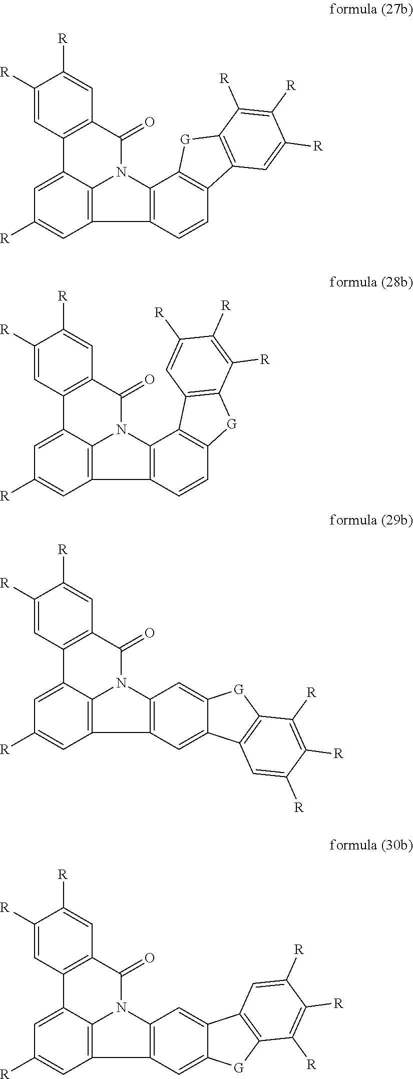

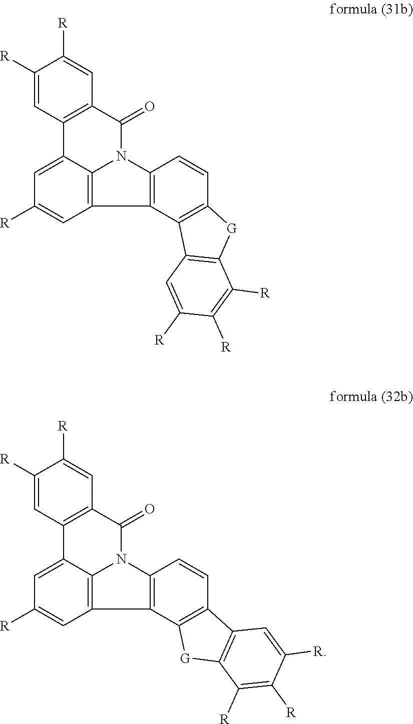

R and G here have the meanings given above and the preferred meanings given above or below.

The bridging group L in the compounds of the formula (1a) is preferably selected from a single bond or an aromatic or heteroaromatic ring system having 5 to 30 aromatic ring atoms, which may be substituted by one or more radicals R. The aromatic or heteroaromatic ring systems here preferably contain no condensed aryl or heteroaryl groups in which more than two six-membered aromatic rings are condensed directly onto one another. Particularly preferably, they contain absolutely no aryl or heteroaryl groups in which six-membered aromatic rings are condensed directly onto one another.

In a further preferred embodiment of the invention, the index n in compounds of the formula (1a) is 2 or 3, in particular 2. Very particularly preferably, compounds of the formula (1) are employed.

In a preferred embodiment of the invention, R in the formulae indicated above is selected, identically or differently on each occurrence, from the group consisting of H, D, F, Cl, Br, CN, N(Ar⁵)₂, C(═O)Ar⁵, a straight-chain alkyl or alkoxy group having 1 to 10 C atoms or a branched or cyclic alkyl or alkoxy group having 3 to 10 C atoms or an alkenyl or alkynyl group having 2 to 10 C atoms, each of which may be substituted by one or more radicals R¹, where one or more non-adjacent CH₂ groups may be replaced by O and where one or more H atoms may be replaced by D or F, an aromatic or heteroaromatic ring system having 5 to 30 aromatic ring atoms, which may in each case be substituted by one or more radicals R¹, an aryloxy or heteroaryloxy group having 5 to 30 aromatic ring atoms, which may be substituted by one or more radicals R¹, or a combination of these systems. R in the formulae indicated above is particularly preferably selected, identically or differently on each occurrence, from the group consisting of H, D, F, Cl, Br, CN, a straight-chain alkyl group having 1 to 10 C atoms or a branched or cyclic alkyl group having 3 to 10 C atoms, each of which may be substituted by one or more radicals R¹, where one or more H atoms may be replaced by D or F, an aromatic or heteroaromatic ring system having 5 to 18 aromatic ring atoms, which may in each case be substituted by one or more radicals R¹, or a combination of these systems.

The radicals R here, if they contain aromatic or heteroaromatic ring systems, preferably contain no condensed aryl or heteroaryl groups in which more than two six-membered aromatic rings are condensed directly onto one another. Particularly preferably, they contain absolutely no aryl or heteroaryl groups in which six-membered aromatic rings are condensed directly onto one another. Particular preference is given here to phenyl, biphenyl, terphenyl, quaterphenyl, carbazole, dibenzothiophene, dibenzofuran, indenocarbazole, indolocarbazole, triazine or pyrimidine, each of which may also be substituted by one or more radicals R¹. It is also preferred here for not more than two six-membered aromatic rings in the radicals R¹ to be condensed directly onto one another. Particularly preferably, R¹ contains absolutely no aryl or heteroaryl groups in which six-membered aromatic rings are condensed directly onto one another.

For compounds which are processed by vacuum evaporation, the alkyl groups preferably have not more than five C atoms, particularly preferably not more than 4 C atoms, very particularly preferably not more than 1 C atom. For compounds which are processed from solution, suitable compounds are also those which are substituted by alkyl groups having up to 10 C atoms or which are substituted by oligoarylene groups, for example ortho-, meta-, para- or branched terphenyl groups.

The synthesis of the compounds of the formula (1) can be carried out by the processes described in WO 2011/116865 and WO 2011/137951.

Examples of preferred compounds in accordance with the embodiments described above are the compounds shown in the following table.

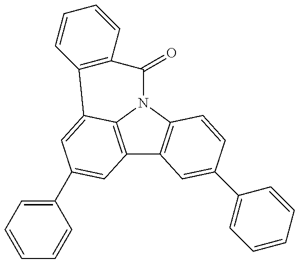 [SMILES: O=c1c2ccccc2c2cc(-c3ccccc3)cc3c4cc(-c5ccccc5)ccc4n1c23]

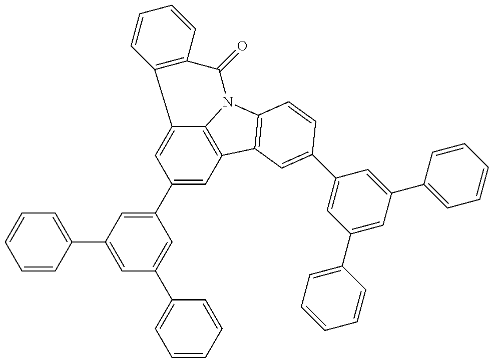 [SMILES: O=c1c2ccccc2c2cc(-c3cc(-c4ccccc4)cc(-c4ccccc4)c3)cc3c4cc(-c5cc(-c6ccccc6)cc(-c6ccccc6)c5)ccc4n1c23]

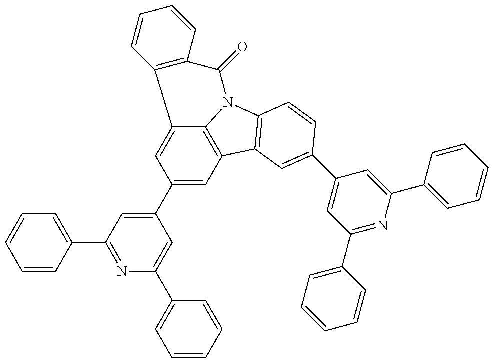 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

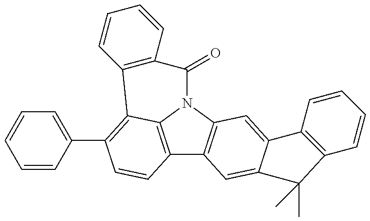 [SMILES: CC1(C)c2ccccc2-c2cc3c(cc21)c1ccc(-c2ccccc2)c2c4ccccc4c(=O)n3c12]

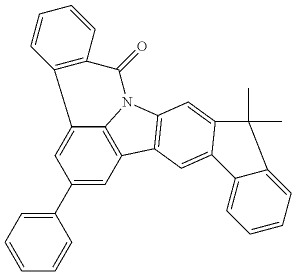 [SMILES: CC1(C)c2ccccc2-c2cc3c4cc(-c5ccccc5)cc5c6ccccc6c(=O)n(c3cc21)c54]

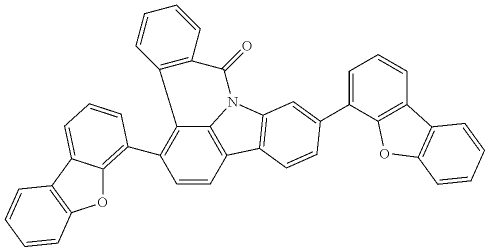 [SMILES: O=c1c2ccccc2c2c(-c3cccc4c3oc3ccccc34)ccc3c4ccc(-c5cccc6c5oc5ccccc56)cc4n1c32]

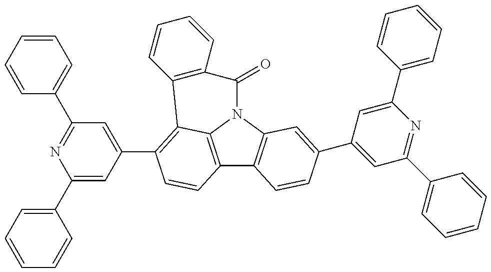 [SMILES: O=c1c2ccccc2c2c(-c3cc(-c4ccccc4)nc(-c4ccccc4)c3)ccc3c4ccc(-c5cc(-c6ccccc6)nc(-c6ccccc6)c5)cc4n1c32]

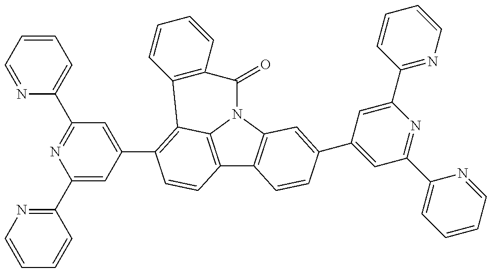 [SMILES: O=c1c2ccccc2c2c(-c3cc(-c4ccccn4)nc(-c4ccccn4)c3)ccc3c4ccc(-c5cc(-c6ccccn6)nc(-c6ccccn6)c5)cc4n1c32]

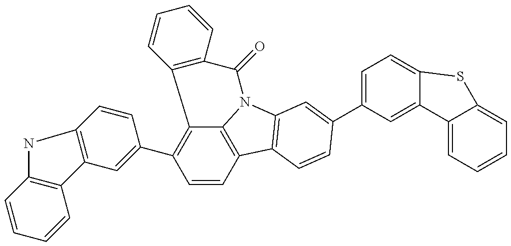 [SMILES: O=c1c2ccccc2c2c(-c3ccc4[nH]c5ccccc5c4c3)ccc3c4ccc(-c5ccc6sc7ccccc7c6c5)cc4n1c32]

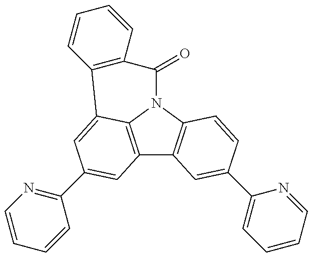 [SMILES: O=c1c2ccccc2c2cc(-c3ccccn3)cc3c4cc(-c5ccccn5)ccc4n1c23]

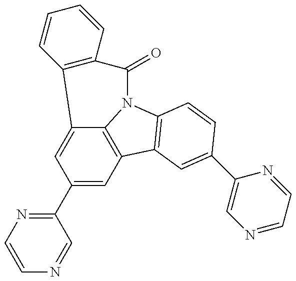 [SMILES: O=c1c2ccccc2c2cc(-c3cnccn3)cc3c4cc(-c5cnccn5)ccc4n1c23]

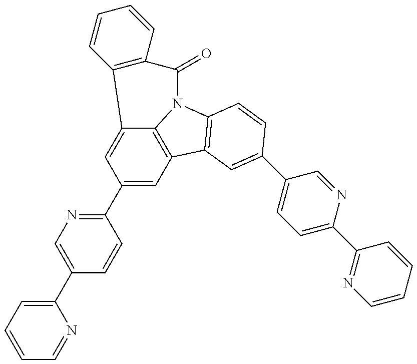 [SMILES: O=c1c2ccccc2c2cc(-c3ccc(-c4ccccn4)cn3)cc3c4cc(-c5ccc(-c6ccccn6)nc5)ccc4n1c23]

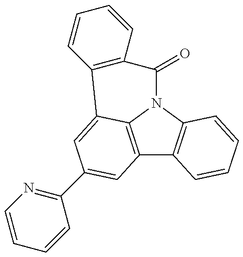 [SMILES: O=c1c2ccccc2c2cc(-c3ccccn3)cc3c4ccccc4n1c23]

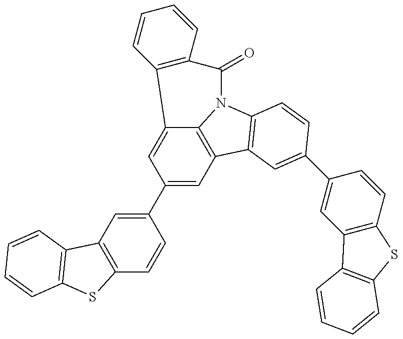 [SMILES: O=c1c2ccccc2c2cc(-c3ccc4sc5ccccc5c4c3)cc3c4cc(-c5ccc6sc7ccccc7c6c5)ccc4n1c23]

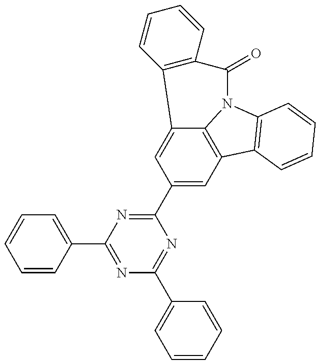 [SMILES: O=c1c2ccccc2c2cc(-c3nc(-c4ccccc4)nc(-c4ccccc4)n3)cc3c4ccccc4n1c23]

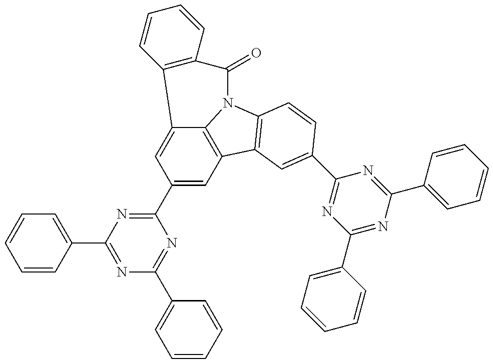 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

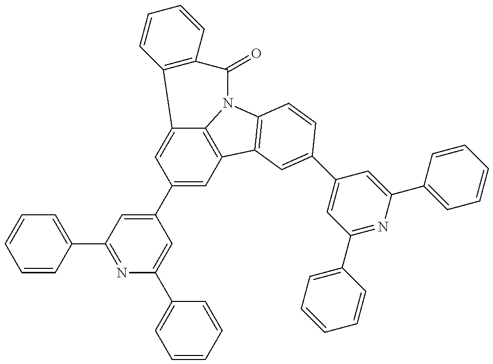 [SMILES: O=c1c2ccccc2c2cc(-c3cc(-c4ccccc4)nc(-c4ccccc4)c3)cc3c4cc(-c5cc(-c6ccccc6)nc(-c6ccccc6)c5)ccc4n1c23]

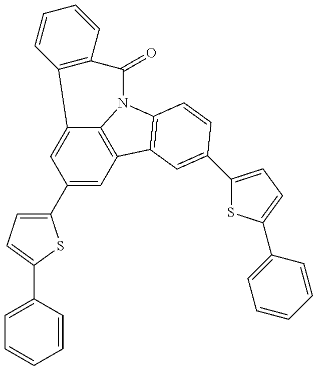 [SMILES: O=c1c2ccccc2c2cc(-c3ccc(-c4ccccc4)s3)cc3c4cc(-c5ccc(-c6ccccc6)s5)ccc4n1c23]

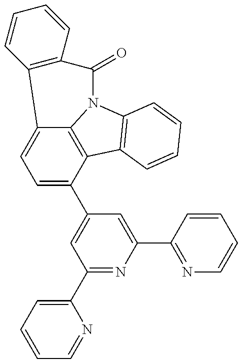 [SMILES: O=c1c2ccccc2c2ccc(-c3cc(-c4ccccn4)nc(-c4ccccn4)c3)c3c4ccccc4n1c23]

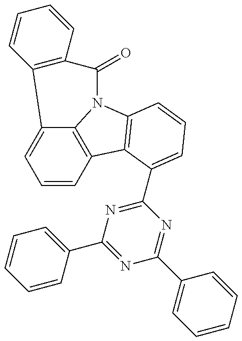 [SMILES: O=c1c2ccccc2c2cccc3c4c(-c5nc(-c6ccccc6)nc(-c6ccccc6)n5)cccc4n1c23]

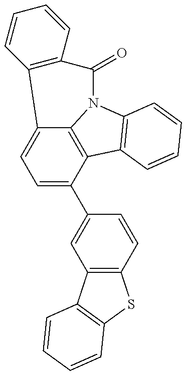 [SMILES: O=c1c2ccccc2c2ccc(-c3ccc4sc5ccccc5c4c3)c3c4ccccc4n1c23]

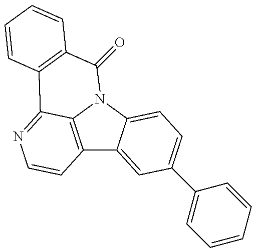 [SMILES: O=c1c2ccccc2c2nccc3c4cc(-c5ccccc5)ccc4n1c32]

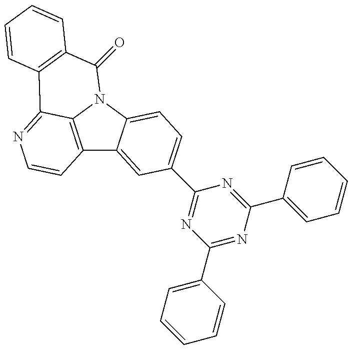 [SMILES: O=c1c2ccccc2c2nccc3c4cc(-c5nc(-c6ccccc6)nc(-c6ccccc6)n5)ccc4n1c32]

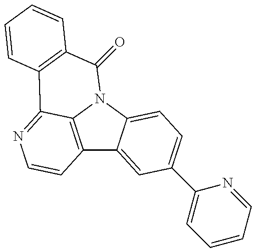 [SMILES: O=c1c2ccccc2c2nccc3c4cc(-c5ccccn5)ccc4n1c32]

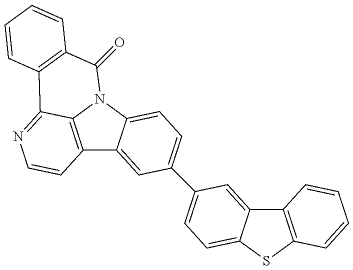 [SMILES: O=c1c2ccccc2c2nccc3c4cc(-c5ccc6sc7ccccc7c6c5)ccc4n1c32]

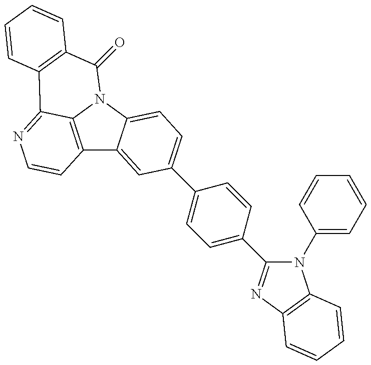 [SMILES: O=c1c2ccccc2c2nccc3c4cc(-c5ccc(-c6nc7ccccc7n6-c6ccccc6)cc5)ccc4n1c32]

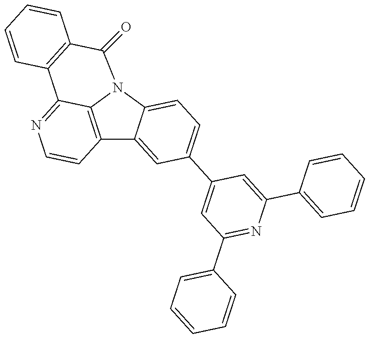 [SMILES: O=c1c2ccccc2c2nccc3c4cc(-c5cc(-c6ccccc6)nc(-c6ccccc6)c5)ccc4n1c32]

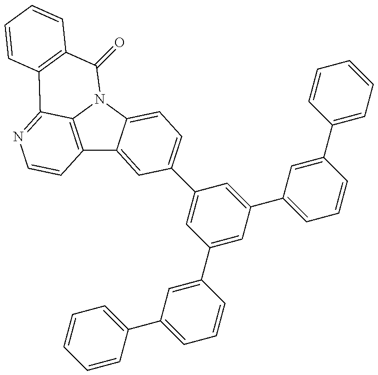 [SMILES: O=c1c2ccccc2c2nccc3c4cc(-c5cc(-c6cccc(-c7ccccc7)c6)cc(-c6cccc(-c7ccccc7)c6)c5)ccc4n1c32]

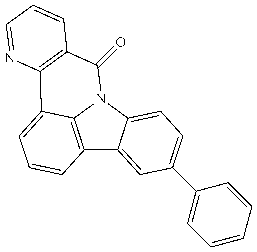 [SMILES: O=c1c2cccnc2c2cccc3c4cc(-c5ccccc5)ccc4n1c32]

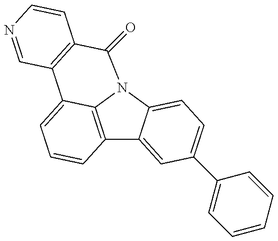 [SMILES: O=c1c2ccncc2c2cccc3c4cc(-c5ccccc5)ccc4n1c23]

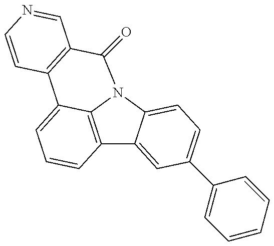 [SMILES: O=c1c2cnccc2c2cccc3c4cc(-c5ccccc5)ccc4n1c23]

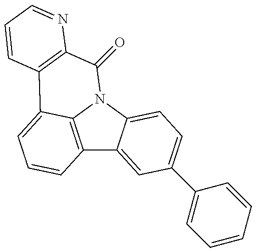 [SMILES: O=c1c2ncccc2c2cccc3c4cc(-c5ccccc5)ccc4n1c23]

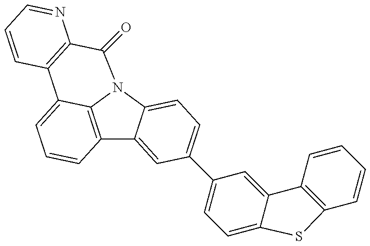 [SMILES: O=c1c2ncccc2c2cccc3c4cc(-c5ccc6sc7ccccc7c6c5)ccc4n1c23]

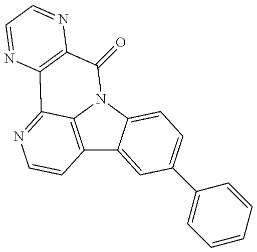 [SMILES: O=c1c2nccnc2c2nccc3c4cc(-c5ccccc5)ccc4n1c32]

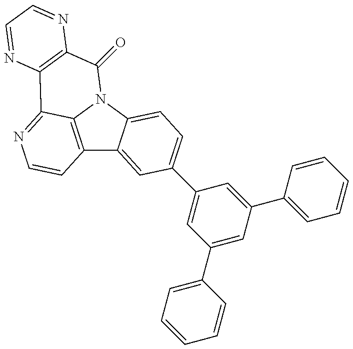 [SMILES: O=c1c2nccnc2c2nccc3c4cc(-c5cc(-c6ccccc6)cc(-c6ccccc6)c5)ccc4n1c32]

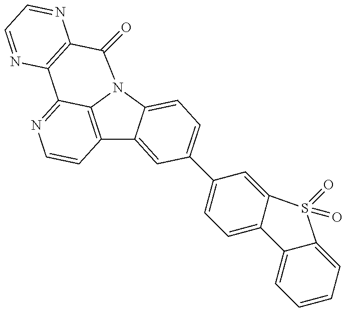 [SMILES: O=c1c2nccnc2c2nccc3c4cc(-c5ccc6c(c5)S(=O)(=O)c5ccccc5-6)ccc4n1c32]

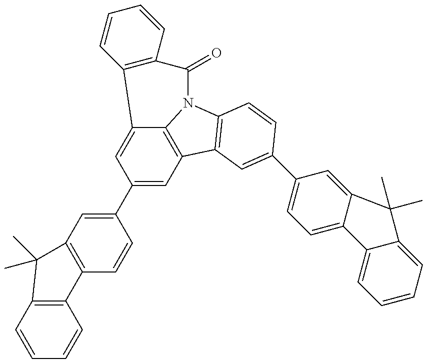

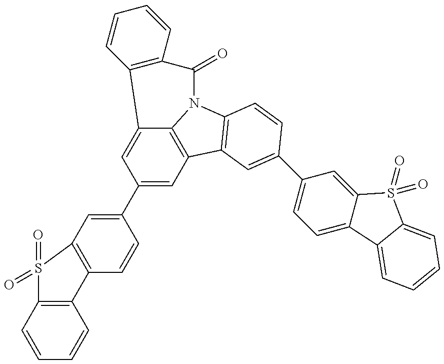 [SMILES: O=c1c2ccccc2c2cc(-c3ccc4c(c3)S(=O)(=O)c3ccccc3-4)cc3c4cc(-c5ccc6c(c5)S(=O)(=O)c5ccccc5-6)ccc4n1c23]

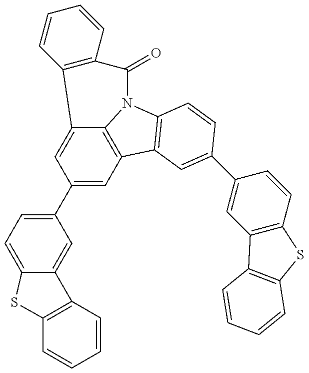 [SMILES: O=c1c2ccccc2c2cc(-c3ccc4sc5ccccc5c4c3)cc3c4cc(-c5ccc6sc7ccccc7c6c5)ccc4n1c23]

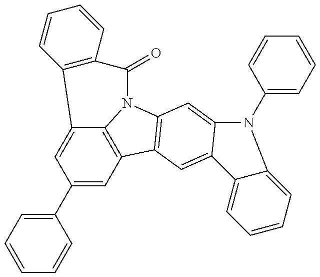 [SMILES: O=c1c2ccccc2c2cc(-c3ccccc3)cc3c4cc5c6ccccc6n(-c6ccccc6)c5cc4n1c23]

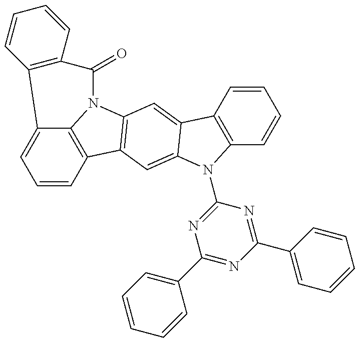 [SMILES: O=c1c2ccccc2c2cccc3c4cc5c(cc4n1c23)c1ccccc1n5-c1nc(-c2ccccc2)nc(-c2ccccc2)n1]

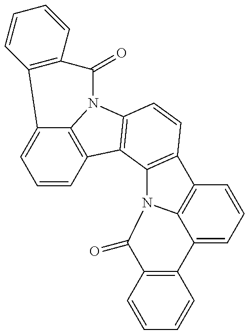 [SMILES: O=c1c2ccccc2c2cccc3c4c(ccc5c6cccc7c8ccccc8c(=O)n(c76)c54)n1c23]

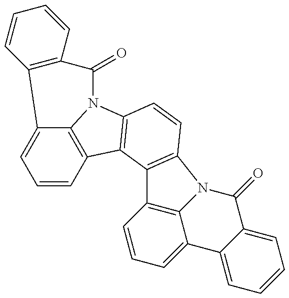 [SMILES: O=c1c2ccccc2c2cccc3c4c5c6cccc7c8ccccc8c(=O)n(c5ccc4n1c23)c76]

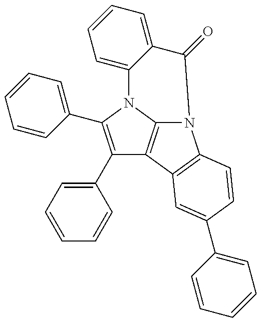 [SMILES: O=c1c2ccccc2n2c(-c3ccccc3)c(-c3ccccc3)c3c4cc(-c5ccccc5)ccc4n1c32]

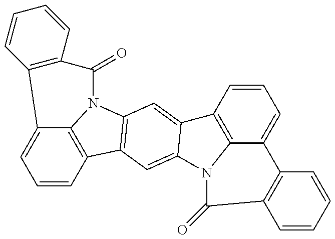 [SMILES: O=c1c2ccccc2c2cccc3c4cc5c(cc4n1c23)c1cccc2c3ccccc3c(=O)n5c21]

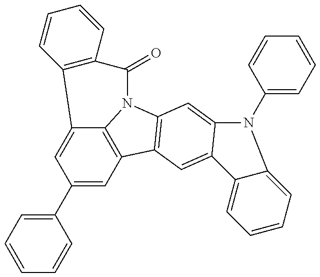 [SMILES: O=c1c2ccccc2c2cc(-c3ccccc3)cc3c4cc5c6ccccc6n(-c6ccccc6)c5cc4n1c23]

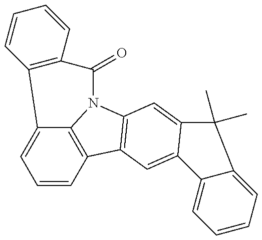 [SMILES: CC1(C)c2ccccc2-c2cc3c4cccc5c6ccccc6c(=O)n(c3cc21)c54]

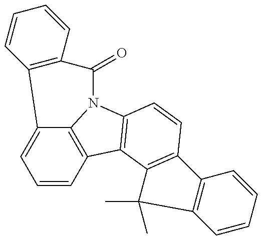 [SMILES: CC1(C)c2ccccc2-c2ccc3c(c21)c1cccc2c4ccccc4c(=O)n3c21]

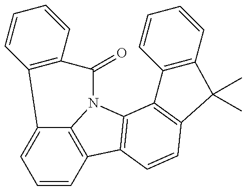 [SMILES: CC1(C)c2ccccc2-c2c1ccc1c3cccc4c5ccccc5c(=O)n(c21)c43]

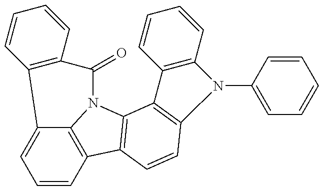 [SMILES: O=c1c2ccccc2c2cccc3c4ccc5c(c6ccccc6n5-c5ccccc5)c4n1c23]

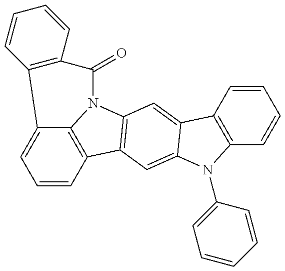 [SMILES: O=c1c2ccccc2c2cccc3c4cc5c(cc4n1c23)c1ccccc1n5-c1ccccc1]

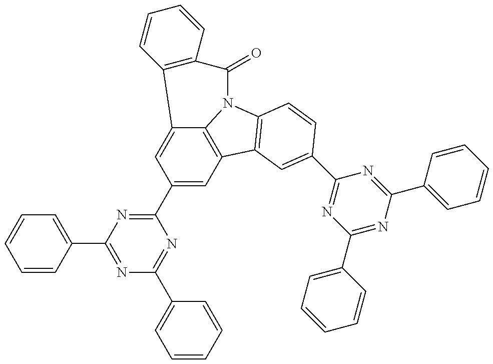 [SMILES: O=c1c2ccccc2c2cc(-c3nc(-c4ccccc4)nc(-c4ccccc4)n3)cc3c4cc(-c5nc(-c6ccccc6)nc(-c6ccccc6)n5)ccc4n1c23]

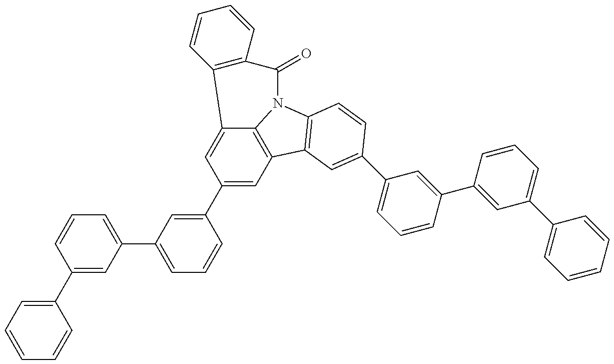 [SMILES: O=c1c2ccccc2c2cc(-c3cccc(-c4cccc(-c5ccccc5)c4)c3)cc3c4cc(-c5cccc(-c6cccc(-c7ccccc7)c6)c5)ccc4n1c23]

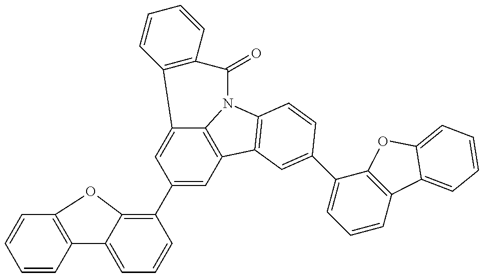 [SMILES: O=c1c2ccccc2c2cc(-c3cccc4c3oc3ccccc34)cc3c4cc(-c5cccc6c5oc5ccccc56)ccc4n1c23]

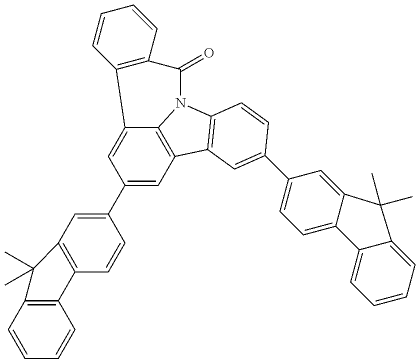 [SMILES: CC1(C)c2ccccc2-c2ccc(-c3ccc4c(c3)c3cc(-c5ccc6c(c5)C(C)(C)c5ccccc5-6)cc5c6ccccc6c(=O)n4c53)cc21]

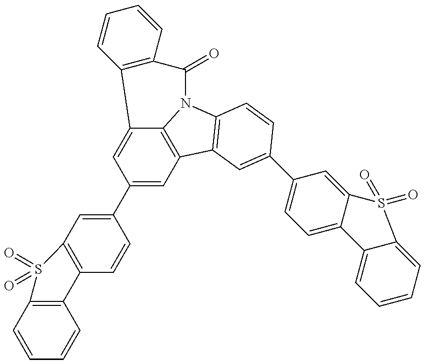 [SMILES: O=c1c2ccccc2c2cc(-c3ccc4c(c3)S(=O)(=O)c3ccccc3-4)cc3c4cc(-c5ccc6c(c5)S(=O)(=O)c5ccccc5-6)ccc4n1c23]

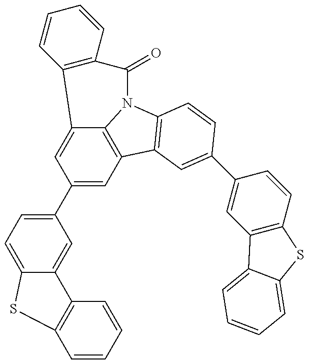 [SMILES: O=c1c2ccccc2c2cc(-c3ccc4sc5ccccc5c4c3)cc3c4cc(-c5ccc6sc7ccccc7c6c5)ccc4n1c23]

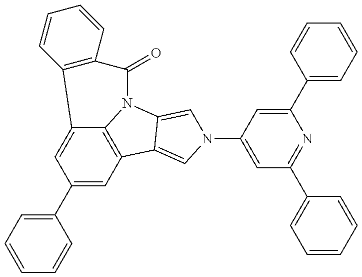 [SMILES: O=c1c2ccccc2c2cc(-c3ccccc3)cc3c4cn(-c5cc(-c6ccccc6)nc(-c6ccccc6)c5)cc4n1c23]

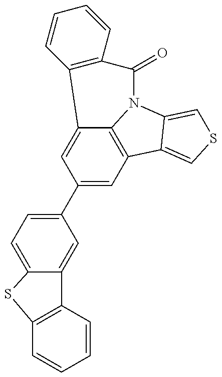 [SMILES: O=c1c2ccccc2c2cc(-c3ccc4sc5ccccc5c4c3)cc3c4cscc4n1c23]

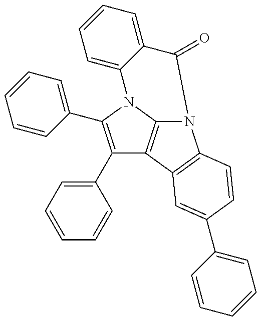 [SMILES: O=c1c2ccccc2n2c(-c3ccccc3)c(-c3ccccc3)c3c4cc(-c5ccccc5)ccc4n1c32]

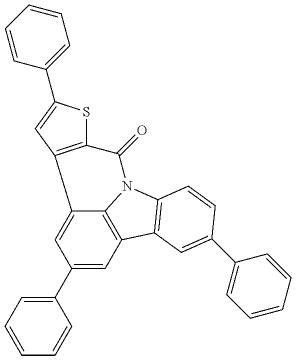 [SMILES: O=c1c2sc(-c3ccccc3)cc2c2cc(-c3ccccc3)cc3c4cc(-c5ccccc5)ccc4n1c23]

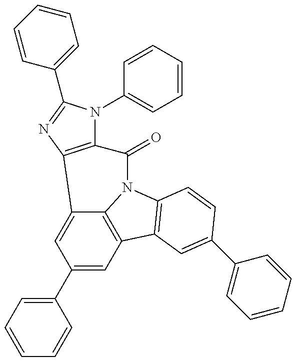 [SMILES: O=c1c2c(nc(-c3ccccc3)n2-c2ccccc2)c2cc(-c3ccccc3)cc3c4cc(-c5ccccc5)ccc4n1c32]

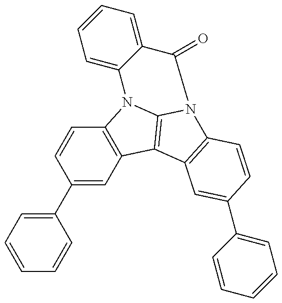 [SMILES: O=c1c2ccccc2n2c3ccc(-c4ccccc4)cc3c3c4cc(-c5ccccc5)ccc4n1c32]

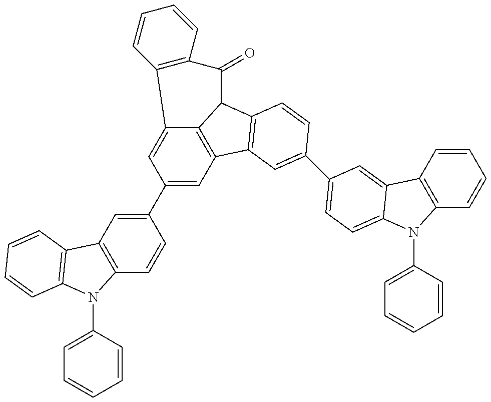 [SMILES: O=C1c2ccccc2-c2cc(-c3ccc4c(c3)c3ccccc3n4-c3ccccc3)cc3c2C1c1ccc(-c2ccc4c(c2)c2ccccc2n4-c2ccccc2)cc1-3]

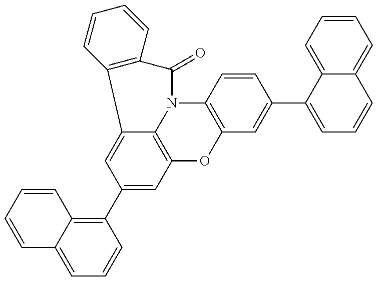 [SMILES: O=c1c2ccccc2c2cc(-c3cccc4ccccc34)cc3c2n1-c1ccc(-c2cccc4ccccc24)cc1O3]

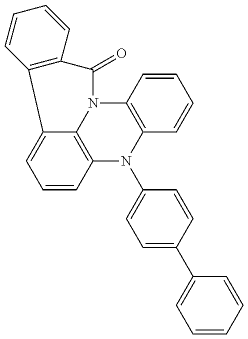 [SMILES: O=c1c2ccccc2c2cccc3c2n1-c1ccccc1N3c1ccc(-c2ccccc2)cc1]

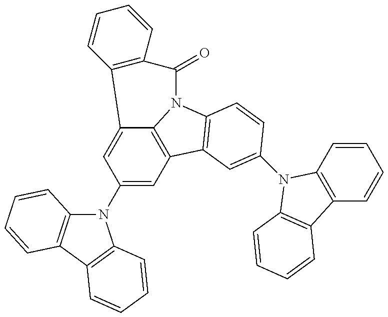 [SMILES: O=c1c2ccccc2c2cc(-n3c4ccccc4c4ccccc43)cc3c4cc(-n5c6ccccc6c6ccccc65)ccc4n1c23]

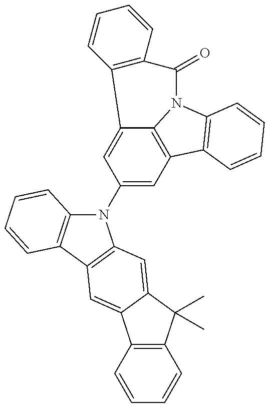 [SMILES: CC1(C)c2ccccc2-c2cc3c4ccccc4n(-c4cc5c6ccccc6c(=O)n6c7ccccc7c(c4)c56)c3cc21]

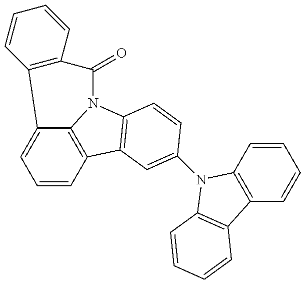 [SMILES: O=c1c2ccccc2c2cccc3c4cc(-n5c6ccccc6c6ccccc65)ccc4n1c23]

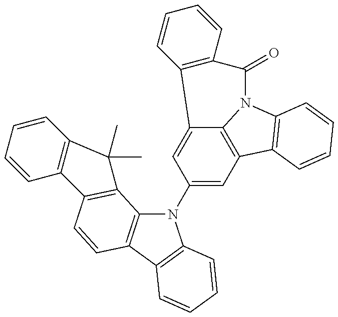 [SMILES: CC1(C)c2ccccc2-c2ccc3c4ccccc4n(-c4cc5c6ccccc6c(=O)n6c7ccccc7c(c4)c56)c3c21]

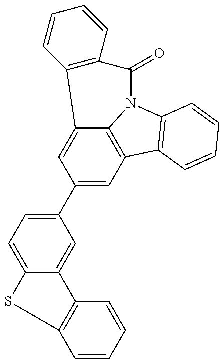 [SMILES: O=c1c2ccccc2c2cc(-c3ccc4sc5ccccc5c4c3)cc3c4ccccc4n1c23]

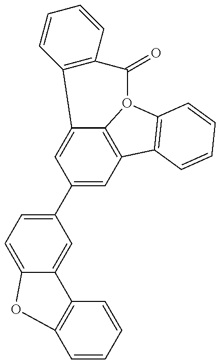

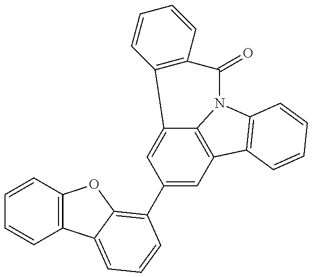 [SMILES: O=c1c2ccccc2c2cc(-c3cccc4c3oc3ccccc34)cc3c4ccccc4n1c23]

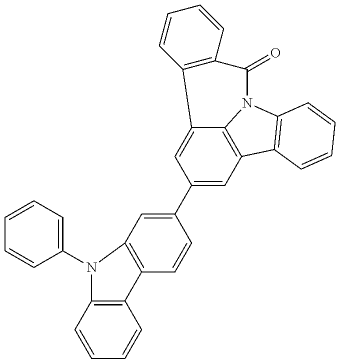 [SMILES: O=c1c2ccccc2c2cc(-c3ccc4c5ccccc5n(-c5ccccc5)c4c3)cc3c4ccccc4n1c23]

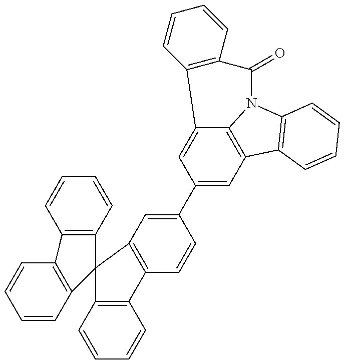 [SMILES: O=c1c2ccccc2c2cc(-c3ccc4c(c3)C3(c5ccccc5-c5ccccc53)c3ccccc3-4)cc3c4ccccc4n1c23]

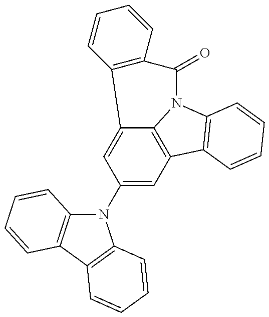 [SMILES: O=c1c2ccccc2c2cc(-n3c4ccccc4c4ccccc43)cc3c4ccccc4n1c23]

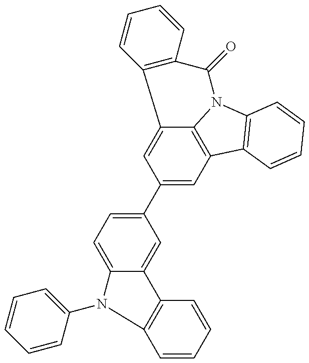 [SMILES: O=c1c2ccccc2c2cc(-c3ccc4c(c3)c3ccccc3n4-c3ccccc3)cc3c4ccccc4n1c23]

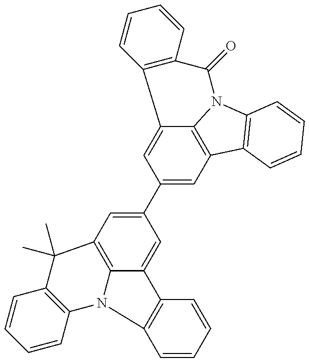 [SMILES: CC1(C)c2ccccc2-n2c3ccccc3c3cc(-c4cc5c6ccccc6c(=O)n6c7ccccc7c(c4)c56)cc1c32]

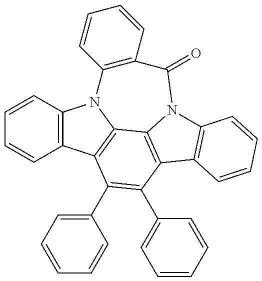 [SMILES: O=c1c2ccccc2n2c3ccccc3c3c(-c4ccccc4)c(-c4ccccc4)c4c5ccccc5n1c4c32]

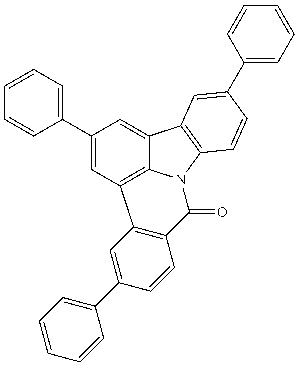 [SMILES: O=c1c2ccc(-c3ccccc3)cc2c2cc(-c3ccccc3)cc3c4cc(-c5ccccc5)ccc4n1c23]

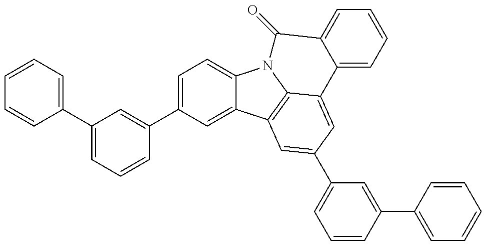 [SMILES: O=c1c2ccccc2c2cc(-c3cccc(-c4ccccc4)c3)cc3c4cc(-c5cccc(-c6ccccc6)c5)ccc4n1c23]

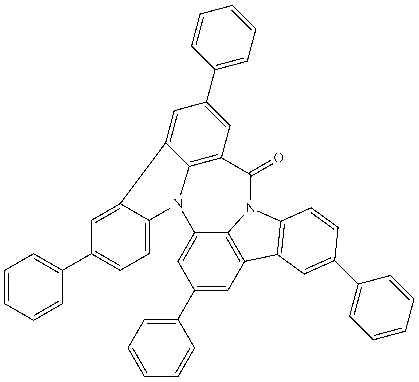 [SMILES: O=c1c2cc(-c3ccccc3)cc3c4cc(-c5ccccc5)ccc4n(c4cc(-c5ccccc5)cc5c6cc(-c7ccccc7)ccc6n1c54)c23]

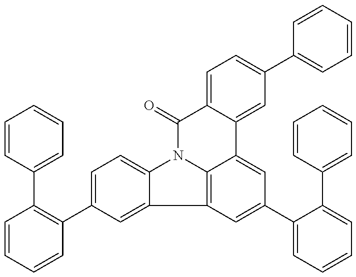 [SMILES: O=c1c2ccc(-c3ccccc3)cc2c2cc(-c3ccccc3-c3ccccc3)cc3c4cc(-c5ccccc5-c5ccccc5)ccc4n1c23]

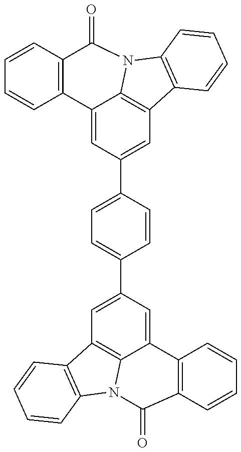 [SMILES: O=c1c2ccccc2c2cc(-c3ccc(-c4cc5c6ccccc6c(=O)n6c7ccccc7c(c4)c56)cc3)cc3c4ccccc4n1c23]

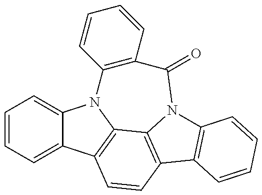 [SMILES: O=c1c2ccccc2n2c3ccccc3c3ccc4c5ccccc5n1c4c32]

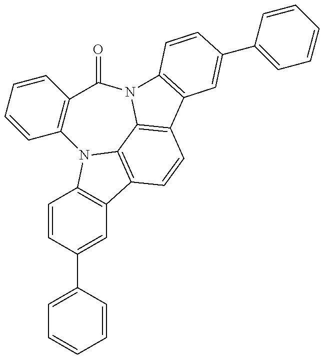 [SMILES: O=c1c2ccccc2n2c3ccc(-c4ccccc4)cc3c3ccc4c5cc(-c6ccccc6)ccc5n1c4c32]

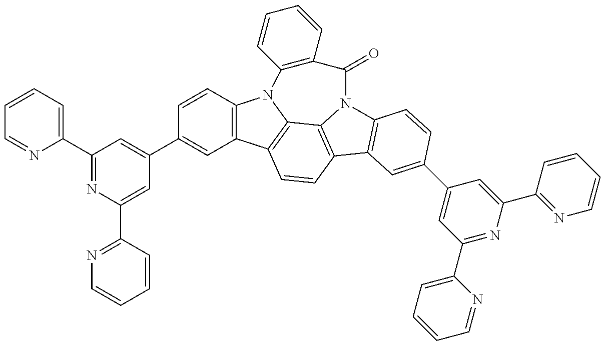 [SMILES: O=c1c2ccccc2n2c3ccc(-c4cc(-c5ccccn5)nc(-c5ccccn5)c4)cc3c3ccc4c5cc(-c6cc(-c7ccccn7)nc(-c7ccccn7)c6)ccc5n1c4c32]

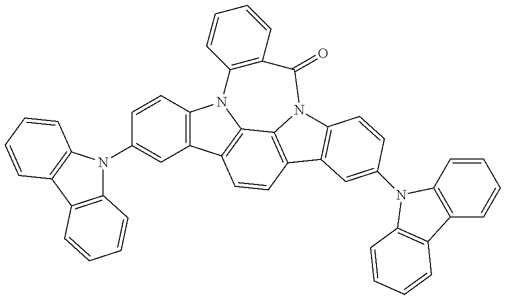 [SMILES: O=c1c2ccccc2n2c3ccc(-n4c5ccccc5c5ccccc54)cc3c3ccc4c5cc(-n6c7ccccc7c7ccccc76)ccc5n1c4c32]

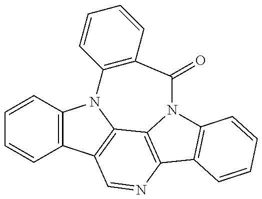 [SMILES: O=c1c2ccccc2n2c3ccccc3c3cnc4c5ccccc5n1c4c32]

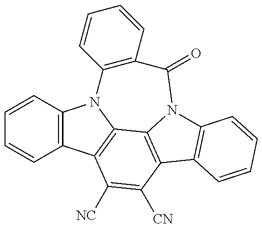 [SMILES: N#Cc1c(C#N)c2c3ccccc3n3c4ccccc4c(=O)n4c5ccccc5c1c4c23]

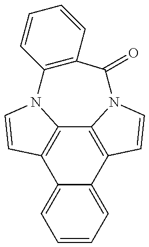 [SMILES: O=c1c2ccccc2n2ccc3c4ccccc4c4ccn1c4c32]

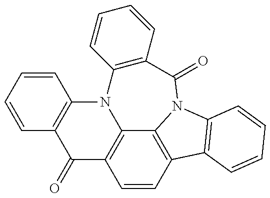 [SMILES: O=c1c2ccccc2n2c3ccccc3c(=O)n3c4ccccc4c4ccc1c2c43]

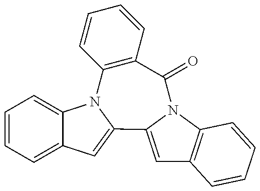 [SMILES: O=c1c2ccccc2n2c3ccccc3cc2c2cc3ccccc3n12]

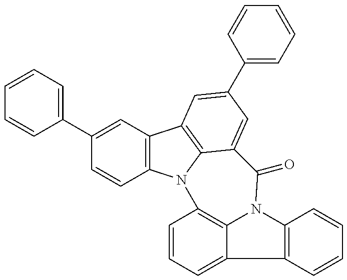 [SMILES: O=c1c2cc(-c3ccccc3)cc3c4cc(-c5ccccc5)ccc4n(c4cccc5c6ccccc6n1c54)c23]

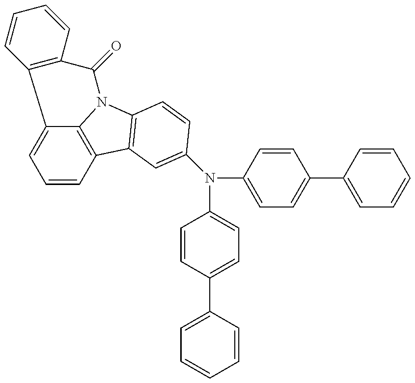 [SMILES: O=c1c2ccccc2c2cccc3c4cc(N(c5ccc(-c6ccccc6)cc5)c5ccc(-c6ccccc6)cc5)ccc4n1c23]

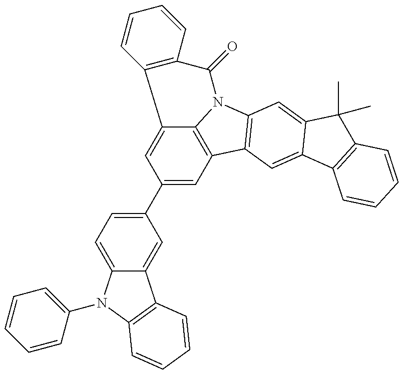 [SMILES: CC1(C)c2ccccc2-c2cc3c4cc(-c5ccc6c(c5)c5ccccc5n6-c5ccccc5)cc5c6ccccc6c(=O)n(c3cc21)c54]

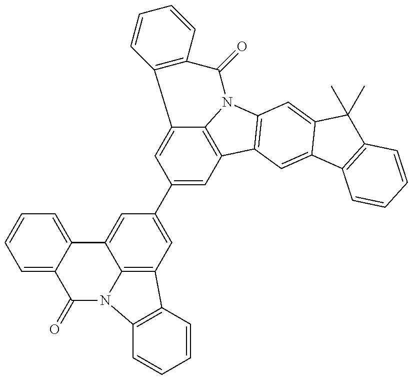 [SMILES: CC1(C)c2ccccc2-c2cc3c4cc(-c5cc6c7ccccc7c(=O)n7c8ccccc8c(c5)c67)cc5c6ccccc6c(=O)n(c3cc21)c54]

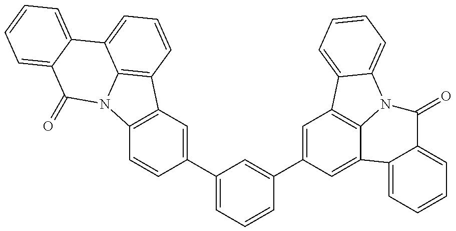 [SMILES: O=c1c2ccccc2c2cccc3c4cc(-c5cccc(-c6cc7c8ccccc8c(=O)n8c9ccccc9c(c6)c78)c5)ccc4n1c23]

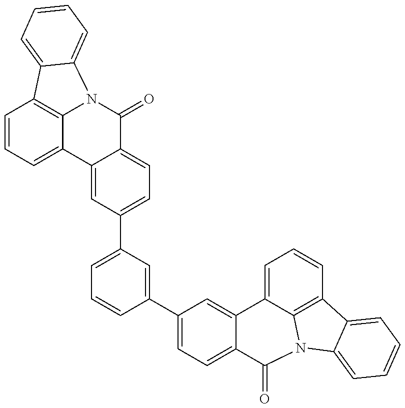 [SMILES: O=c1c2ccc(-c3cccc(-c4ccc5c(=O)n6c7ccccc7c7cccc(c5c4)c76)c3)cc2c2cccc3c4ccccc4n1c23]

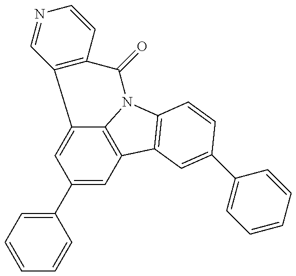 [SMILES: O=c1c2ccncc2c2cc(-c3ccccc3)cc3c4cc(-c5ccccc5)ccc4n1c23]

Preferred electron-transporting compounds, as are employed in accordance with the invention in combination with compounds of the formula (1), are described below.

In a preferred embodiment of the invention, the electron-transporting compound has an LUMO of ≦−2.5 eV, particularly preferably ≦−2.55 eV.

In a further preferred embodiment of the invention, the compound contains at least one triazine group, at least one pyrimidine group and/or at least one lactam group.

In the case of a compound containing a lactam group, this is then preferably selected from the compounds of the formula (1) indicated above or the preferred embodiments described above. The electron-transporting compound having an LUMO ≦−2.4 eV and the compound of the formula (1) are different from one another here, i.e. a mixture of two different compounds of the formula (1) is involved.

In the case of a compound containing a triazine group or a pyrimidine group, this group is then preferably bonded to three aromatic or heteroaromatic ring systems, each having 5 to 30 aromatic ring atoms, preferably 6 to 24 aromatic ring atoms, each of which may be substituted by one or more radicals R which are as defined above.

In the case of a compound containing a triazine group or a pyrimidine group, this group is then preferably bonded directly or via a bridging group to an indenocarbazole group, a spiroindenocarbazole group, an indolocarbazole group, a carbazole group or a spirobifluorene group. Both the triazine or pyrimidine group and also the indenocarbazole or indolocarbazole or carbazole group here may be substituted by one or more radicals R, where R is as defined above and two substituents R, in particular also the indeno carbon atom of the indenocarbazole, may also form a ring with one another and may thus form a spiro system.

Preferred embodiments of the triazine or pyrimidine group are the structures of the following formula (T-1) or (P-1), (P-2) or (P-3) respectively,

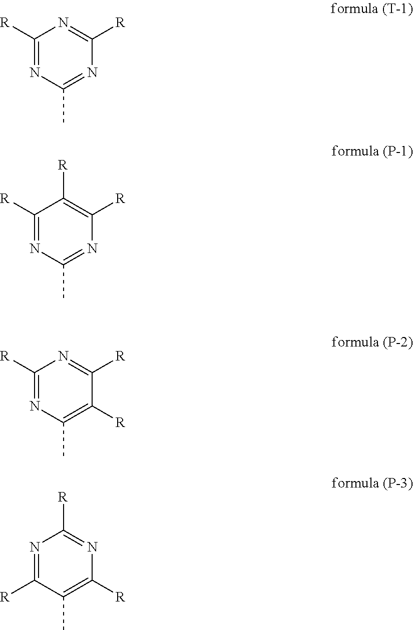

where R has the meanings given above and the dashed bond represents the bond to the indenocarbazole group, the indolocarbazole group or the carbazole group or the bond to the bridging group, which is in turn bonded to the indenocarbazole group, the indolocarbazole group or the carbazole group.

Particularly preferred pyrimidine groups are the structures of the following formulae (P-1a), (P-2a) and (P-3a),

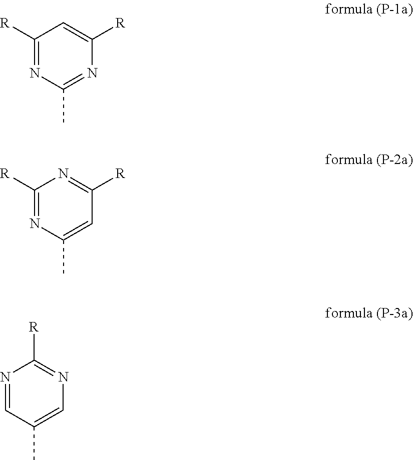

where the symbols used have the meanings given above.

The radicals R in formula (T-1) or (P-1a), (P-2a) or (P-3a) here preferably stand, identically or differently on each occurrence, for an aromatic or heteroaromatic ring system having 5 to 30, preferably 6 to 24, aromatic ring atoms, which may in each case be substituted by one or more radicals R¹. The aromatic or heteroaromatic ring systems here preferably contain no condensed aryl or heteroaryl groups in which more than two six-membered aromatic rings are condensed directly onto one another. Particularly preferably, they contain absolutely no aryl or heteroaryl groups in which six-membered aromatic rings are condensed directly onto one another.

Preferred embodiments of the indenocarbazole group, the indolocarbazole group or the carbazole group are the structures of the following formulae (indeno-1), (indeno-2), (indolo-1), (carb-1) and (spiro-1),

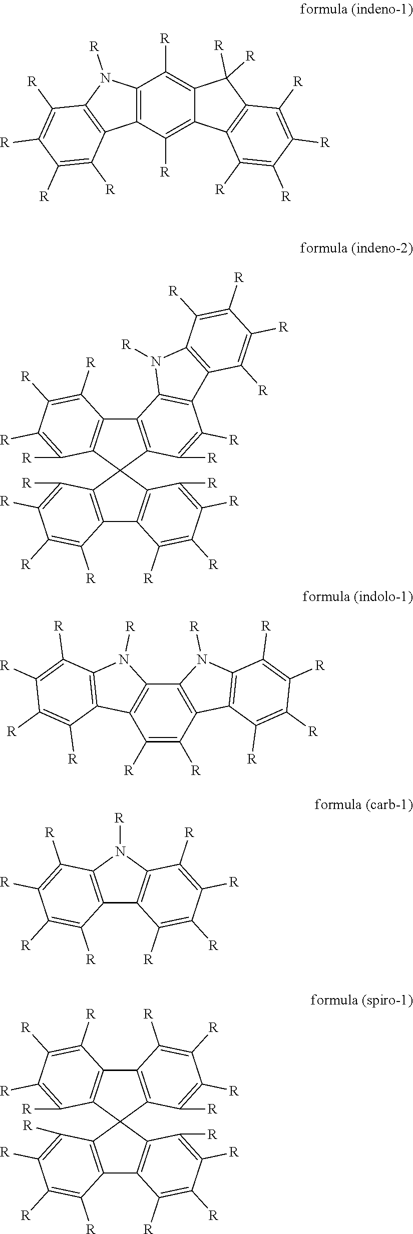

where the symbols used have the meanings given above. Instead of one of the radicals R which is bonded to a carbon atom or a nitrogen atom, these groups contain a bond to the pyrimidine or triazine group or to the bridging group, which is in turn bonded to the pyrimidine or triazine group.

Particularly preferred embodiments of the indenocarbazole group, the indolocarbazole group or the carbazole group are the structures of the following formulae (indeno-1a), (indeno-2a), (indolo-1a), (carb-1a) and (spiro-1a),

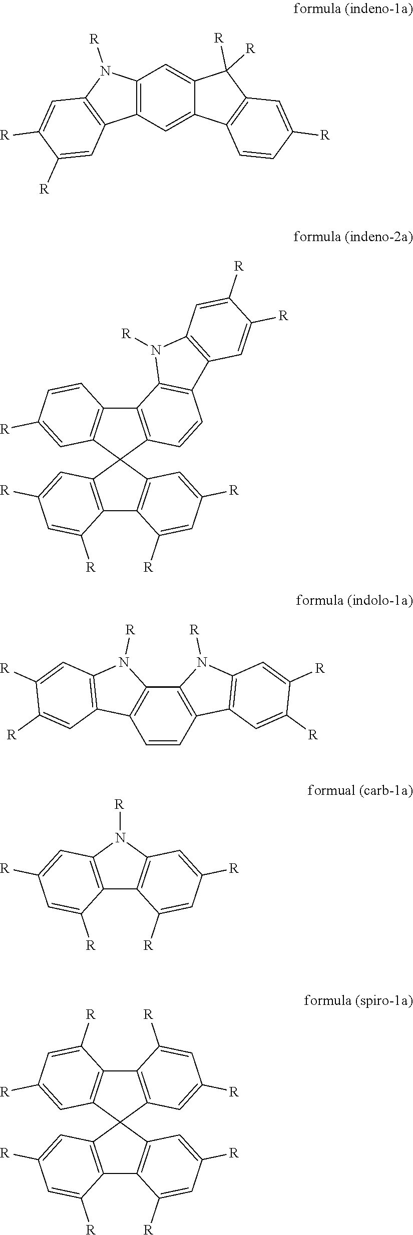

where the symbols used have the meanings given above. Instead of one of the radicals R which is bonded to a carbon atom or a nitrogen atom, these groups contain a bond to the pyrimidine or triazine group or to the bridging group, which is in turn bonded to the pyrimidine or triazine group.

Preferred bridging groups which link the pyrimidine or triazine group to the indenocarbazole group, the indolocarbazole group or the carbazole group are selected from divalent aromatic or heteroaromatic ring systems having 5 to 30 aromatic ring atoms, which may in each case be substituted by one or more radicals R. The aromatic or heteroaromatic ring systems here preferably contain no condensed aryl or heteroaryl groups in which more than two six-membered aromatic rings are condensed directly onto one another.

Particularly preferably, they contain absolutely no aryl or heteroaryl groups in which six-membered aromatic rings are condensed directly onto one another.

Preferred radicals R are the radicals R indicated above under the description of the compounds of the formula (1).

Examples of suitable electron-transporting compounds having an LUMO ≦−2.4 eV are the compounds depicted in the following table.

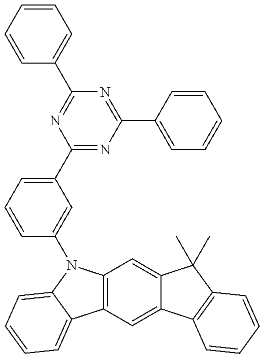 [SMILES: CC1(C)c2ccccc2-c2cc3c4ccccc4n(-c4cccc(-c5nc(-c6ccccc6)nc(-c6ccccc6)n5)c4)c3cc21]

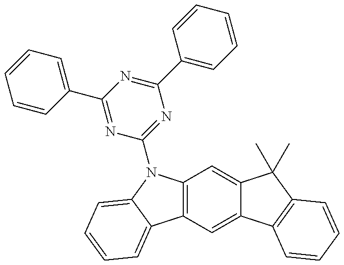 [SMILES: CC1(C)c2ccccc2-c2cc3c4ccccc4n(-c4nc(-c5ccccc5)nc(-c5ccccc5)n4)c3cc21]

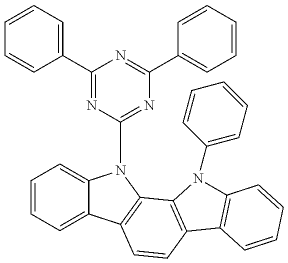 [SMILES: c1ccc(-c2nc(-c3ccccc3)nc(-n3c4ccccc4c4ccc5c6ccccc6n(-c6ccccc6)c5c43)n2)cc1]

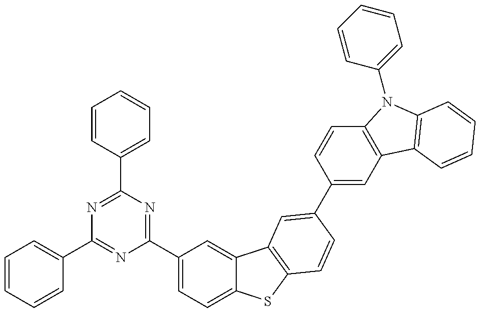 [SMILES: c1ccc(-c2nc(-c3ccccc3)nc(-c3ccc4sc5ccc(-c6ccc7c(c6)c6ccccc6n7-c6ccccc6)cc5c4c3)n2)cc1]

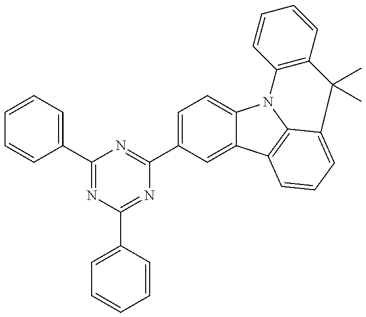 [SMILES: CC1(C)c2ccccc2-n2c3ccc(-c4nc(-c5ccccc5)nc(-c5ccccc5)n4)cc3c3cccc1c32]

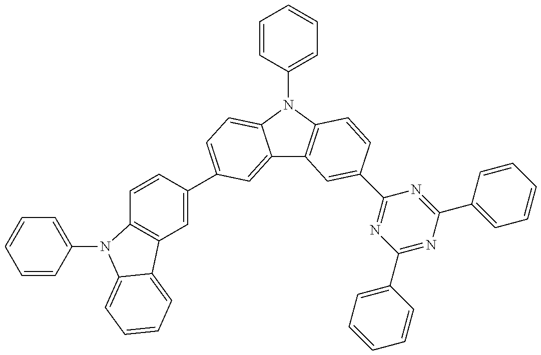 [SMILES: c1ccc(-c2nc(-c3ccccc3)nc(-c3ccc4c(c3)c3cc(-c5ccc6c(c5)c5ccccc5n6-c5ccccc5)ccc3n4-c3ccccc3)n2)cc1]

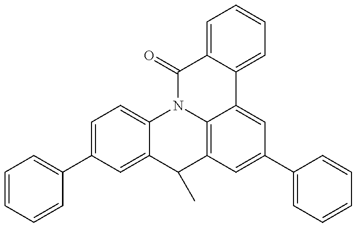 [SMILES: CC1c2cc(-c3ccccc3)ccc2-n2c(=O)c3ccccc3c3cc(-c4ccccc4)cc1c32]

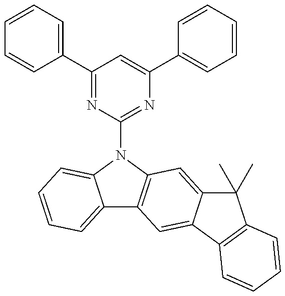 [SMILES: CC1(C)c2ccccc2-c2cc3c4ccccc4n(-c4nc(-c5ccccc5)cc(-c5ccccc5)n4)c3cc21]

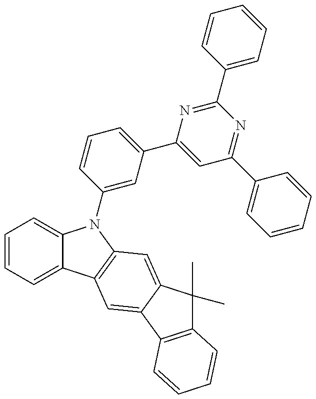 [SMILES: CC1(C)c2ccccc2-c2cc3c4ccccc4n(-c4cccc(-c5cc(-c6ccccc6)nc(-c6ccccc6)n5)c4)c3cc21]

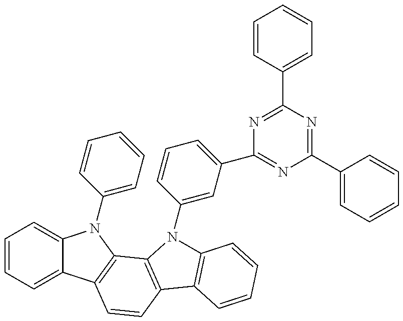 [SMILES: c1ccc(-c2nc(-c3ccccc3)nc(-c3cccc(-n4c5ccccc5c5ccc6c7ccccc7n(-c7ccccc7)c6c54)c3)n2)cc1]

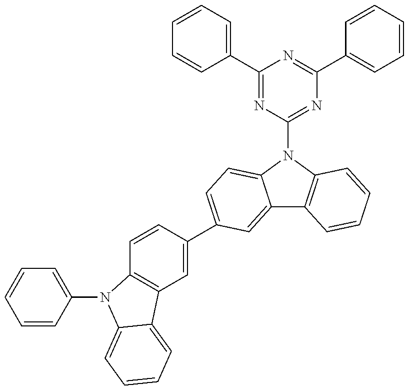 [SMILES: c1ccc(-c2nc(-c3ccccc3)nc(-n3c4ccccc4c4cc(-c5ccc6c(c5)c5ccccc5n6-c5ccccc5)ccc43)n2)cc1]

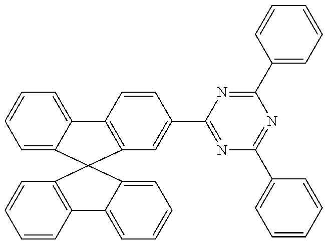 [SMILES: c1ccc(-c2nc(-c3ccccc3)nc(-c3ccc4c(c3)C3(c5ccccc5-c5ccccc53)c3ccccc3-4)n2)cc1]

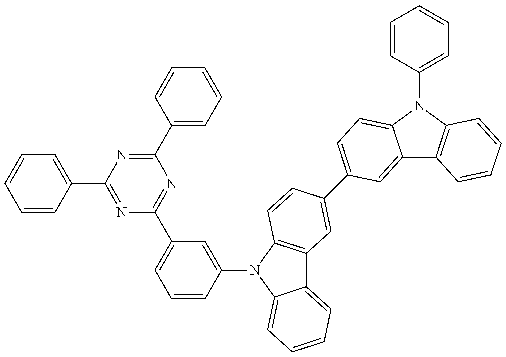 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

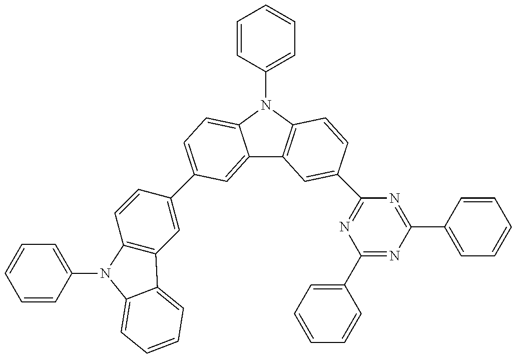 [SMILES: c1ccc(-c2nc(-c3ccccc3)nc(-c3ccc4c(c3)c3cc(-c5ccc6c(c5)c5ccccc5n6-c5ccccc5)ccc3n4-c3ccccc3)n2)cc1]

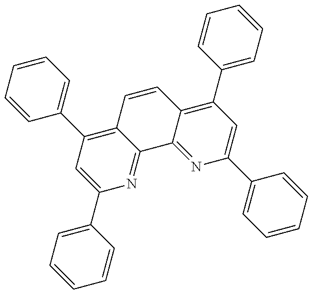 [SMILES: c1ccc(-c2cc(-c3ccccc3)c3ccc4c(-c5ccccc5)cc(-c5ccccc5)nc4c3n2)cc1]

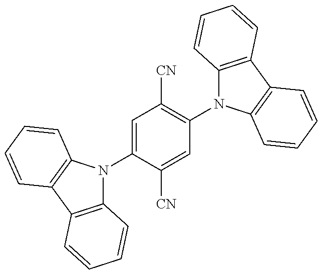 [SMILES: N#Cc1cc(-n2c3ccccc3c3ccccc32)c(C#N)cc1-n1c2ccccc2c2ccccc21]

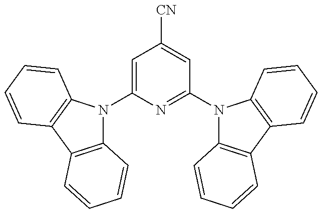 [SMILES: N#Cc1cc(-n2c3ccccc3c3ccccc32)nc(-n2c3ccccc3c3ccccc32)c1]

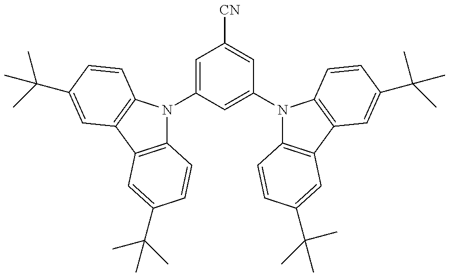 [SMILES: CC(C)(C)c1ccc2c(c1)c1cc(C(C)(C)C)ccc1n2-c1cc(C#N)cc(-n2c3ccc(C(C)(C)C)cc3c3cc(C(C)(C)C)ccc32)c1]

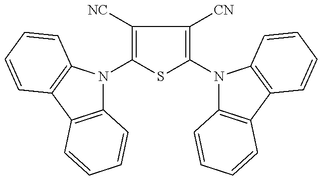 [SMILES: N#Cc1c(-n2c3ccccc3c3ccccc32)sc(-n2c3ccccc3c3ccccc32)c1C#N]

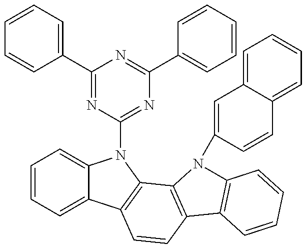 [SMILES: c1ccc(-c2nc(-c3ccccc3)nc(-n3c4ccccc4c4ccc5c6ccccc6n(-c6ccc7ccccc7c6)c5c43)n2)cc1]

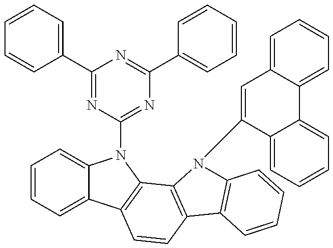 [SMILES: c1ccc(-c2nc(-c3ccccc3)nc(-n3c4ccccc4c4ccc5c6ccccc6n(-c6cc7ccccc7c7ccccc67)c5c43)n2)cc1]

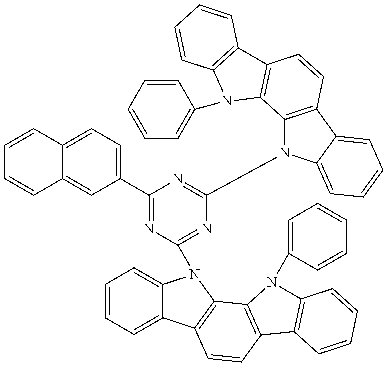 [SMILES: c1ccc(-n2c3ccccc3c3ccc4c5ccccc5n(-c5nc(-c6ccc7ccccc7c6)nc(-n6c7ccccc7c7ccc8c9ccccc9n(-c9ccccc9)c8c76)n5)c4c32)cc1]

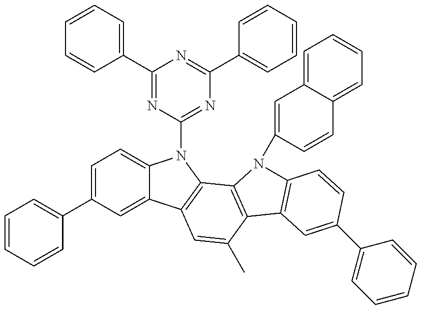 [SMILES: Cc1cc2c3cc(-c4ccccc4)ccc3n(-c3nc(-c4ccccc4)nc(-c4ccccc4)n3)c2c2c1c1cc(-c3ccccc3)ccc1n2-c1ccc2ccccc2c1]

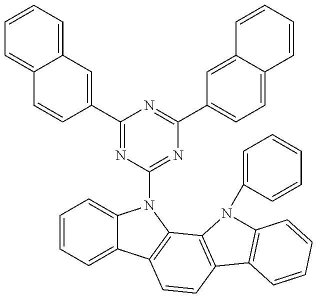 [SMILES: c1ccc(-n2c3ccccc3c3ccc4c5ccccc5n(-c5nc(-c6ccc7ccccc7c6)nc(-c6ccc7ccccc7c6)n5)c4c32)cc1]

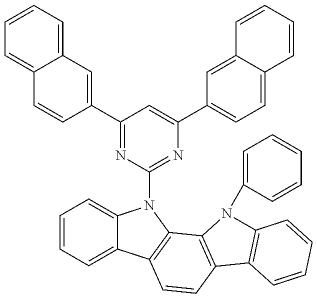 [SMILES: c1ccc(-n2c3ccccc3c3ccc4c5ccccc5n(-c5nc(-c6ccc7ccccc7c6)cc(-c6ccc7ccccc7c6)n5)c4c32)cc1]

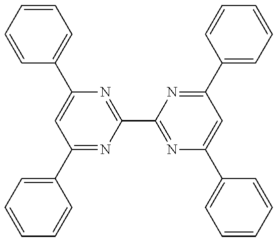 [SMILES: c1ccc(-c2cc(-c3ccccc3)nc(-c3nc(-c4ccccc4)cc(-c4ccccc4)n3)n2)cc1]

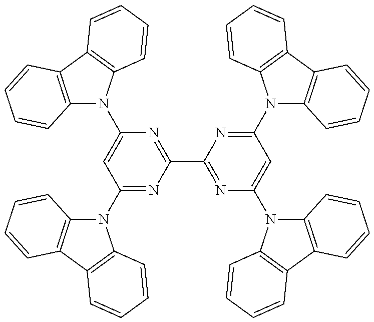 [SMILES: c1ccc2c(c1)c1ccccc1n2-c1cc(-n2c3ccccc3c3ccccc32)nc(-c2nc(-n3c4ccccc4c4ccccc43)cc(-n3c4ccccc4c4ccccc43)n2)n1]

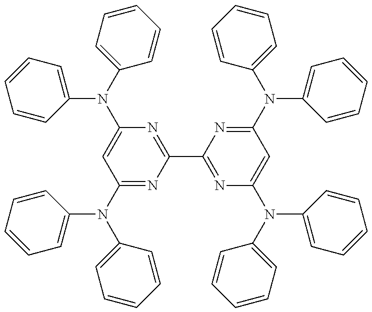 [SMILES: c1ccc(N(c2ccccc2)c2cc(N(c3ccccc3)c3ccccc3)nc(-c3nc(N(c4ccccc4)c4ccccc4)cc(N(c4ccccc4)c4ccccc4)n3)n2)cc1]

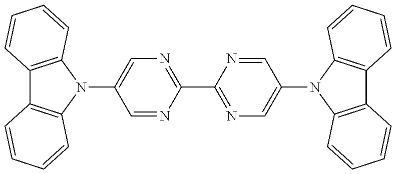 [SMILES: c1ccc2c(c1)c1ccccc1n2-c1cnc(-c2ncc(-n3c4ccccc4c4ccccc43)cn2)nc1]

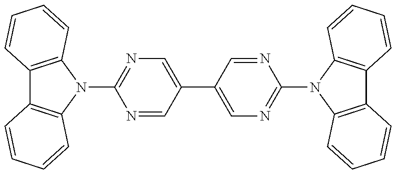 [SMILES: c1ccc2c(c1)c1ccccc1n2-c1ncc(-c2cnc(-n3c4ccccc4c4ccccc43)nc2)cn1]

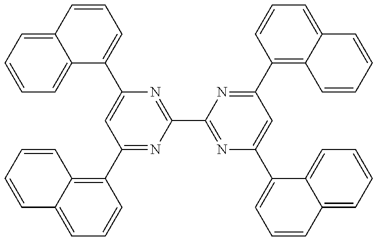 [SMILES: c1ccc2c(-c3cc(-c4cccc5ccccc45)nc(-c4nc(-c5cccc6ccccc56)cc(-c5cccc6ccccc56)n4)n3)cccc2c1]

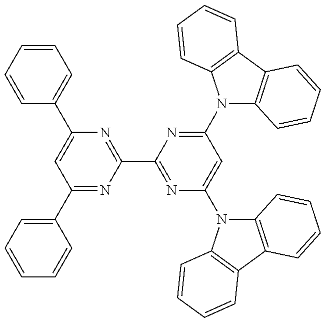 [SMILES: c1ccc(-c2cc(-c3ccccc3)nc(-c3nc(-n4c5ccccc5c5ccccc54)cc(-n4c5ccccc5c5ccccc54)n3)n2)cc1]

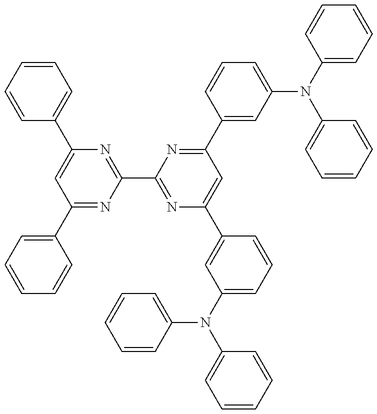 [SMILES: c1ccc(-c2cc(-c3ccccc3)nc(-c3nc(-c4cccc(N(c5ccccc5)c5ccccc5)c4)cc(-c4cccc(N(c5ccccc5)c5ccccc5)c4)n3)n2)cc1]

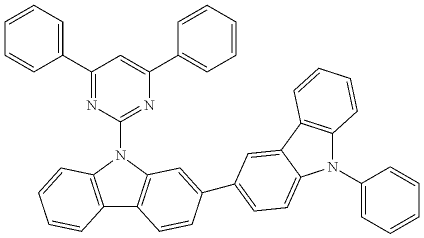 [SMILES: c1ccc(-c2cc(-c3ccccc3)nc(-n3c4ccccc4c4ccc(-c5ccc6c(c5)c5ccccc5n6-c5ccccc5)cc43)n2)cc1]

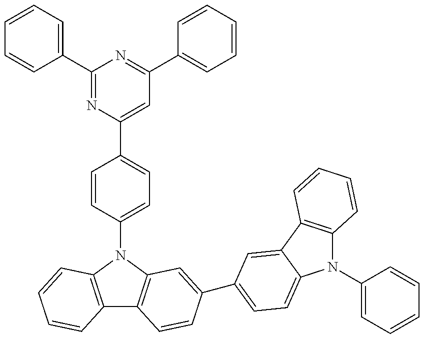 [SMILES: c1ccc(-c2cc(-c3ccc(-n4c5ccccc5c5ccc(-c6ccc7c(c6)c6ccccc6n7-c6ccccc6)cc54)cc3)nc(-c3ccccc3)n2)cc1]

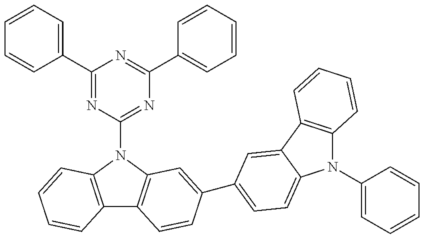 [SMILES: c1ccc(-c2nc(-c3ccccc3)nc(-n3c4ccccc4c4ccc(-c5ccc6c(c5)c5ccccc5n6-c5ccccc5)cc43)n2)cc1]

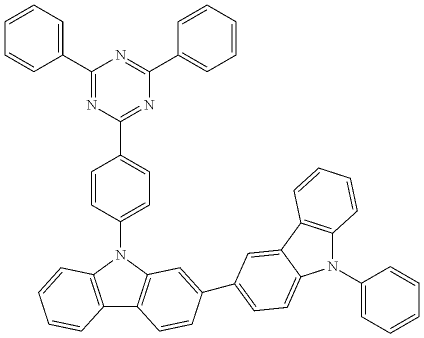 [SMILES: c1ccc(-c2nc(-c3ccccc3)nc(-c3ccc(-n4c5ccccc5c5ccc(-c6ccc7c(c6)c6ccccc6n7-c6ccccc6)cc54)cc3)n2)cc1]

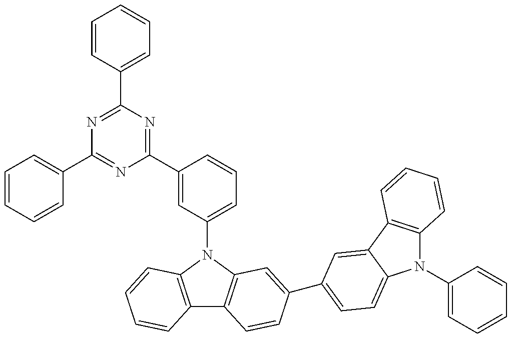 [SMILES: c1ccc(-c2nc(-c3ccccc3)nc(-c3cccc(-n4c5ccccc5c5ccc(-c6ccc7c(c6)c6ccccc6n7-c6ccccc6)cc54)c3)n2)cc1]

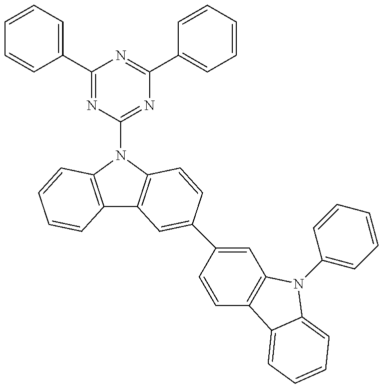 [SMILES: c1ccc(-c2nc(-c3ccccc3)nc(-n3c4ccccc4c4cc(-c5ccc6c7ccccc7n(-c7ccccc7)c6c5)ccc43)n2)cc1]

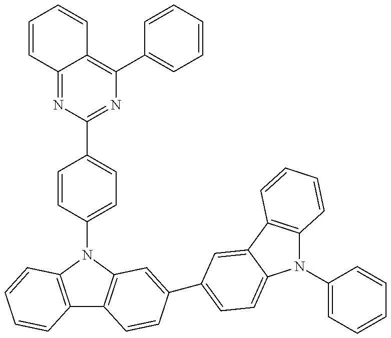 [SMILES: c1ccc(-c2nc(-c3ccc(-n4c5ccccc5c5ccc(-c6ccc7c(c6)c6ccccc6n7-c6ccccc6)cc54)cc3)nc3ccccc23)cc1]

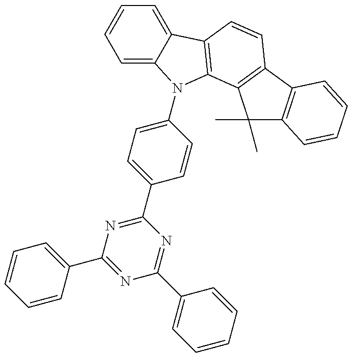 [SMILES: CC1(C)c2ccccc2-c2ccc3c4ccccc4n(-c4ccc(-c5nc(-c6ccccc6)nc(-c6ccccc6)n5)cc4)c3c21]

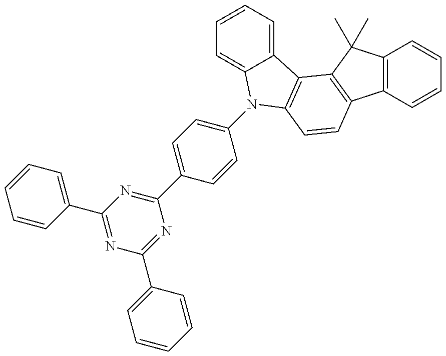 [SMILES: CC1(C)c2ccccc2-c2ccc3c(c21)c1ccccc1n3-c1ccc(-c2nc(-c3ccccc3)nc(-c3ccccc3)n2)cc1]

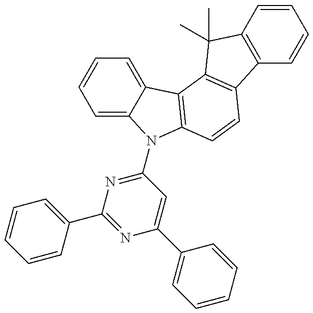 [SMILES: CC1(C)c2ccccc2-c2ccc3c(c21)c1ccccc1n3-c1cc(-c2ccccc2)nc(-c2ccccc2)n1]

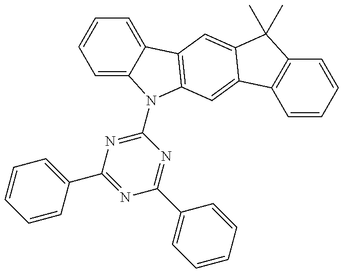 [SMILES: CC1(C)c2ccccc2-c2cc3c(cc21)c1ccccc1n3-c1nc(-c2ccccc2)nc(-c2ccccc2)n1]

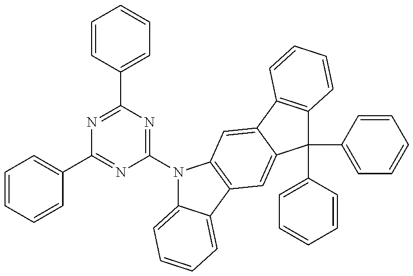 [SMILES: c1ccc(-c2nc(-c3ccccc3)nc(-n3c4ccccc4c4cc5c(cc43)-c3ccccc3C5(c3ccccc3)c3ccccc3)n2)cc1]

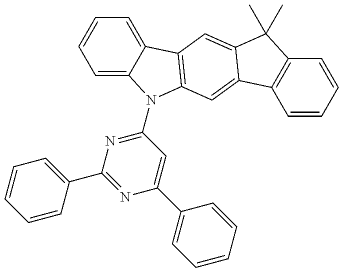 [SMILES: CC1(C)c2ccccc2-c2cc3c(cc21)c1ccccc1n3-c1cc(-c2ccccc2)nc(-c2ccccc2)n1]

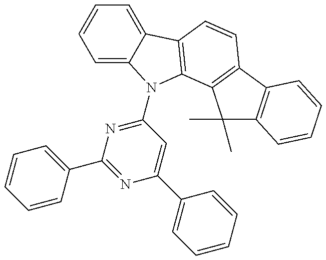 [SMILES: CC1(C)c2ccccc2-c2ccc3c4ccccc4n(-c4cc(-c5ccccc5)nc(-c5ccccc5)n4)c3c21]

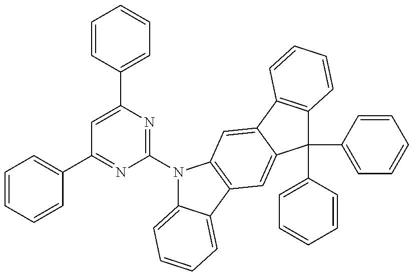 [SMILES: c1ccc(-c2cc(-c3ccccc3)nc(-n3c4ccccc4c4cc5c(cc43)-c3ccccc3C5(c3ccccc3)c3ccccc3)n2)cc1]

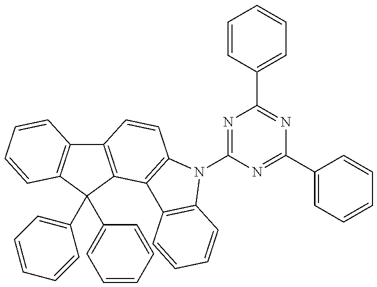 [SMILES: c1ccc(-c2nc(-c3ccccc3)nc(-n3c4ccccc4c4c5c(ccc43)-c3ccccc3C5(c3ccccc3)c3ccccc3)n2)cc1]

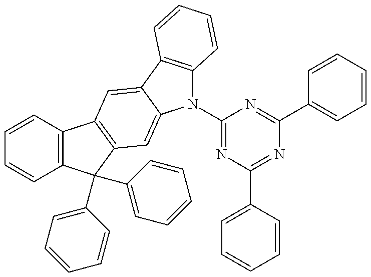 [SMILES: c1ccc(-c2nc(-c3ccccc3)nc(-n3c4ccccc4c4cc5c(cc43)C(c3ccccc3)(c3ccccc3)c3ccccc3-5)n2)cc1]

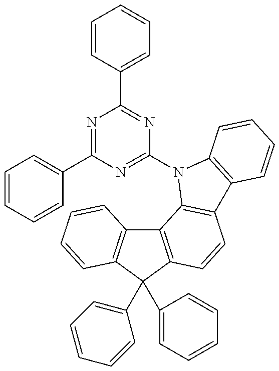 [SMILES: c1ccc(-c2nc(-c3ccccc3)nc(-n3c4ccccc4c4ccc5c(c43)-c3ccccc3C5(c3ccccc3)c3ccccc3)n2)cc1]

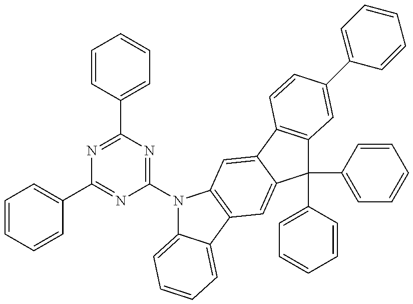 [SMILES: c1ccc(-c2ccc3c(c2)C(c2ccccc2)(c2ccccc2)c2cc4c5ccccc5n(-c5nc(-c6ccccc6)nc(-c6ccccc6)n5)c4cc2-3)cc1]

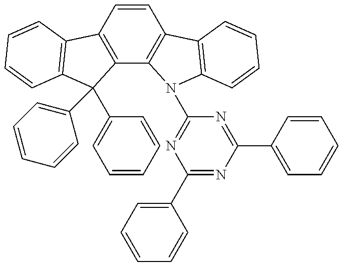 [SMILES: c1ccc(-c2nc(-c3ccccc3)nc(-n3c4ccccc4c4ccc5c(c43)C(c3ccccc3)(c3ccccc3)c3ccccc3-5)n2)cc1]

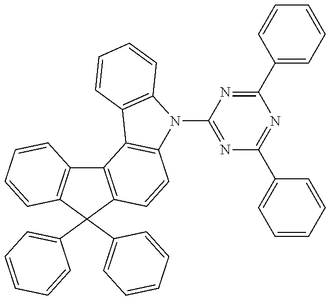 [SMILES: c1ccc(-c2nc(-c3ccccc3)nc(-n3c4ccccc4c4c5c(ccc43)C(c3ccccc3)(c3ccccc3)c3ccccc3-5)n2)cc1]

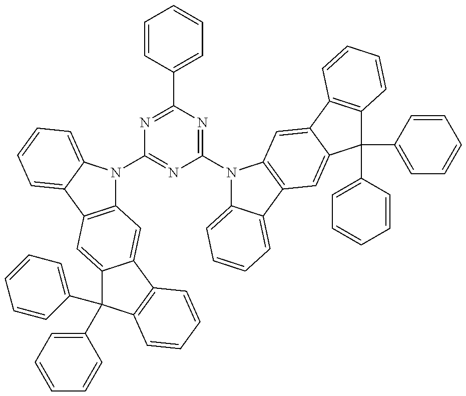 [SMILES: c1ccc(-c2nc(-n3c4ccccc4c4cc5c(cc43)-c3ccccc3C5(c3ccccc3)c3ccccc3)nc(-n3c4ccccc4c4cc5c(cc43)-c3ccccc3C5(c3ccccc3)c3ccccc3)n2)cc1]

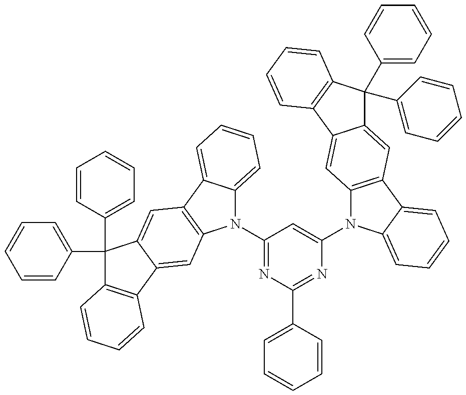 [SMILES: c1ccc(-c2nc(-n3c4ccccc4c4cc5c(cc43)-c3ccccc3C5(c3ccccc3)c3ccccc3)cc(-n3c4ccccc4c4cc5c(cc43)-c3ccccc3C5(c3ccccc3)c3ccccc3)n2)cc1]

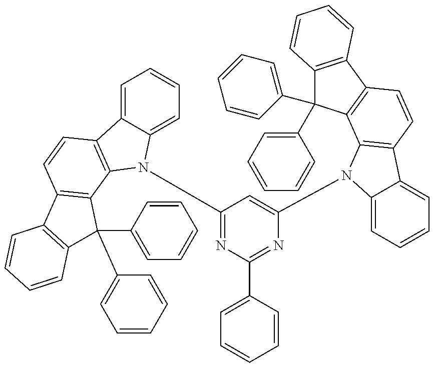 [SMILES: c1ccc(-c2nc(-n3c4ccccc4c4ccc5c(c43)C(c3ccccc3)(c3ccccc3)c3ccccc3-5)cc(-n3c4ccccc4c4ccc5c(c43)C(c3ccccc3)(c3ccccc3)c3ccccc3-5)n2)cc1]

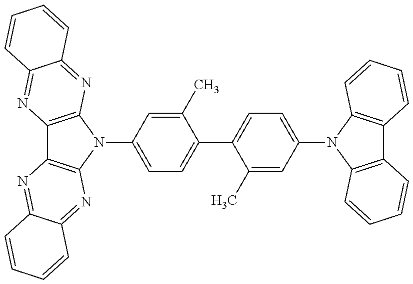 [SMILES: Cc1cc(-n2c3ccccc3c3ccccc32)ccc1-c1ccc(-n2c3nc4ccccc4nc3c3nc4ccccc4nc32)cc1C]

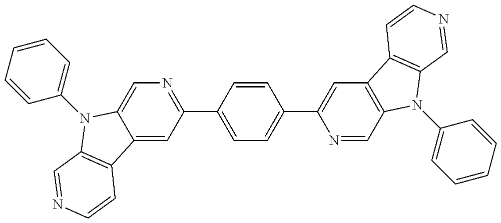 [SMILES: c1ccc(-n2c3cnccc3c3cc(-c4ccc(-c5cc6c7ccncc7n(-c7ccccc7)c6cn5)cc4)ncc32)cc1]

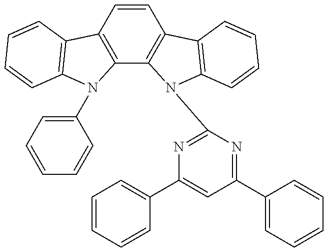 [SMILES: c1ccc(-c2cc(-c3ccccc3)nc(-n3c4ccccc4c4ccc5c6ccccc6n(-c6ccccc6)c5c43)n2)cc1]

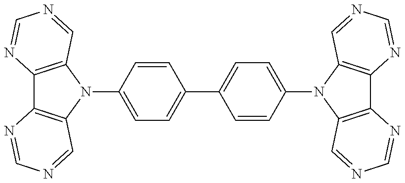 [SMILES: c1ncc2c(n1)c1ncncc1n2-c1ccc(-c2ccc(-n3c4cncnc4c4ncncc43)cc2)cc1]

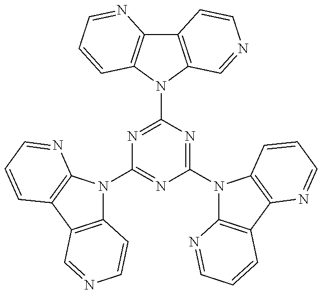 [SMILES: c1cnc2c(c1)c1cnccc1n2-c1nc(-n2c3cnccc3c3ncccc32)nc(-n2c3cccnc3c3cccnc32)n1]

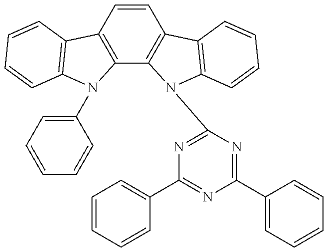 [SMILES: c1ccc(-c2nc(-c3ccccc3)nc(-n3c4ccccc4c4ccc5c6ccccc6n(-c6ccccc6)c5c43)n2)cc1]

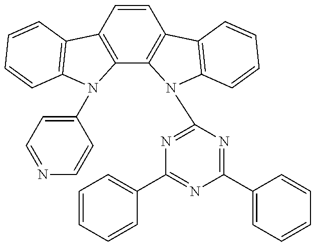 [SMILES: c1ccc(-c2nc(-c3ccccc3)nc(-n3c4ccccc4c4ccc5c6ccccc6n(-c6ccncc6)c5c43)n2)cc1]

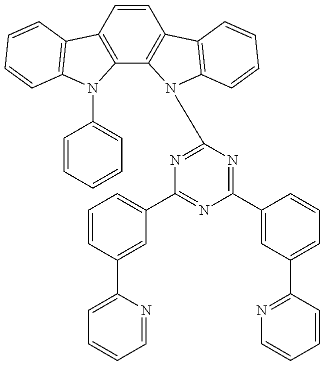 [SMILES: c1ccc(-n2c3ccccc3c3ccc4c5ccccc5n(-c5nc(-c6cccc(-c7ccccn7)c6)nc(-c6cccc(-c7ccccn7)c6)n5)c4c32)cc1]

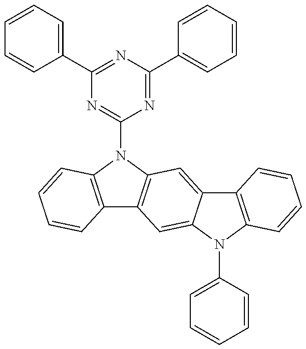 [SMILES: c1ccc(-c2nc(-c3ccccc3)nc(-n3c4ccccc4c4cc5c(cc43)c3ccccc3n5-c3ccccc3)n2)cc1]

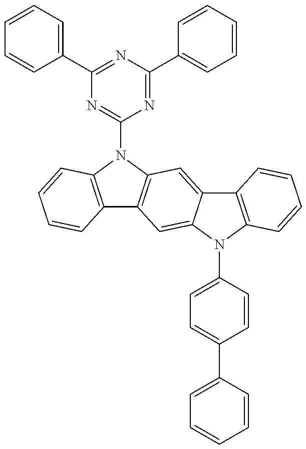 [SMILES: c1ccc(-c2ccc(-n3c4ccccc4c4cc5c(cc43)c3ccccc3n5-c3nc(-c4ccccc4)nc(-c4ccccc4)n3)cc2)cc1]

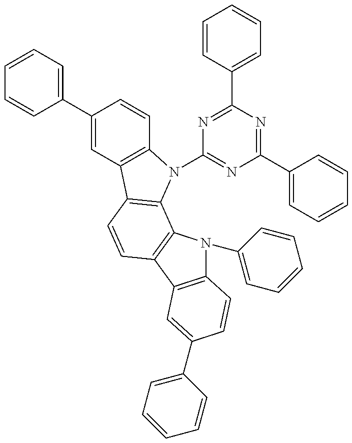 [SMILES: c1ccc(-c2ccc3c(c2)c2ccc4c5cc(-c6ccccc6)ccc5n(-c5nc(-c6ccccc6)nc(-c6ccccc6)n5)c4c2n3-c2ccccc2)cc1]

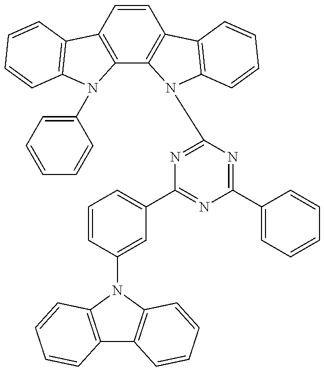 [SMILES: c1ccc(-c2nc(-c3cccc(-n4c5ccccc5c5ccccc54)c3)nc(-n3c4ccccc4c4ccc5c6ccccc6n(-c6ccccc6)c5c43)n2)cc1]

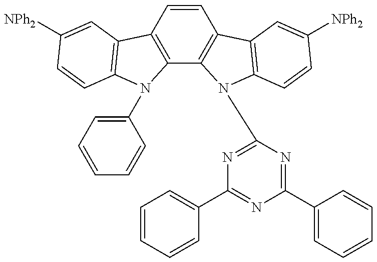

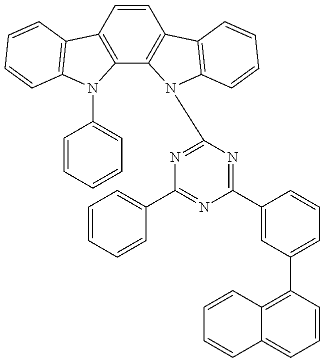 [SMILES: c1ccc(-c2nc(-c3cccc(-c4cccc5ccccc45)c3)nc(-n3c4ccccc4c4ccc5c6ccccc6n(-c6ccccc6)c5c43)n2)cc1]

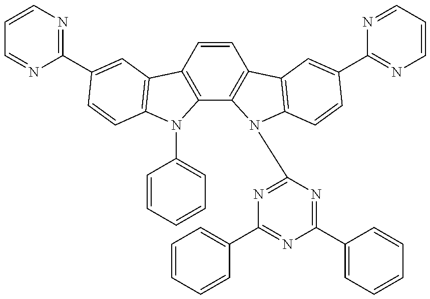 [SMILES: c1ccc(-c2nc(-c3ccccc3)nc(-n3c4ccc(-c5ncccn5)cc4c4ccc5c6cc(-c7ncccn7)ccc6n(-c6ccccc6)c5c43)n2)cc1]

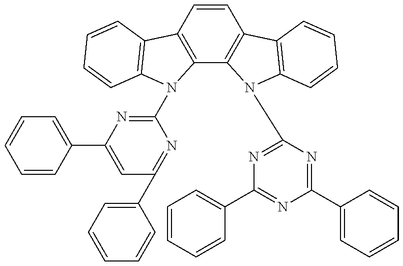 [SMILES: c1ccc(-c2cc(-c3ccccc3)nc(-n3c4ccccc4c4ccc5c6ccccc6n(-c6nc(-c7ccccc7)nc(-c7ccccc7)n6)c5c43)n2)cc1]

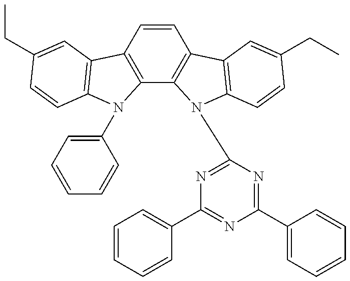 [SMILES: CCc1ccc2c(c1)c1ccc3c4cc(CC)ccc4n(-c4nc(-c5ccccc5)nc(-c5ccccc5)n4)c3c1n2-c1ccccc1]

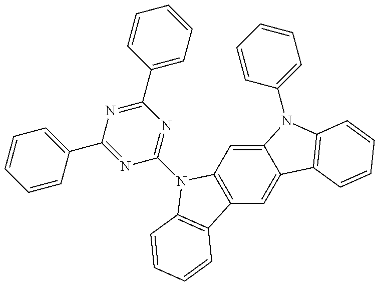 [SMILES: c1ccc(-c2nc(-c3ccccc3)nc(-n3c4ccccc4c4cc5c6ccccc6n(-c6ccccc6)c5cc43)n2)cc1]

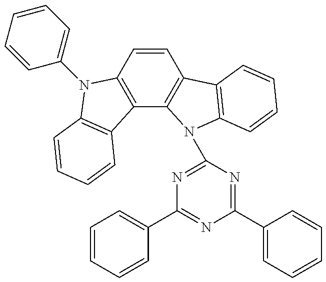 [SMILES: c1ccc(-c2nc(-c3ccccc3)nc(-n3c4ccccc4c4ccc5c(c6ccccc6n5-c5ccccc5)c43)n2)cc1]

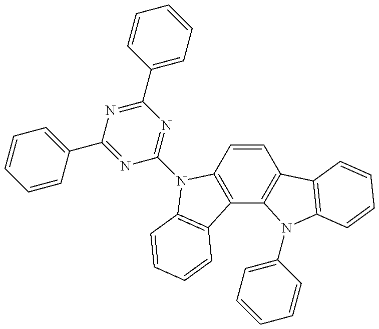 [SMILES: c1ccc(-c2nc(-c3ccccc3)nc(-n3c4ccccc4c4c3ccc3c5ccccc5n(-c5ccccc5)c34)n2)cc1]

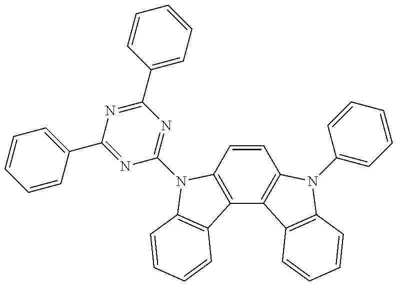 [SMILES: c1ccc(-c2nc(-c3ccccc3)nc(-n3c4ccccc4c4c5c6ccccc6n(-c6ccccc6)c5ccc43)n2)cc1]

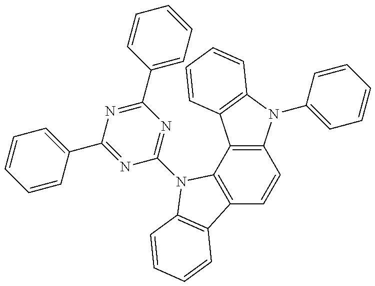 [SMILES: c1ccc(-c2nc(-c3ccccc3)nc(-n3c4ccccc4c4ccc5c(c6ccccc6n5-c5ccccc5)c43)n2)cc1]

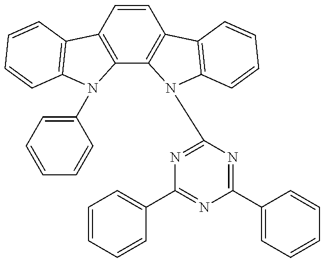 [SMILES: c1ccc(-c2nc(-c3ccccc3)nc(-n3c4ccccc4c4ccc5c6ccccc6n(-c6ccccc6)c5c43)n2)cc1]

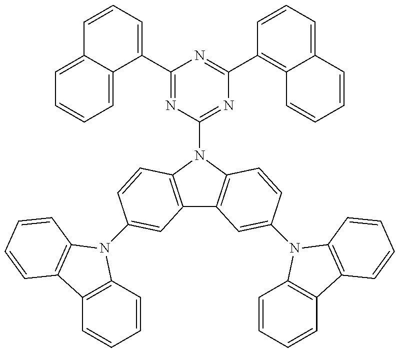 [SMILES: c1ccc2c(-c3nc(-c4cccc5ccccc45)nc(-n4c5ccc(-n6c7ccccc7c7ccccc76)cc5c5cc(-n6c7ccccc7c7ccccc76)ccc54)n3)cccc2c1]

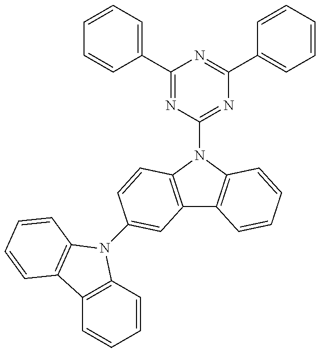 [SMILES: c1ccc(-c2nc(-c3ccccc3)nc(-n3c4ccccc4c4cc(-n5c6ccccc6c6ccccc65)ccc43)n2)cc1]

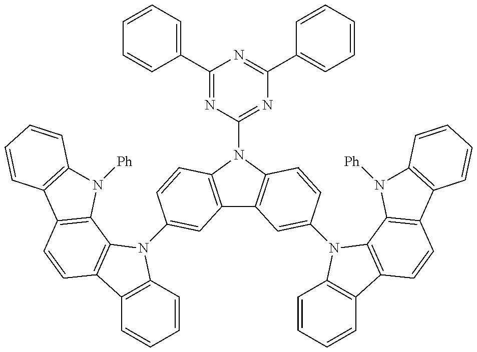 [SMILES: c1ccc(-c2nc(-c3ccccc3)nc(-n3c4ccc(-n5c6ccccc6c6ccc7c8ccccc8n(-c8ccccc8)c7c65)cc4c4cc(-n5c6ccccc6c6ccc7c8ccccc8n(-c8ccccc8)c7c65)ccc43)n2)cc1]

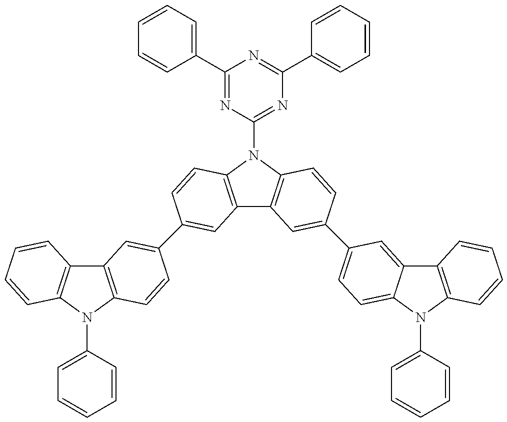 [SMILES: c1ccc(-c2nc(-c3ccccc3)nc(-n3c4ccc(-c5ccc6c(c5)c5ccccc5n6-c5ccccc5)cc4c4cc(-c5ccc6c(c5)c5ccccc5n6-c5ccccc5)ccc43)n2)cc1]

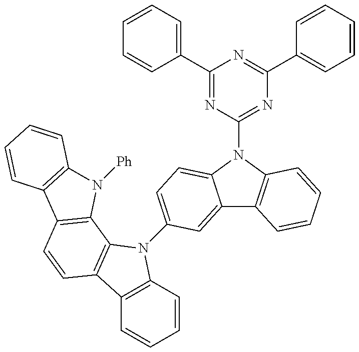 [SMILES: c1ccc(-c2nc(-c3ccccc3)nc(-n3c4ccccc4c4cc(-n5c6ccccc6c6ccc7c8ccccc8n(-c8ccccc8)c7c65)ccc43)n2)cc1]

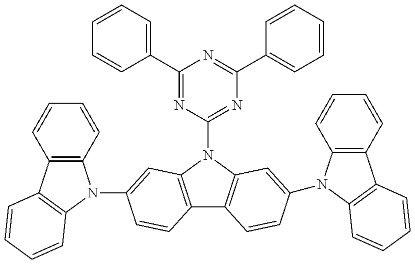 [SMILES: c1ccc(-c2nc(-c3ccccc3)nc(-n3c4cc(-n5c6ccccc6c6ccccc65)ccc4c4ccc(-n5c6ccccc6c6ccccc65)cc43)n2)cc1]

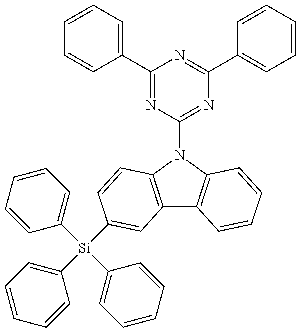 [SMILES: c1ccc(-c2nc(-c3ccccc3)nc(-n3c4ccccc4c4cc([Si](c5ccccc5)(c5ccccc5)c5ccccc5)ccc43)n2)cc1]

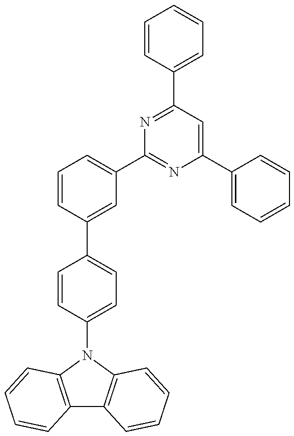 [SMILES: c1ccc(-c2cc(-c3ccccc3)nc(-c3cccc(-c4ccc(-n5c6ccccc6c6ccccc65)cc4)c3)n2)cc1]

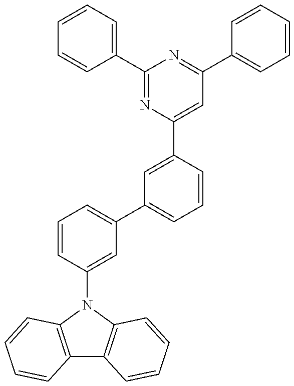 [SMILES: c1ccc(-c2cc(-c3cccc(-c4cccc(-n5c6ccccc6c6ccccc65)c4)c3)nc(-c3ccccc3)n2)cc1]

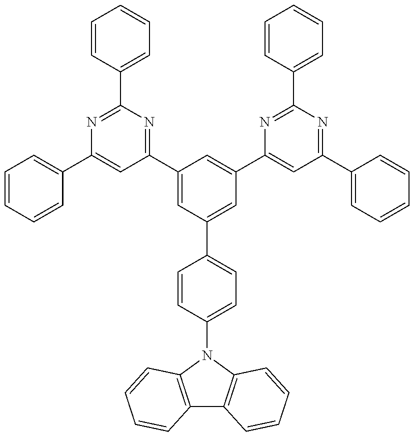 [SMILES: c1ccc(-c2cc(-c3cc(-c4ccc(-n5c6ccccc6c6ccccc65)cc4)cc(-c4cc(-c5ccccc5)nc(-c5ccccc5)n4)c3)nc(-c3ccccc3)n2)cc1]

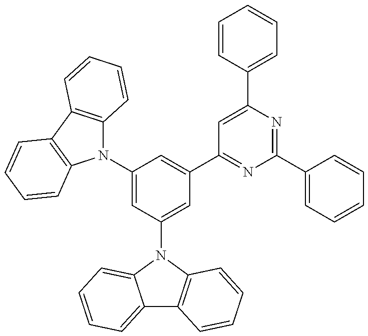 [SMILES: c1ccc(-c2cc(-c3cc(-n4c5ccccc5c5ccccc54)cc(-n4c5ccccc5c5ccccc54)c3)nc(-c3ccccc3)n2)cc1]

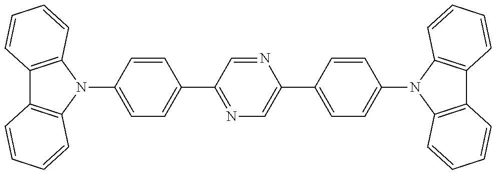 [SMILES: c1ccc2c(c1)c1ccccc1n2-c1ccc(-c2cnc(-c3ccc(-n4c5ccccc5c5ccccc54)cc3)cn2)cc1]

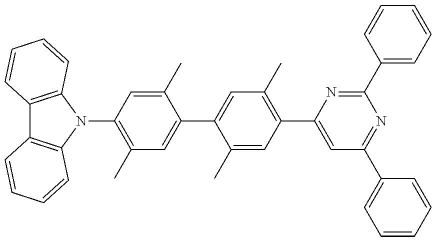 [SMILES: Cc1cc(-c2cc(C)c(-n3c4ccccc4c4ccccc43)cc2C)c(C)cc1-c1cc(-c2ccccc2)nc(-c2ccccc2)n1]

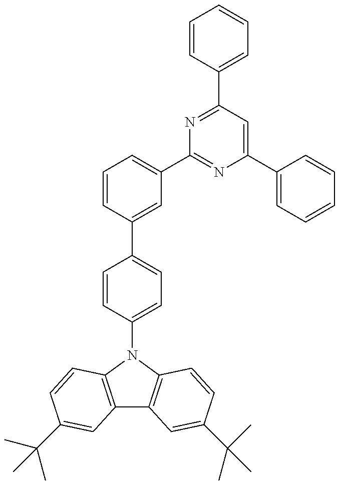 [SMILES: CC(C)(C)c1ccc2c(c1)c1cc(C(C)(C)C)ccc1n2-c1ccc(-c2cccc(-c3nc(-c4ccccc4)cc(-c4ccccc4)n3)c2)cc1]

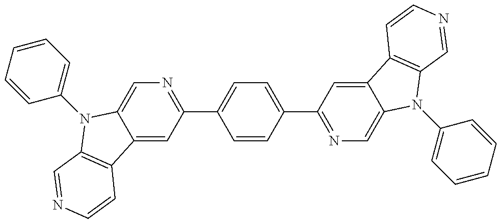 [SMILES: c1ccc(-n2c3cnccc3c3cc(-c4ccc(-c5cc6c7ccncc7n(-c7ccccc7)c6cn5)cc4)ncc32)cc1]

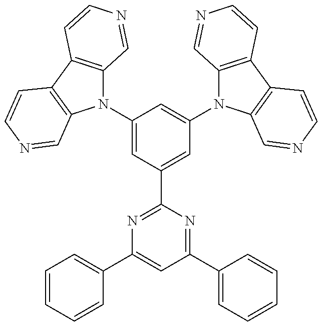 [SMILES: c1ccc(-c2cc(-c3ccccc3)nc(-c3cc(-n4c5cnccc5c5ccncc54)cc(-n4c5cnccc5c5ccncc54)c3)n2)cc1]

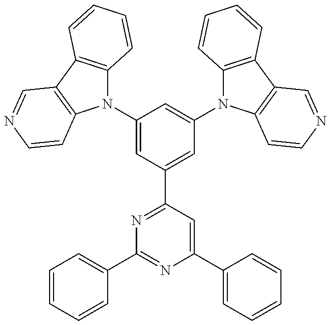 [SMILES: c1ccc(-c2cc(-c3cc(-n4c5ccccc5c5cnccc54)cc(-n4c5ccccc5c5cnccc54)c3)nc(-c3ccccc3)n2)cc1]

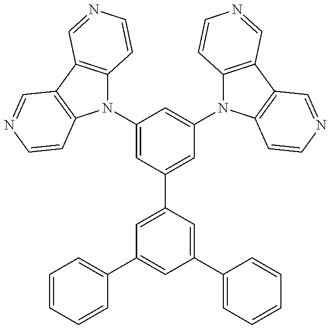 [SMILES: c1ccc(-c2cc(-c3ccccc3)cc(-c3cc(-n4c5ccncc5c5cnccc54)cc(-n4c5ccncc5c5cnccc54)c3)c2)cc1]

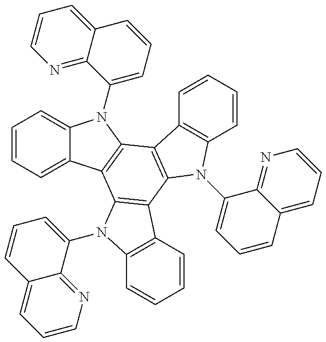 [SMILES: c1cnc2c(-n3c4ccccc4c4c3c3c5ccccc5n(-c5cccc6cccnc56)c3c3c5ccccc5n(-c5cccc6cccnc56)c43)cccc2c1]

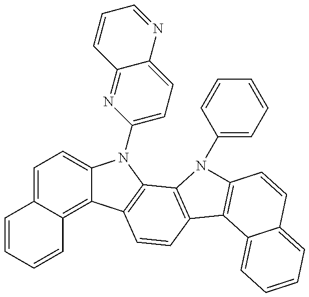 [SMILES: c1ccc(-n2c3ccc4ccccc4c3c3ccc4c5c6ccccc6ccc5n(-c5ccc6ncccc6n5)c4c32)cc1]

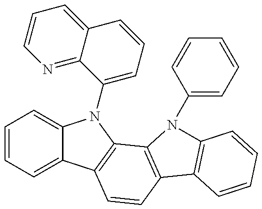 [SMILES: c1ccc(-n2c3ccccc3c3ccc4c5ccccc5n(-c5cccc6cccnc56)c4c32)cc1]

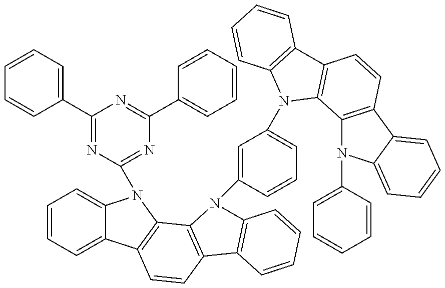 [SMILES: c1ccc(-c2nc(-c3ccccc3)nc(-n3c4ccccc4c4ccc5c6ccccc6n(-c6cccc(-n7c8ccccc8c8ccc9c%10ccccc%10n(-c%10ccccc%10)c9c87)c6)c5c43)n2)cc1]

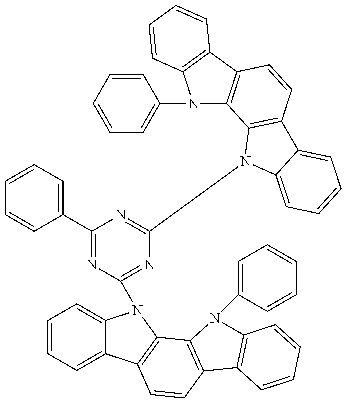 [SMILES: c1ccc(-c2nc(-n3c4ccccc4c4ccc5c6ccccc6n(-c6ccccc6)c5c43)nc(-n3c4ccccc4c4ccc5c6ccccc6n(-c6ccccc6)c5c43)n2)cc1]

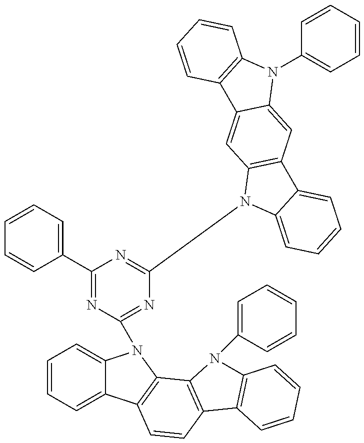 [SMILES: c1ccc(-c2nc(-n3c4ccccc4c4cc5c(cc43)c3ccccc3n5-c3ccccc3)nc(-n3c4ccccc4c4ccc5c6ccccc6n(-c6ccccc6)c5c43)n2)cc1]

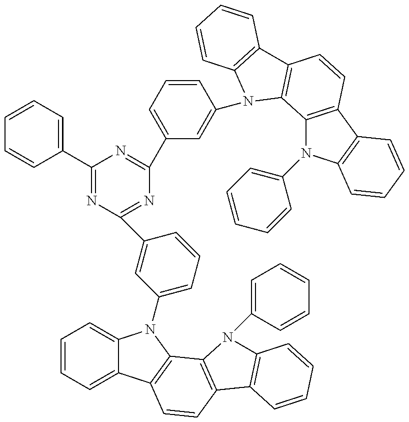 [SMILES: c1ccc(-c2nc(-c3cccc(-n4c5ccccc5c5ccc6c7ccccc7n(-c7ccccc7)c6c54)c3)nc(-c3cccc(-n4c5ccccc5c5ccc6c7ccccc7n(-c7ccccc7)c6c54)c3)n2)cc1]

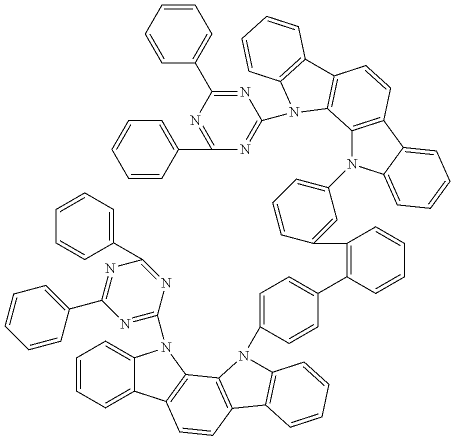 [SMILES: c1ccc(-c2nc(-c3ccccc3)nc(-n3c4ccccc4c4ccc5c6ccccc6n(-c6ccc(-c7ccccc7-c7cccc(-n8c9ccccc9c9ccc%10c%11ccccc%11n(-c%11nc(-c%12ccccc%12)nc(-c%12ccccc%12)n%11)c%10c98)c7)cc6)c5c43)n2)cc1]

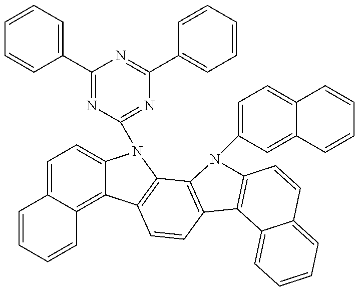 [SMILES: c1ccc(-c2nc(-c3ccccc3)nc(-n3c4ccc5ccccc5c4c4ccc5c6c7ccccc7ccc6n(-c6ccc7ccccc7c6)c5c43)n2)cc1]

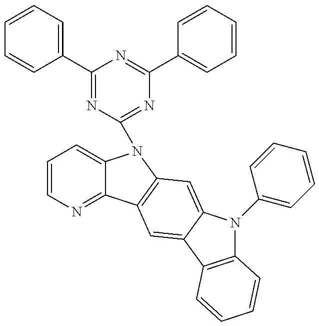 [SMILES: c1ccc(-c2nc(-c3ccccc3)nc(-n3c4cc5c(cc4c4ncccc43)c3ccccc3n5-c3ccccc3)n2)cc1]

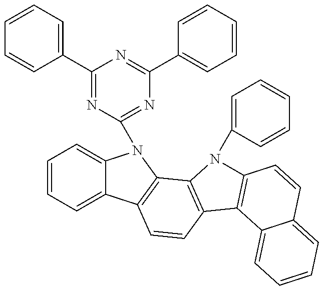 [SMILES: c1ccc(-c2nc(-c3ccccc3)nc(-n3c4ccccc4c4ccc5c6c7ccccc7ccc6n(-c6ccccc6)c5c43)n2)cc1]

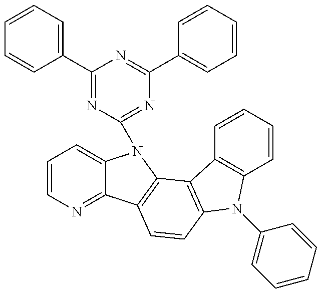 [SMILES: c1ccc(-c2nc(-c3ccccc3)nc(-n3c4cccnc4c4ccc5c(c6ccccc6n5-c5ccccc5)c43)n2)cc1]

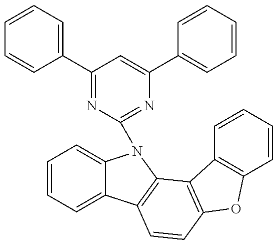 [SMILES: c1ccc(-c2cc(-c3ccccc3)nc(-n3c4ccccc4c4ccc5oc6ccccc6c5c43)n2)cc1]

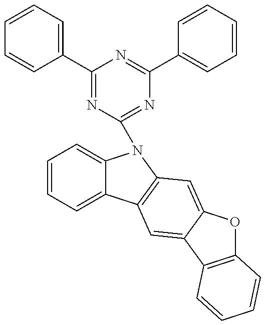 [SMILES: c1ccc(-c2nc(-c3ccccc3)nc(-n3c4ccccc4c4cc5c(cc43)oc3ccccc35)n2)cc1]

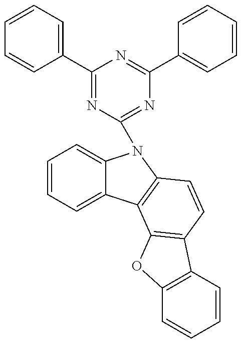 [SMILES: c1ccc(-c2nc(-c3ccccc3)nc(-n3c4ccccc4c4c5oc6ccccc6c5ccc43)n2)cc1]

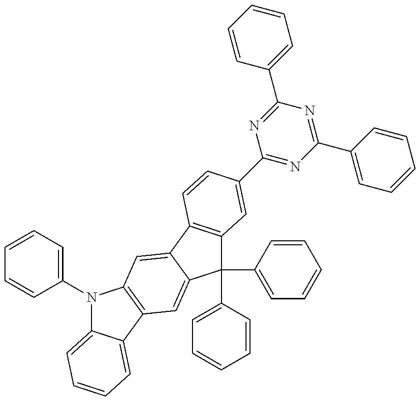 [SMILES: c1ccc(-c2nc(-c3ccccc3)nc(-c3ccc4c(c3)C(c3ccccc3)(c3ccccc3)c3cc5c6ccccc6n(-c6ccccc6)c5cc3-4)n2)cc1]

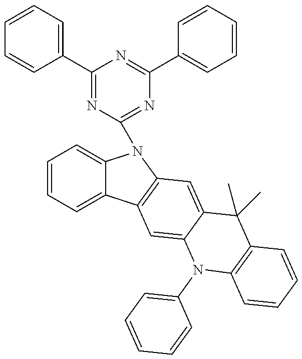 [SMILES: CC1(C)c2ccccc2N(c2ccccc2)c2cc3c4ccccc4n(-c4nc(-c5ccccc5)nc(-c5ccccc5)n4)c3cc21]

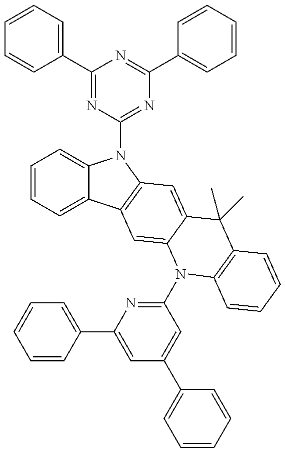 [SMILES: CC1(C)c2ccccc2N(c2cc(-c3ccccc3)cc(-c3ccccc3)n2)c2cc3c4ccccc4n(-c4nc(-c5ccccc5)nc(-c5ccccc5)n4)c3cc21]

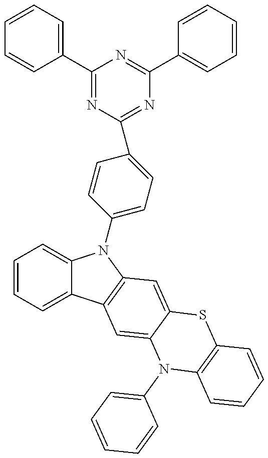 [SMILES: c1ccc(-c2nc(-c3ccccc3)nc(-c3ccc(-n4c5ccccc5c5cc6c(cc54)Sc4ccccc4N6c4ccccc4)cc3)n2)cc1]

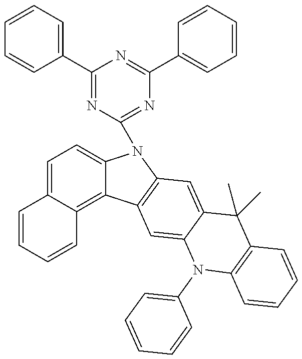 [SMILES: CC1(C)c2ccccc2N(c2ccccc2)c2cc3c4c5ccccc5ccc4n(-c4nc(-c5ccccc5)nc(-c5ccccc5)n4)c3cc21]

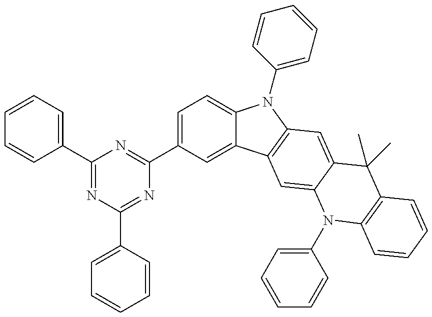 [SMILES: CC1(C)c2ccccc2N(c2ccccc2)c2cc3c4cc(-c5nc(-c6ccccc6)nc(-c6ccccc6)n5)ccc4n(-c4ccccc4)c3cc21]

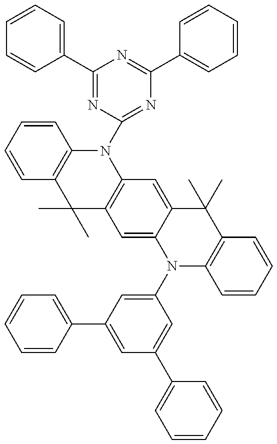 [SMILES: CC1(C)c2ccccc2N(c2cc(-c3ccccc3)cc(-c3ccccc3)c2)c2cc3c(cc21)N(c1nc(-c2ccccc2)nc(-c2ccccc2)n1)c1ccccc1C3(C)C]

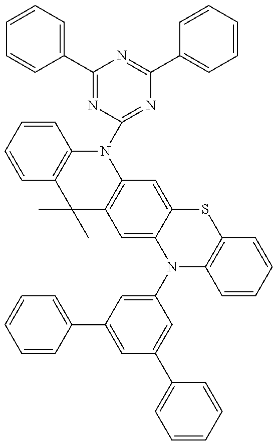 [SMILES: CC1(C)c2ccccc2N(c2nc(-c3ccccc3)nc(-c3ccccc3)n2)c2cc3c(cc21)N(c1cc(-c2ccccc2)cc(-c2ccccc2)c1)c1ccccc1S3]

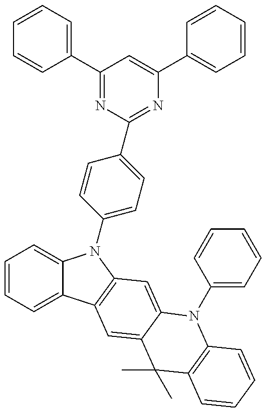 [SMILES: CC1(C)c2ccccc2N(c2ccccc2)c2cc3c(cc21)c1ccccc1n3-c1ccc(-c2nc(-c3ccccc3)cc(-c3ccccc3)n2)cc1]

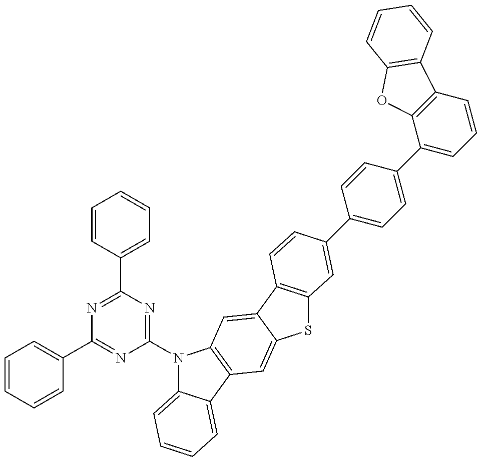 [SMILES: c1ccc(-c2nc(-c3ccccc3)nc(-n3c4ccccc4c4cc5sc6cc(-c7ccc(-c8cccc9c8oc8ccccc89)cc7)ccc6c5cc43)n2)cc1]

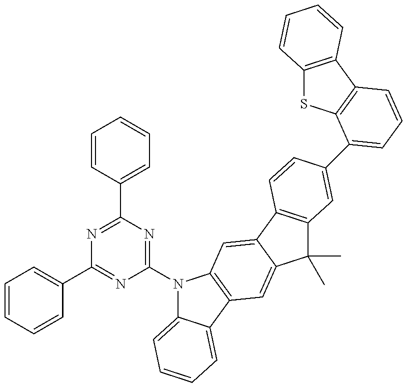 [SMILES: CC1(C)c2cc(-c3cccc4c3sc3ccccc34)ccc2-c2cc3c(cc21)c1ccccc1n3-c1nc(-c2ccccc2)nc(-c2ccccc2)n1]

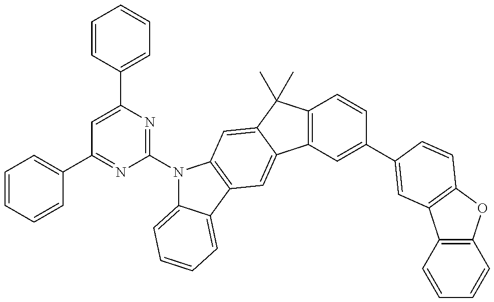 [SMILES: CC1(C)c2ccc(-c3ccc4oc5ccccc5c4c3)cc2-c2cc3c4ccccc4n(-c4nc(-c5ccccc5)cc(-c5ccccc5)n4)c3cc21]

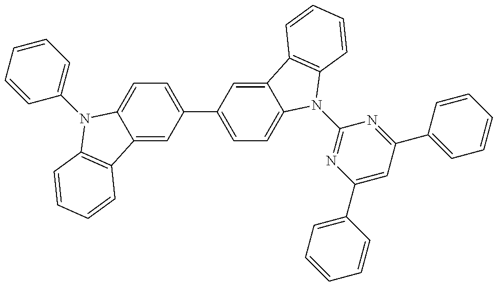 [SMILES: c1ccc(-c2cc(-c3ccccc3)nc(-n3c4ccccc4c4cc(-c5ccc6c(c5)c5ccccc5n6-c5ccccc5)ccc43)n2)cc1]

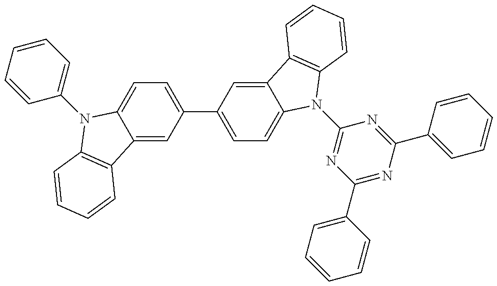 [SMILES: c1ccc(-c2nc(-c3ccccc3)nc(-n3c4ccccc4c4cc(-c5ccc6c(c5)c5ccccc5n6-c5ccccc5)ccc43)n2)cc1]

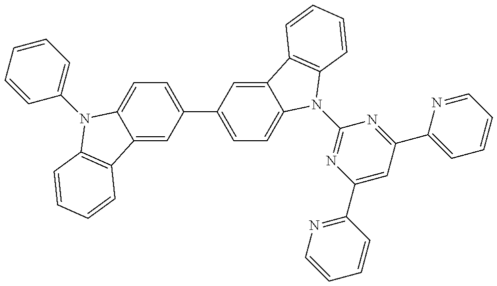 [SMILES: c1ccc(-n2c3ccccc3c3cc(-c4ccc5c(c4)c4ccccc4n5-c4nc(-c5ccccn5)cc(-c5ccccn5)n4)ccc32)cc1]

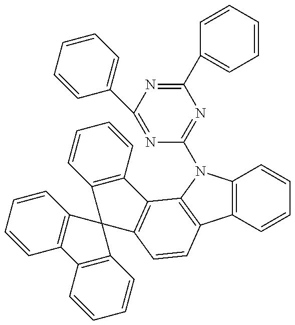 [SMILES: c1ccc(-c2nc(-c3ccccc3)nc(-n3c4ccccc4c4ccc5c(c43)-c3ccccc3C53c4ccccc4-c4ccccc43)n2)cc1]

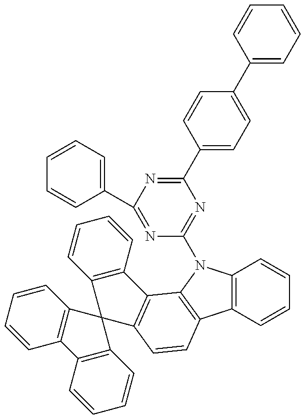 [SMILES: c1ccc(-c2ccc(-c3nc(-c4ccccc4)nc(-n4c5ccccc5c5ccc6c(c54)-c4ccccc4C64c5ccccc5-c5ccccc54)n3)cc2)cc1]

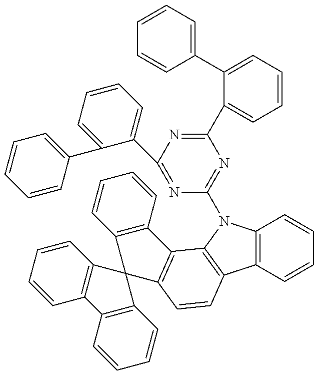 [SMILES: c1ccc(-c2ccccc2-c2nc(-c3ccccc3-c3ccccc3)nc(-n3c4ccccc4c4ccc5c(c43)-c3ccccc3C53c4ccccc4-c4ccccc43)n2)cc1]

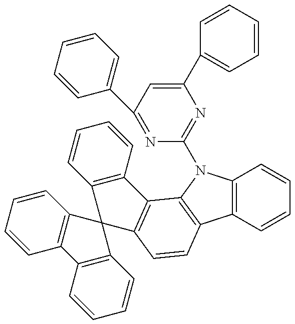 [SMILES: c1ccc(-c2cc(-c3ccccc3)nc(-n3c4ccccc4c4ccc5c(c43)-c3ccccc3C53c4ccccc4-c4ccccc43)n2)cc1]

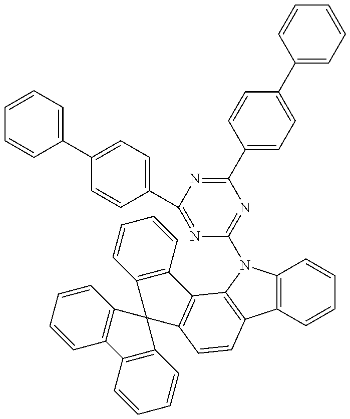 [SMILES: c1ccc(-c2ccc(-c3nc(-c4ccc(-c5ccccc5)cc4)nc(-n4c5ccccc5c5ccc6c(c54)-c4ccccc4C64c5ccccc5-c5ccccc54)n3)cc2)cc1]

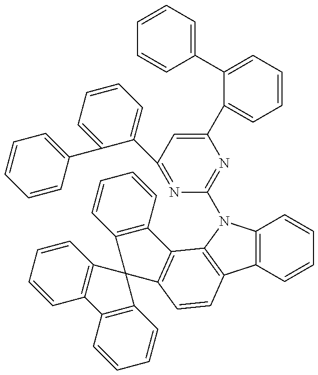 [SMILES: c1ccc(-c2ccccc2-c2cc(-c3ccccc3-c3ccccc3)nc(-n3c4ccccc4c4ccc5c(c43)-c3ccccc3C53c4ccccc4-c4ccccc43)n2)cc1]

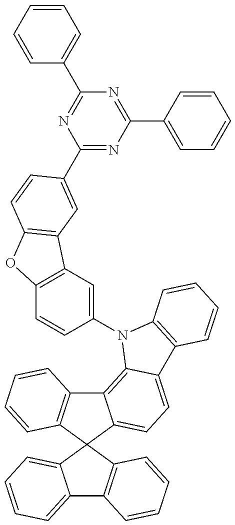 [SMILES: c1ccc(-c2nc(-c3ccccc3)nc(-c3ccc4oc5ccc(-n6c7ccccc7c7ccc8c(c76)-c6ccccc6C86c7ccccc7-c7ccccc76)cc5c4c3)n2)cc1]

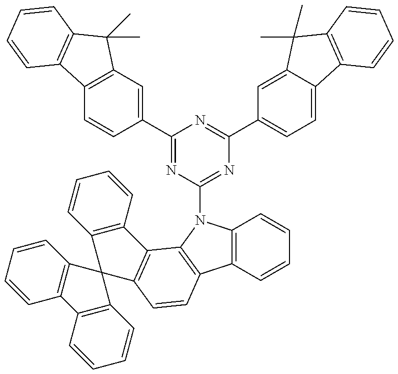 [SMILES: CC1(C)c2ccccc2-c2ccc(-c3nc(-c4ccc5c(c4)C(C)(C)c4ccccc4-5)nc(-n4c5ccccc5c5ccc6c(c54)-c4ccccc4C64c5ccccc5-c5ccccc54)n3)cc21]

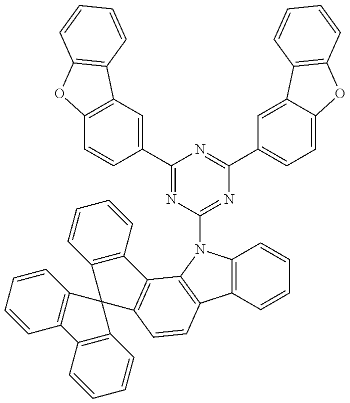 [SMILES: c1ccc2c(c1)-c1ccccc1C21c2ccccc2-c2c1ccc1c3ccccc3n(-c3nc(-c4ccc5oc6ccccc6c5c4)nc(-c4ccc5oc6ccccc6c5c4)n3)c21]

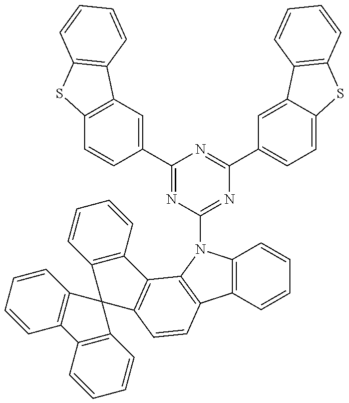 [SMILES: c1ccc2c(c1)-c1ccccc1C21c2ccccc2-c2c1ccc1c3ccccc3n(-c3nc(-c4ccc5sc6ccccc6c5c4)nc(-c4ccc5sc6ccccc6c5c4)n3)c21]

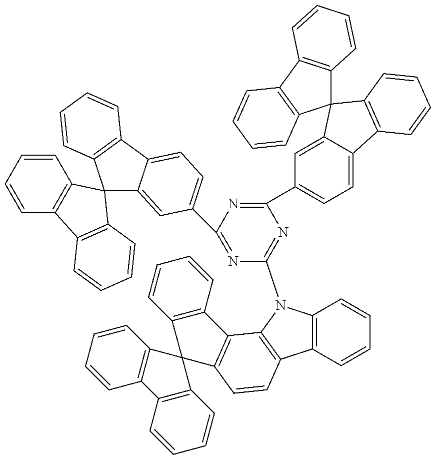 [SMILES: c1ccc2c(c1)-c1ccccc1C21c2ccccc2-c2ccc(-c3nc(-c4ccc5c(c4)C4(c6ccccc6-c6ccccc64)c4ccccc4-5)nc(-n4c5ccccc5c5ccc6c(c54)-c4ccccc4C64c5ccccc5-c5ccccc54)n3)cc21]

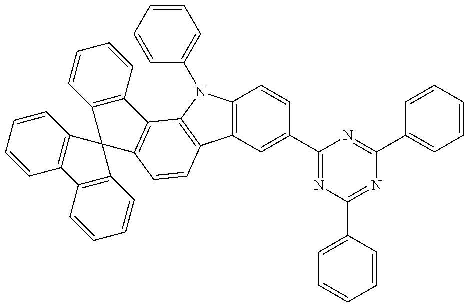 [SMILES: c1ccc(-c2nc(-c3ccccc3)nc(-c3ccc4c(c3)c3ccc5c(c3n4-c3ccccc3)-c3ccccc3C53c4ccccc4-c4ccccc43)n2)cc1]

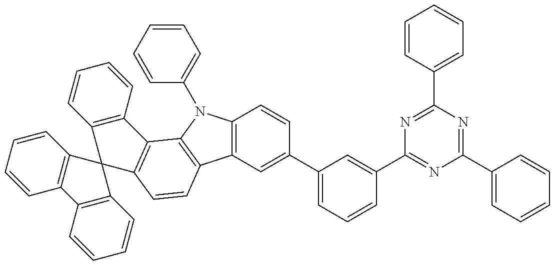 [SMILES: c1ccc(-c2nc(-c3ccccc3)nc(-c3cccc(-c4ccc5c(c4)c4ccc6c(c4n5-c4ccccc4)-c4ccccc4C64c5ccccc5-c5ccccc54)c3)n2)cc1]

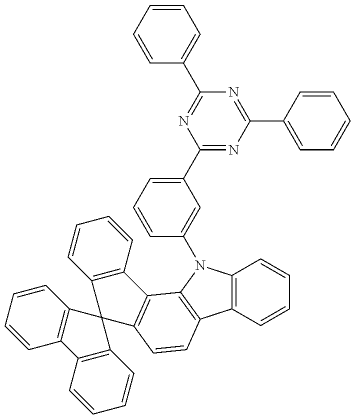 [SMILES: c1ccc(-c2nc(-c3ccccc3)nc(-c3cccc(-n4c5ccccc5c5ccc6c(c54)-c4ccccc4C64c5ccccc5-c5ccccc54)c3)n2)cc1]

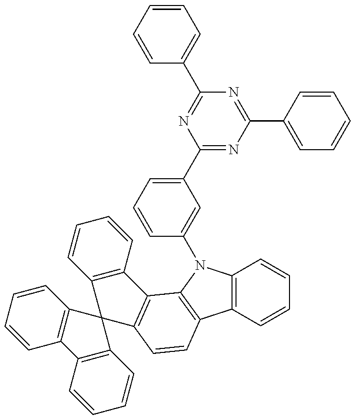 [SMILES: c1ccc(-c2nc(-c3ccccc3)nc(-c3cccc(-n4c5ccccc5c5ccc6c(c54)-c4ccccc4C64c5ccccc5-c5ccccc54)c3)n2)cc1]

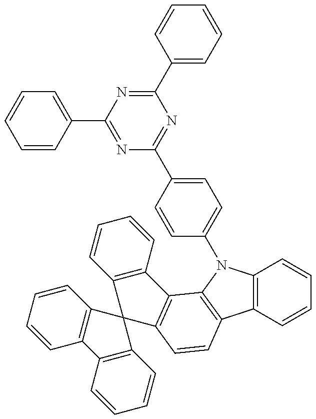 [SMILES: c1ccc(-c2nc(-c3ccccc3)nc(-c3ccc(-n4c5ccccc5c5ccc6c(c54)-c4ccccc4C64c5ccccc5-c5ccccc54)cc3)n2)cc1]

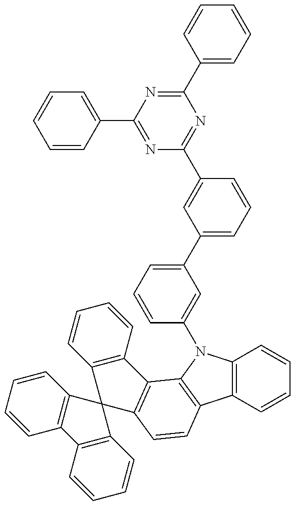 [SMILES: c1ccc(-c2nc(-c3ccccc3)nc(-c3cccc(-c4cccc(-n5c6ccccc6c6ccc7c(c65)-c5ccccc5C75c6ccccc6-c6ccccc65)c4)c3)n2)cc1]

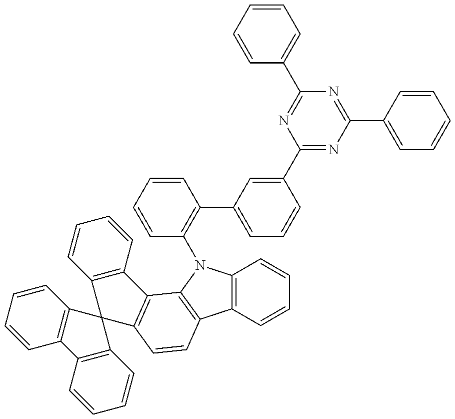 [SMILES: c1ccc(-c2nc(-c3ccccc3)nc(-c3cccc(-c4ccccc4-n4c5ccccc5c5ccc6c(c54)-c4ccccc4C64c5ccccc5-c5ccccc54)c3)n2)cc1]

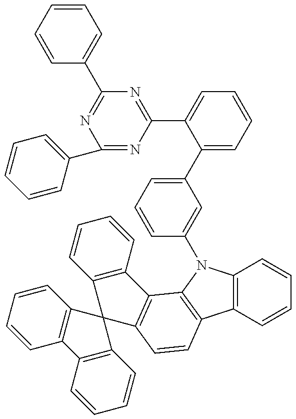 [SMILES: c1ccc(-c2nc(-c3ccccc3)nc(-c3ccccc3-c3cccc(-n4c5ccccc5c5ccc6c(c54)-c4ccccc4C64c5ccccc5-c5ccccc54)c3)n2)cc1]

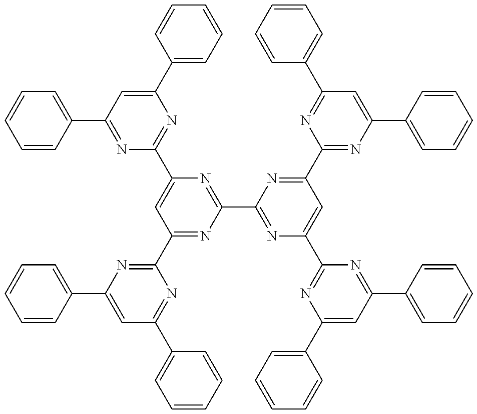 [SMILES: c1ccc(-c2cc(-c3ccccc3)nc(-c3cc(-c4nc(-c5ccccc5)cc(-c5ccccc5)n4)nc(-c4nc(-c5nc(-c6ccccc6)cc(-c6ccccc6)n5)cc(-c5nc(-c6ccccc6)cc(-c6ccccc6)n5)n4)n3)n2)cc1]

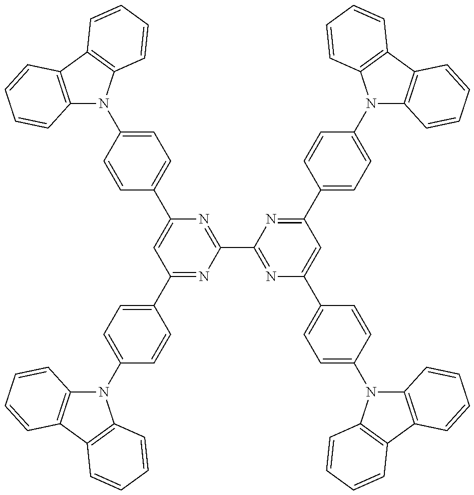 [SMILES: c1ccc2c(c1)c1ccccc1n2-c1ccc(-c2cc(-c3ccc(-n4c5ccccc5c5ccccc54)cc3)nc(-c3nc(-c4ccc(-n5c6ccccc6c6ccccc65)cc4)cc(-c4ccc(-n5c6ccccc6c6ccccc65)cc4)n3)n2)cc1]

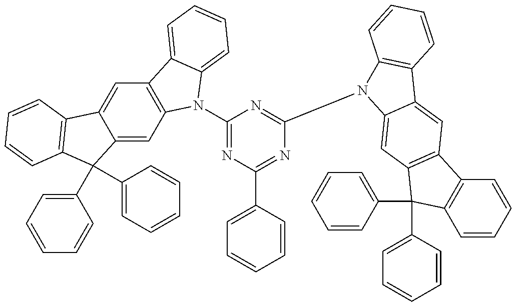 [SMILES: c1ccc(-c2nc(-n3c4ccccc4c4cc5c(cc43)C(c3ccccc3)(c3ccccc3)c3ccccc3-5)nc(-n3c4ccccc4c4cc5c(cc43)C(c3ccccc3)(c3ccccc3)c3ccccc3-5)n2)cc1]

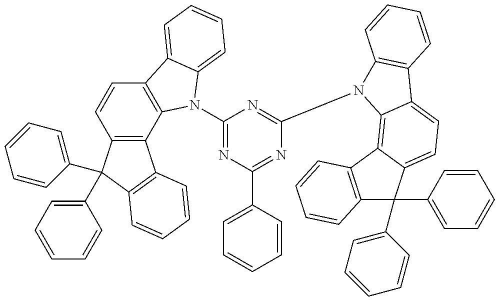 [SMILES: c1ccc(-c2nc(-n3c4ccccc4c4ccc5c(c43)-c3ccccc3C5(c3ccccc3)c3ccccc3)nc(-n3c4ccccc4c4ccc5c(c43)-c3ccccc3C5(c3ccccc3)c3ccccc3)n2)cc1]

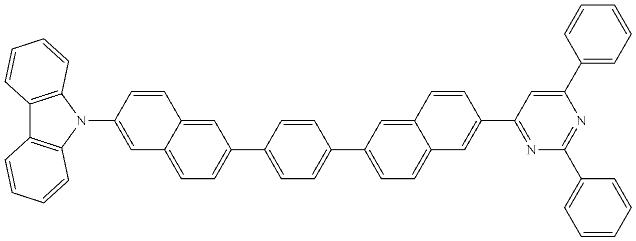 [SMILES: c1ccc(-c2cc(-c3ccc4cc(-c5ccc(-c6ccc7cc(-n8c9ccccc9c9ccccc98)ccc7c6)cc5)ccc4c3)nc(-c3ccccc3)n2)cc1]

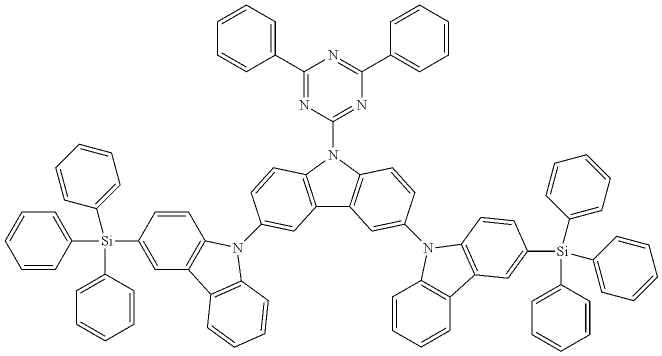 [SMILES: c1ccc(-c2nc(-c3ccccc3)nc(-n3c4ccc(-n5c6ccccc6c6cc([Si](c7ccccc7)(c7ccccc7)c7ccccc7)ccc65)cc4c4cc(-n5c6ccccc6c6cc([Si](c7ccccc7)(c7ccccc7)c7ccccc7)ccc65)ccc43)n2)cc1]

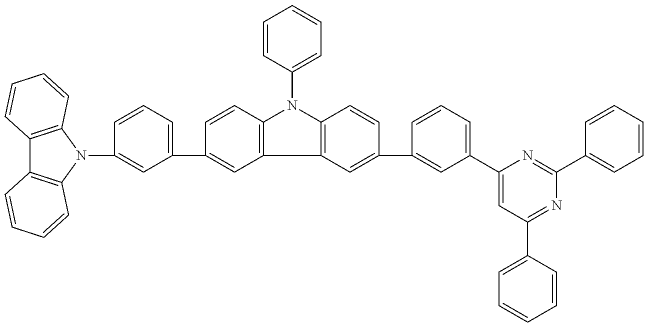 [SMILES: c1ccc(-c2cc(-c3cccc(-c4ccc5c(c4)c4cc(-c6cccc(-n7c8ccccc8c8ccccc87)c6)ccc4n5-c4ccccc4)c3)nc(-c3ccccc3)n2)cc1]

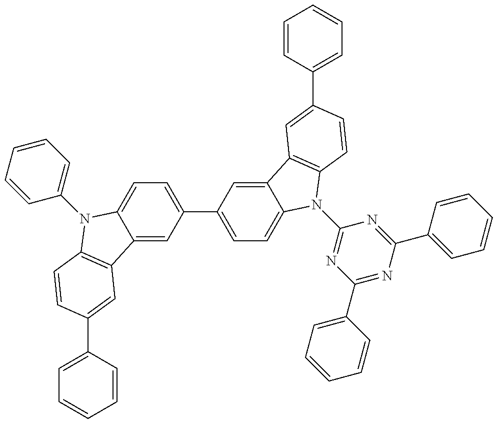 [SMILES: c1ccc(-c2ccc3c(c2)c2cc(-c4ccc5c(c4)c4cc(-c6ccccc6)ccc4n5-c4nc(-c5ccccc5)nc(-c5ccccc5)n4)ccc2n3-c2ccccc2)cc1]

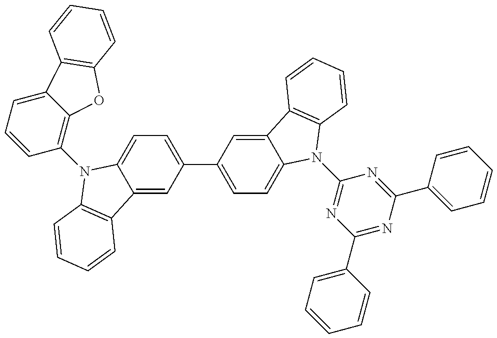 [SMILES: c1ccc(-c2nc(-c3ccccc3)nc(-n3c4ccccc4c4cc(-c5ccc6c(c5)c5ccccc5n6-c5cccc6c5oc5ccccc56)ccc43)n2)cc1]

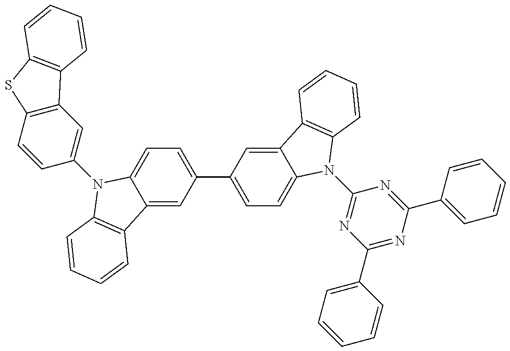 [SMILES: c1ccc(-c2nc(-c3ccccc3)nc(-n3c4ccccc4c4cc(-c5ccc6c(c5)c5ccccc5n6-c5ccc6sc7ccccc7c6c5)ccc43)n2)cc1]

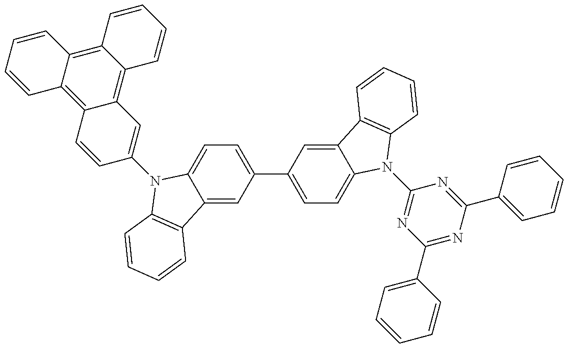 [SMILES: c1ccc(-c2nc(-c3ccccc3)nc(-n3c4ccccc4c4cc(-c5ccc6c(c5)c5ccccc5n6-c5ccc6c7ccccc7c7ccccc7c6c5)ccc43)n2)cc1]

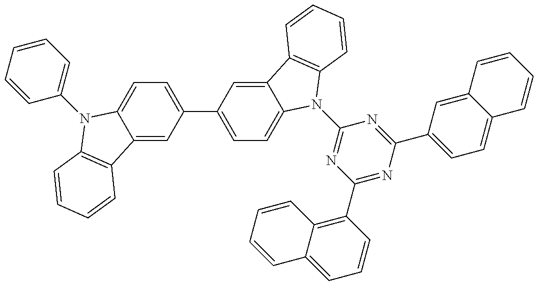 [SMILES: c1ccc(-n2c3ccccc3c3cc(-c4ccc5c(c4)c4ccccc4n5-c4nc(-c5ccc6ccccc6c5)nc(-c5cccc6ccccc56)n4)ccc32)cc1]

Preferred phosphorescent compounds are described below if the mixture of the electron-transporting compound having an LUMO of ≦−2.4 eV and the compound of the formula (1) is employed in an emitting layer in combination with a phosphorescent compound.

Suitable phosphorescent compounds (=triplet emitters) are, in particular, compounds which emit light, preferably in the visible region, on suitable excitation and in addition contain at least one atom having an atomic number greater than 20, preferably greater than 38 and less than 84, particularly preferably greater than 56 and less than 80, in particular a metal having this atomic number. The phosphorescence emitters used are preferably compounds which contain copper, molybdenum, tungsten, rhenium, ruthenium, osmium, rhodium, iridium, palladium, platinum, silver, gold or europium, in particular compounds which contain iridium, platinum or copper.

Examples of the emitters described above are revealed by the applications WO 00/70655, WO 2001/41512, WO 2002/02714, WO 2002/15645, EP 1191613, EP 1191612, EP 1191614, WO 2005/033244, WO 2005/019373, US 2005/0258742, WO 2010/086089, WO 2011/157339, WO 2012/007086, WO 2012/163471, WO 2013/000531 and WO 2013/020631. In general, all phosphorescent complexes as are used in accordance with the prior art for phosphorescent OLEDs and as are known to the person skilled in the art in the area of organic electroluminescence are suitable, and the person skilled in the art will be able to use further phosphorescent complexes without inventive step.

Examples of suitable phosphorescent compounds are depicted in the following table.

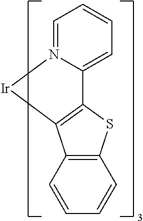

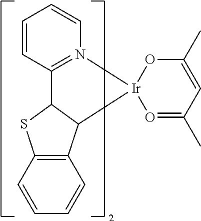

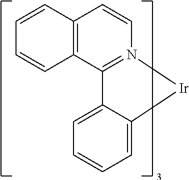

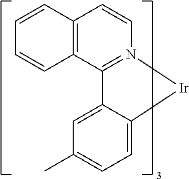

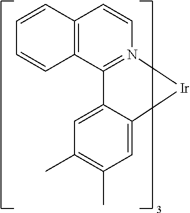

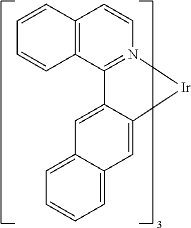

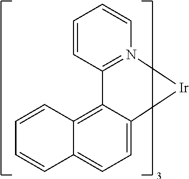

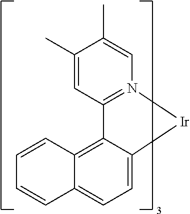

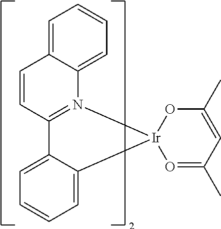

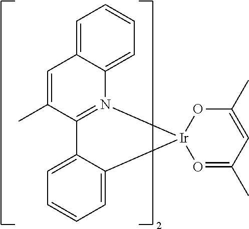

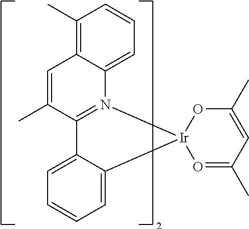

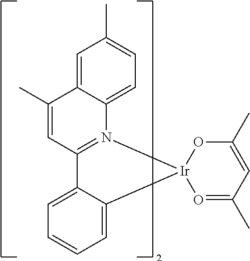

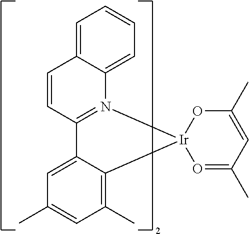

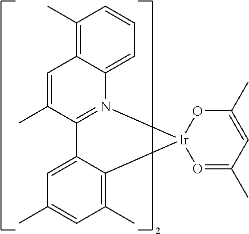

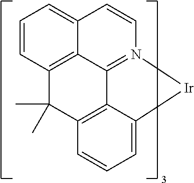

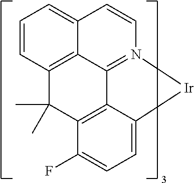

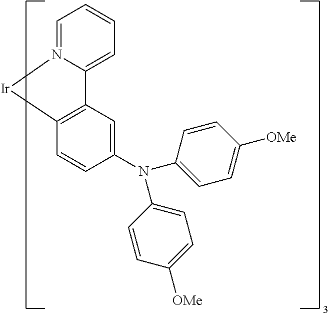

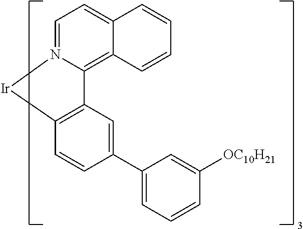

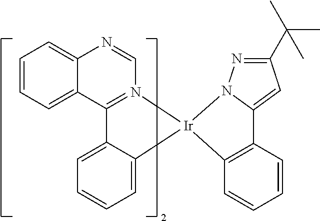

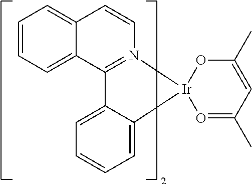

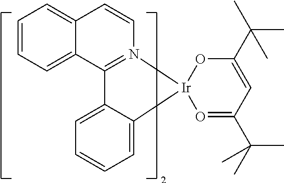

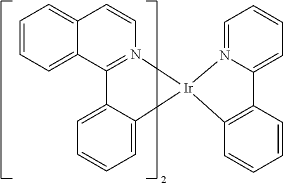

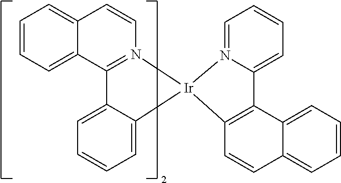

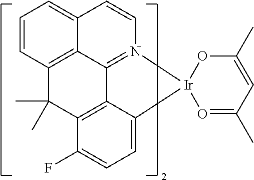

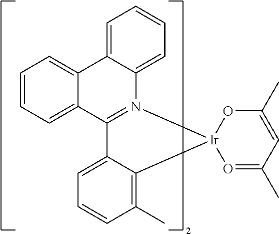

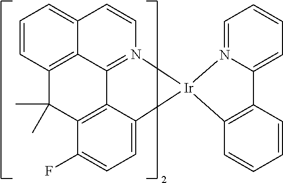

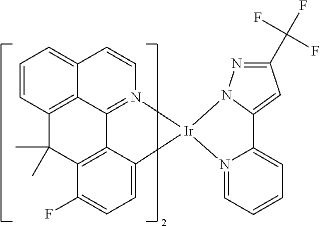

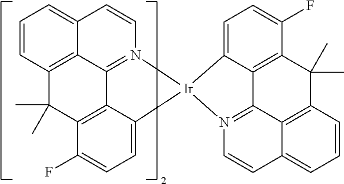

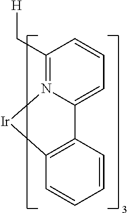

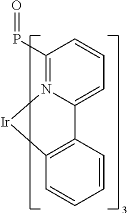

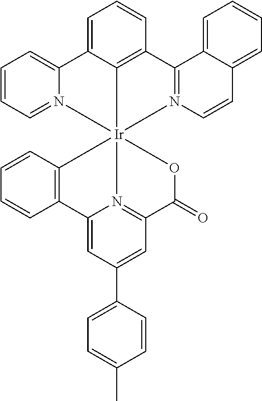

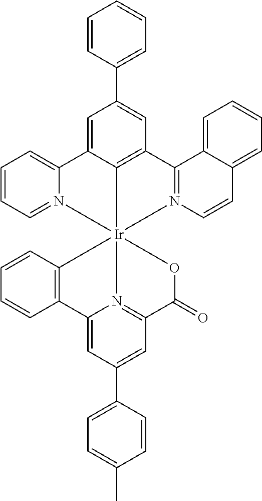

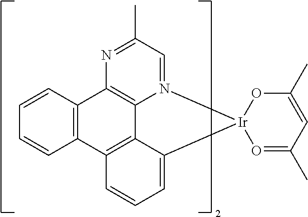

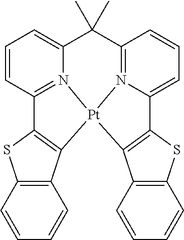

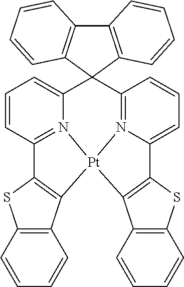

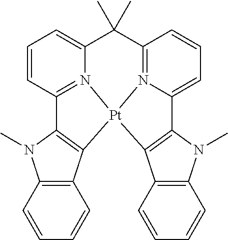

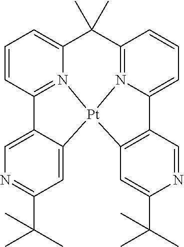

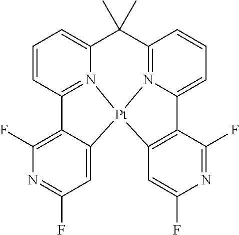

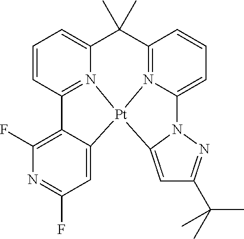

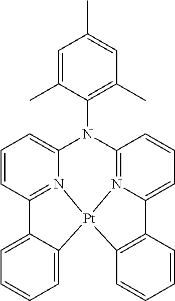

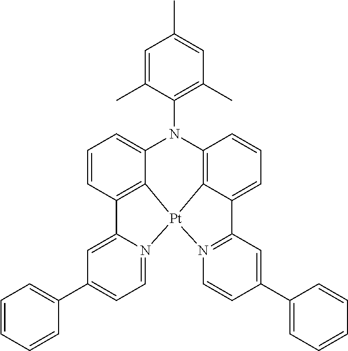

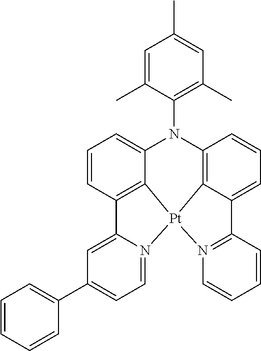

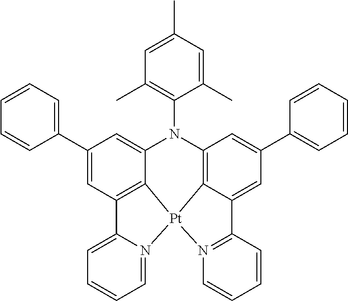

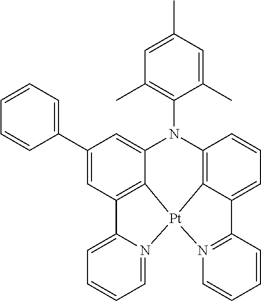

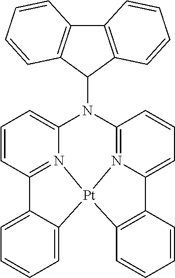

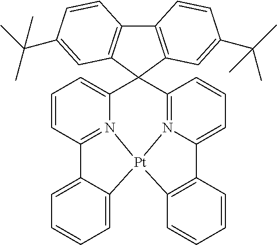

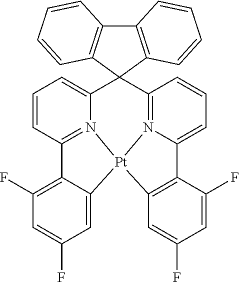

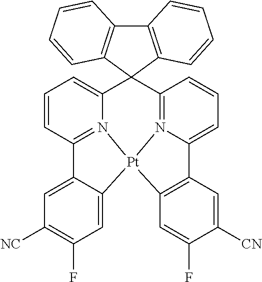

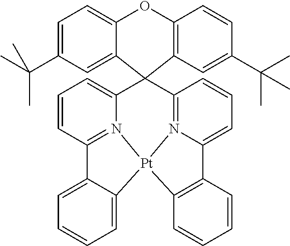

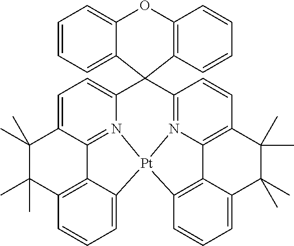

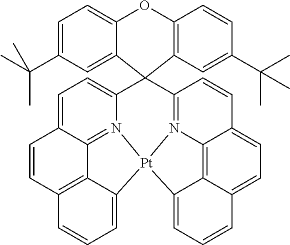

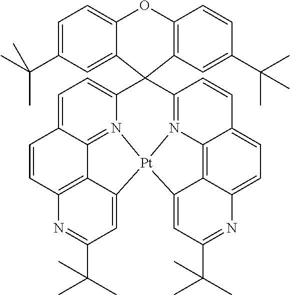

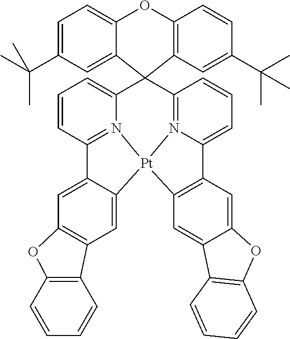

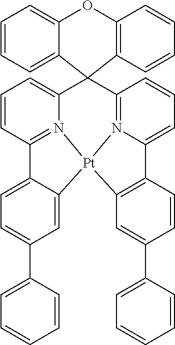

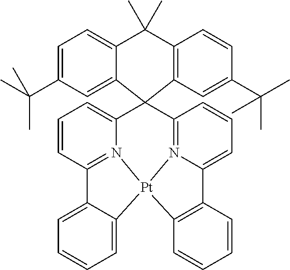

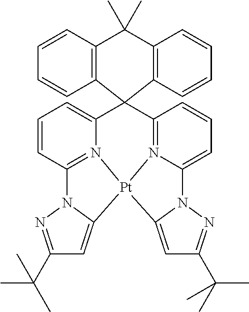

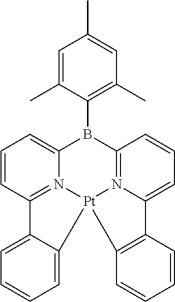

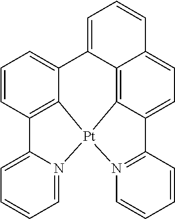

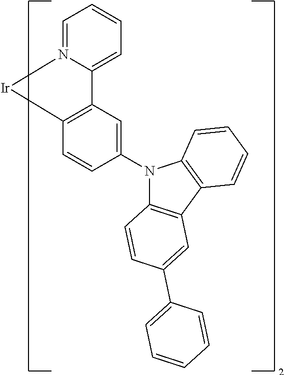

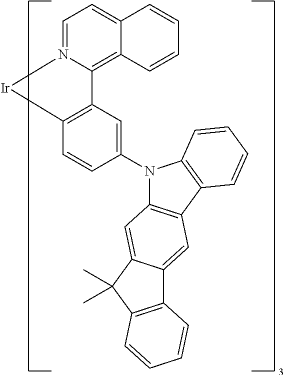

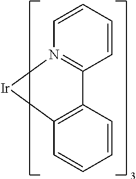

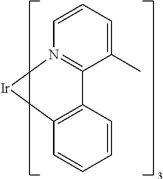

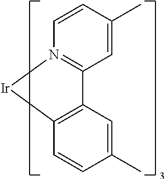

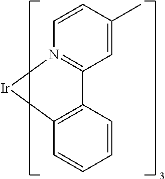

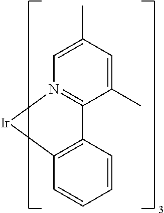

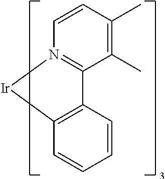

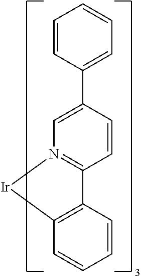

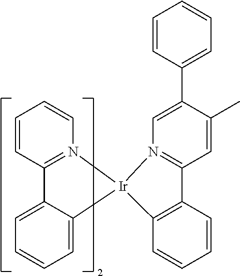

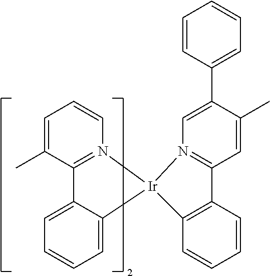

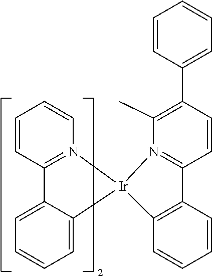

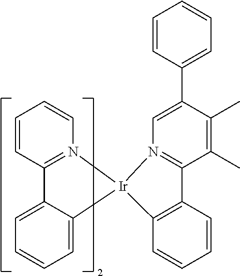

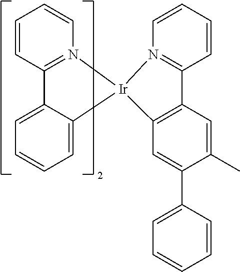

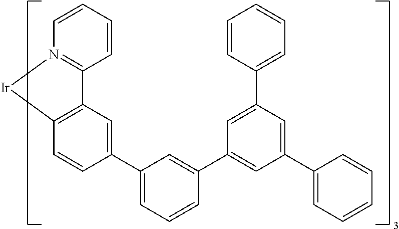

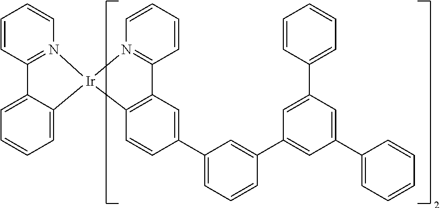

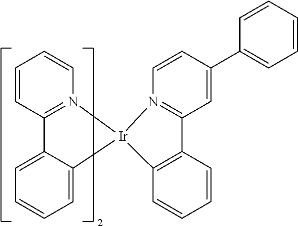

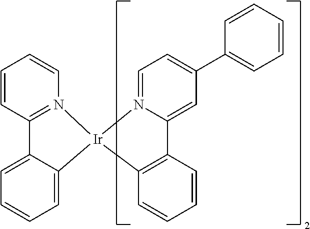

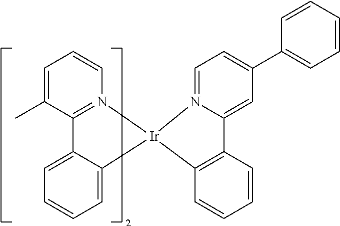

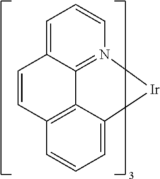

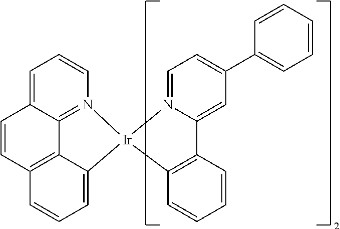

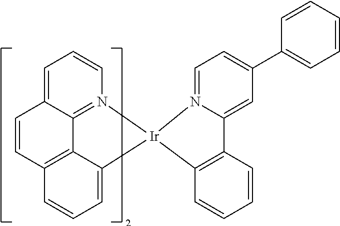

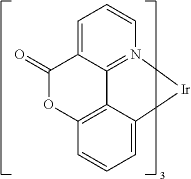

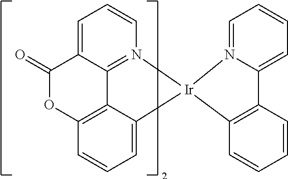

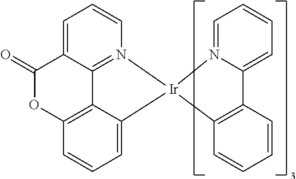

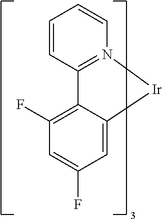

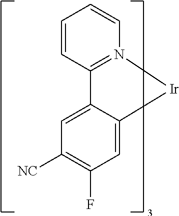

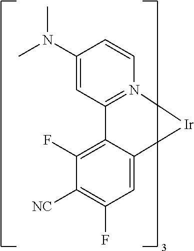

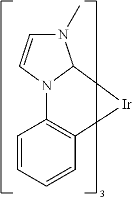

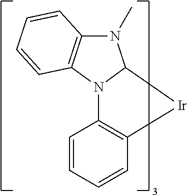

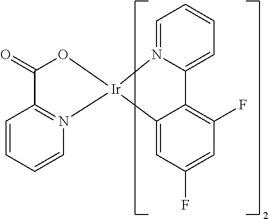

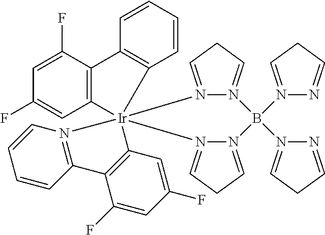

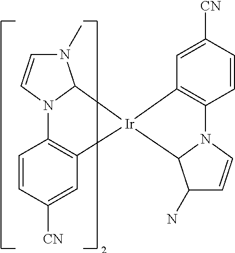

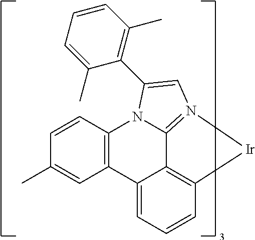

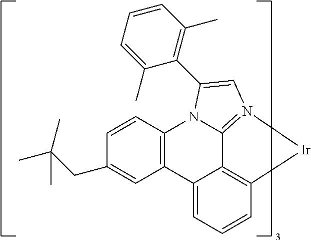

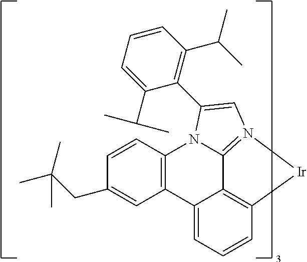

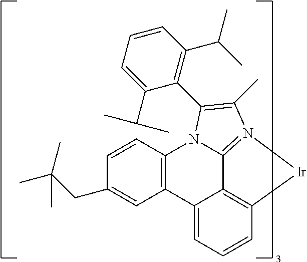

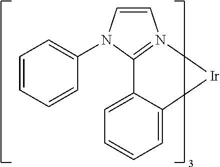

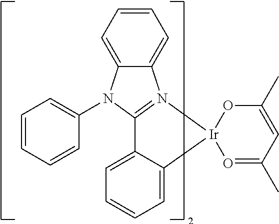

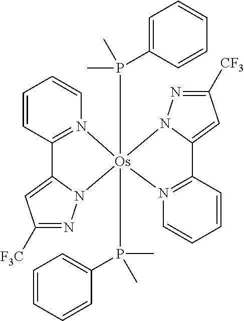

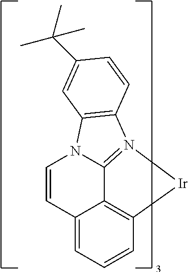

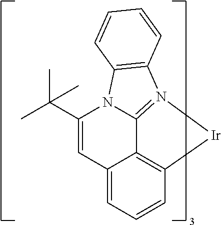

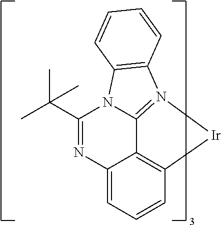

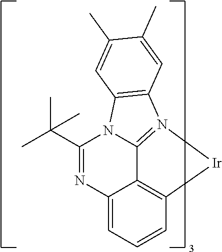

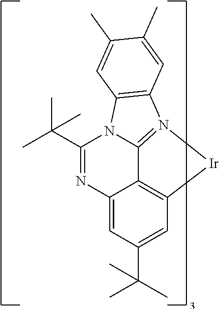

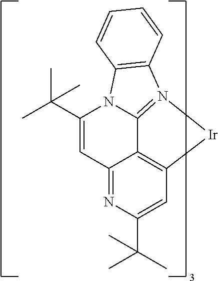

The organic electroluminescent device comprises cathode, anode and at least one emitting layer. Apart from these layers, it may also comprise further layers, for example in each case one or more hole-injection layers, hole-transport layers, hole-blocking layers, electron-transport layers, electron-injection layers, exciton-blocking layers, electron-blocking layers and/or charge-generation layers. Interlayers, which have, for example, an exciton-blocking function, may likewise be introduced between two emitting layers. However, it should be pointed out that each of these layers does not necessarily have to be present. The organic electroluminescent device here may comprise one emitting layer, or it may comprise a plurality of emitting layers. If a plurality of emission layers are present, these preferably have in total a plurality of emission maxima between 380 nm and 750 nm, resulting overall in white emission, i.e. various emitting compounds which are able to fluoresce or phosphoresce are used in the emitting layers. Particular preference is given to systems having three emitting layers, where the three layers exhibit blue, green and orange or red emission (for the basic structure, see, for example, WO 2005/011013). If more than one emitting layer is present, at least one of these layers comprises, in accordance with the invention, a phosphorescent compound, an electron-transporting compound having an LUMO ≦−2.4 eV and a compound of the formula (1) and/or an electron-transport layer or electron-injection layer comprises the electron-transporting compound having an LUMO ≦−2.4 eV and the compound of the formula (1).

In a further embodiment of the invention, the organic electroluminescent device according to the invention does not comprise a separate hole-injection layer and/or hole-transport layer and/or hole-blocking layer and/or electron-transport layer, i.e. the emitting layer is directly adjacent to the hole-injection layer or the anode and/or the emitting layer is directly adjacent to the electron-transport layer or the electron-injection layer or the cathode, as described, for example, in WO 2005/053051.

In the further layers of the organic electroluminescent device according to the invention, in particular in the hole-injection and -transport layers and in the electron-injection and -transport layers, all materials can be used as are usually employed in accordance with the prior art. The person skilled in the art will therefore be able to employ, without inventive step, all materials known for organic electroluminescent devices in combination with the emitting layer according to the invention.

Preference is furthermore given to an organic electroluminescent device, characterised in that one or more layers are coated by means of a sublimation process, in which the materials are applied by vapour deposition in vacuum sublimation units at an initial pressure of less than 10⁻⁵ mbar, preferably less than 10⁻⁶ mbar. However, it is also possible for the initial pressure to be even lower, for example less than 10⁻⁷ mbar.

Preference is likewise given to an organic electroluminescent device, characterised in that one or more layers are coated by means of the OVPD (organic vapour phase deposition) process or with the aid of carrier-gas sublimation, in which the materials are applied at a pressure between 10⁻⁵ mbar and 1 bar. A special case of this process is the OVJP (organic vapour jet printing) process, in which the materials are applied directly through a nozzle and are thus structured (for example M. S. Arnold et al., Appl. Phys. Lett. 2008, 92, 053301).

Preference is furthermore given to an organic electroluminescent device, characterised in that one or more layers are produced from solution, such as, for example, by spin coating, or by means of any desired printing process, such as, for example, screen printing, flexographic printing, offset printing, LITI (light induced thermal imaging, thermal transfer printing), ink-jet printing or nozzle printing. Soluble compounds, which are obtained, for example, by suitable substitution, are necessary for this purpose. These processes are also suitable, in particular, for oligomers, dendrimers and polymers

Also possible are hybrid processes, in which, for example, one or more layers are applied from solution and one or more further layers are applied by vapour deposition.

These processes are generally known to the person skilled in the art and can be applied by him without inventive step to organic electroluminescent devices comprising the compounds according to the invention.

The present invention therefore furthermore relates to a process for the production of an organic electroluminescent device according to the invention, characterised in that at least one layer is applied by means of a sublimation process and/or in that at least one layer is applied by means of an OVPD (organic vapour phase deposition) process or with the aid of carrier-gas sublimation and/or in that at least one layer is applied from solution, by spin coating or by means of a printing process.

The present invention again furthermore relates to a mixture comprising at least one compound of the formula (1) or (1a) indicated above and at least one electron-transporting compound which has an LUMO ≦−2.4 eV. The same preferences as indicated above for the organic electroluminescent device apply to the mixture. In particular, it may also be preferred for the mixture furthermore to comprise a phosphorescent compound.

For the processing of the mixture according to the invention from the liquid phase, for example by spin coating or by printing processes, formulations of the compounds according to the invention are necessary. These formulations can be, for example, solutions, dispersions or emulsions. It may be preferred to use mixtures of two or more solvents for this purpose. Suitable and preferred solvents are, for example, toluene, anisole, o-, m- or p-xylene, methyl benzoate, mesitylene, tetralin, veratrol, THF, methyl-THF, THP, chloro-benzene, dioxane, phenoxytoluene, in particular 3-phenoxytoluene, (−)-fenchone, 1,2,3,5-tetramethylbenzene, 1,2,4,5-tetramethylbenzene, 1-methyl-naphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, butyl benzoate, cumene, cyclo-hexanol, cyclohexanone, cyclohexylbenzene, decalin, dodecylbenzene, ethyl benzoate, indane, methyl benzoate, NMP, p-cymene, phenetole, 1,4-di-isopropylbenzene, dibenzyl ether, diethylene glycol butyl methyl ether, triethylene glycol butyl methyl ether, diethylene glycol dibutyl ether, triethylene-glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-di-methylphenyl)ethane or mixtures of these solvents.

The present invention therefore furthermore relates to a formulation, in particular a solution or dispersion, comprising a mixture according to the invention and at least one solvent.

The organic electroluminescent devices according to the invention are distinguished by the following surprising advantages over the prior art:
1. The organic electroluminescent devices according to the invention have a very good lifetime. The lifetime here is longer compared with electroluminescent devices which either comprise only electron-transporting compounds having an LUMO ≦−2.4 eV or only compounds of the formula (1) as matrix material.
2. The organic electroluminescent devices according to the invention have a very low operating voltage. The operating voltage here is lower compared with electroluminescent devices which either comprise only electron-transporting compounds having an LUMO ≦−2.4 eV or only compounds of the formula (1) as matrix material.

These above-mentioned advantages are not accompanied by an impairment in the other electronic properties.

The invention is explained in greater detail by the following examples, without wishing to restrict it thereby. The person skilled in the art will be able to carry out the invention throughout the range disclosed on the basis of the descriptions and produce further organic electroluminescent devices according to the invention without inventive step.

### EXAMPLES

### Determination of the LUMO Levels and the Triplet Level

The LUMO levels and the triplet level of the materials are determined via quantum-chemical calculations. To this end, the “Gaussian03W” software (Gaussian Inc.) is used. In order to calculate organic substances without metals denoted in Table 5 by “org.” method), firstly a geometry optimisation is carried out using the “Ground State/Semi-empirical/Default Spin/AM1/Charge 0/Spin Singlet” method. This is followed by an energy calculation on the basis of the optimised geometry. The “TD-SCF/DFT/Default Spin/B3PW91” method with the “6-31G(d)” base set is used here (Charge 0/Spin Singlet). For organometallic compounds (denoted in Table 5 by “organo.-M” method), the geometry is optimised via the “Ground State/Hartree-Fock/Default Spin/LanL2 MB/Charge 0/Spin Singlet” method. The energy calculation is carried out analogously to the organic substances, as described above, with the difference that the “LanL2DZ” base set is used for the metal atom and the “6-31G(d)” base set is used for the ligands. The energy calculation gives the LUMO LEh in hartree units. The LUMO values in electron-volts, calibrated with reference to cyclic voltammetry measurements, is determined therefrom as follows:

LUMO(eV)=((LEh*27.212)−2.0041)/1.385

For the purposes of this application, this value is to be regarded as the LUMO of the materials.

The triplet level T₁ of a material as is defined as the energy of the lowest-energy triplet state that arises from the quantum-chemical calculation.

### Synthesis of the Materials which are not Known from the Literature

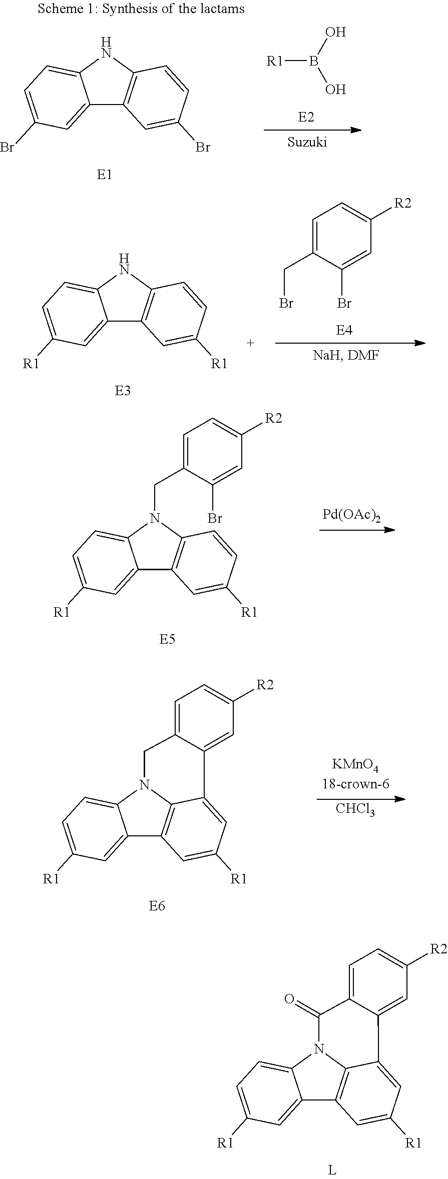

### Synthesis of E3 in Example L1

100 g (310 mmol) of 3,6-dibromocarbazole (CAS 6825-20-3) E1 together with 189 g (1550 mmol) of phenylboronic acid (CAS 98-80-6) E2 and 430 g (3.1 mol) of potassium carbonate are initially introduced in a 4 l four-necked flask and dissolved in 1000 ml of tetrahydrofuran and 300 ml of water. After the mixture has been degassed for 30 minutes, 140 mg (0.62 mmol) of palladium acetate and 650 mg of triphenylphosphine are added, and the mixture is heated under reflux overnight. 700 ml of water are subsequently added to the batch, and the aqueous phase is extracted a number of times with dichloromethane. The combined organic phases are dried over sodium sulfate, and the solvent mixture is removed in vacuo. The residue obtained is dissolved in 1.51 of dichloromethane and filtered through silica gel. The solvent is removed again in vacua, and the solid is washed by stirring with 600 ml of ethanol. Filtration and drying give 68 g (0.21 mol, 69%) of the desired product.

| Starting material E1 | Starting material E2 | Product E3 | Yield |
|---|---|---|---|
| 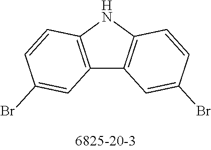 [SMILES: Brc1ccc2[nH]c3ccc(Br)cc3c2c1] | 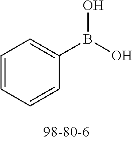 | 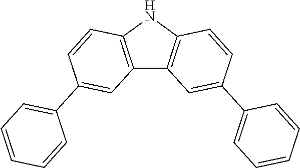 [SMILES: c1ccc(-c2ccc3[nH]c4ccc(-c5ccccc5)cc4c3c2)cc1] | 69% |
| 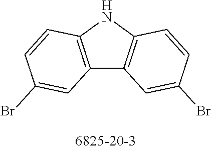 [SMILES: Brc1ccc2[nH]c3ccc(Br)cc3c2c1] | 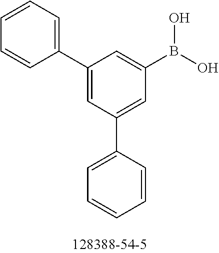 [SMILES: OB(O)c1cc(-c2ccccc2)cc(-c2ccccc2)c1] | 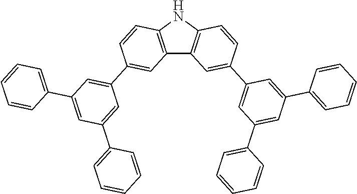 [SMILES: c1ccc(-c2cc(-c3ccccc3)cc(-c3ccc4[nH]c5ccc(-c6cc(-c7ccccc7)cc(-c7ccccc7)c6)cc5c4c3)c2)cc1] | 94% |
| 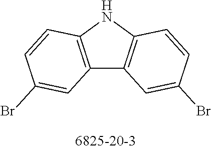 [SMILES: Brc1ccc2[nH]c3ccc(Br)cc3c2c1] | 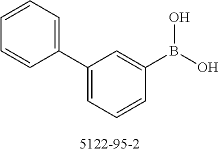 [SMILES: OB(O)c1cccc(-c2ccccc2)c1] | 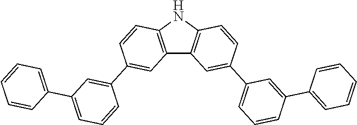 [SMILES: c1ccc(-c2cccc(-c3ccc4[nH]c5ccc(-c6cccc(-c7ccccc7)c6)cc5c4c3)c2)cc1] | 89% |
| 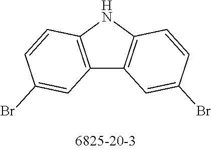 [SMILES: Brc1ccc2[nH]c3ccc(Br)cc3c2c1] | 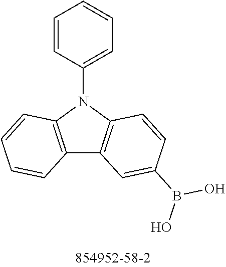 [SMILES: OB(O)c1ccc2c(c1)c1ccccc1n2-c1ccccc1] | 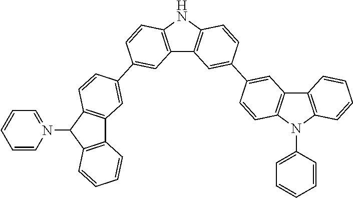 | 86% |
| 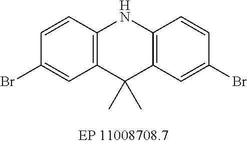 [SMILES: CC1(C)c2cc(Br)ccc2Nc2ccc(Br)cc21] | 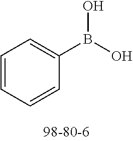 | 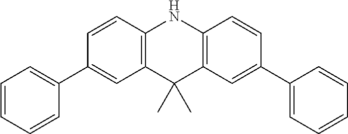 [SMILES: CC1(C)c2cc(-c3ccccc3)ccc2Nc2ccc(-c3ccccc3)cc21] | 93% |

### Synthesis of E5 in Example L1

100 g (313 mmol) of 3,6-diphenylcarbazole E3 are dissolved in 1 l of dried DMF in a 2 l four-necked flask, and 24 g (610 mmol) of sodium hydride (60% in oil) are added in portions under protective gas and with ice-cooling. 82 g (320 mmol) of 1-bromo-2-bromomethylbenzene in 360 ml of DMF are subsequently added, and the reaction mixture is stirred overnight. When the reaction is complete, 1 l of water is added, and the precipitated solid is filtered off with suction, giving 149 g (305 mmol, 97%) of the product E5.

| Starting material E3 | Starting material E4 | Product E5 | Yield |
|---|---|---|---|
| 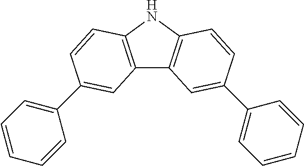 [SMILES: c1ccc(-c2ccc3[nH]c4ccc(-c5ccccc5)cc4c3c2)cc1] | 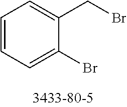 | 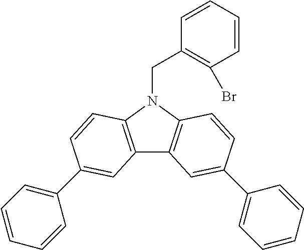 [SMILES: Brc1ccccc1Cn1c2ccc(-c3ccccc3)cc2c2cc(-c3ccccc3)ccc21] | 97% |

| | | | |
|---|---|---|---|
| 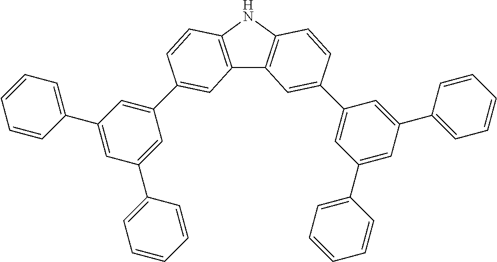 [SMILES: c1ccc(-c2cc(-c3ccccc3)cc(-c3ccc4[nH]c5ccc(-c6cc(-c7ccccc7)cc(-c7ccccc7)c6)cc5c4c3)c2)cc1] | 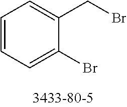 | 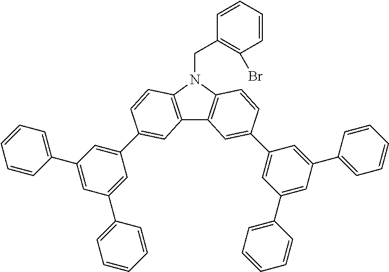 [SMILES: Brc1ccccc1Cn1c2ccc(-c3cc(-c4ccccc4)cc(-c4ccccc4)c3)cc2c2cc(-c3cc(-c4ccccc4)cc(-c4ccccc4)c3)ccc21] | 89% |
| 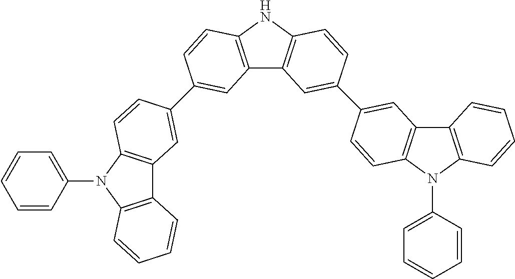 [SMILES: c1ccc(-n2c3ccccc3c3cc(-c4ccc5[nH]c6ccc(-c7ccc8c(c7)c7ccccc7n8-c7ccccc7)cc6c5c4)ccc32)cc1] | 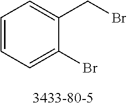 | 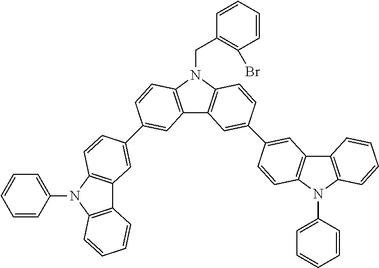 [SMILES: Brc1ccccc1Cn1c2ccc(-c3ccc4c(c3)c3ccccc3n4-c3ccccc3)cc2c2cc(-c3ccc4c(c3)c3ccccc3n4-c3ccccc3)ccc21] | 98% |
| 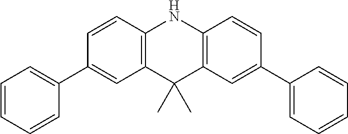 [SMILES: CC1(C)c2cc(-c3ccccc3)ccc2Nc2ccc(-c3ccccc3)cc21] | 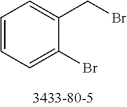 | 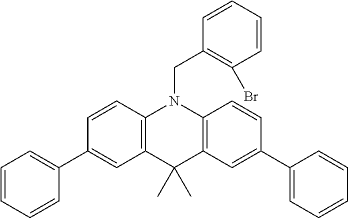 [SMILES: CC1(C)c2cc(-c3ccccc3)ccc2N(Cc2ccccc2Br)c2ccc(-c3ccccc3)cc21] | 91% |
| 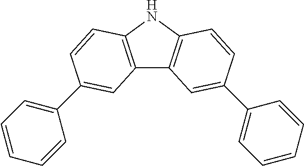 [SMILES: c1ccc(-c2ccc3[nH]c4ccc(-c5ccccc5)cc4c3c2)cc1] | 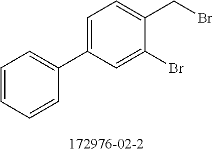 [SMILES: BrCc1ccc(-c2ccccc2)cc1Br] | 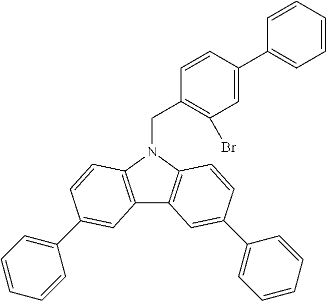 [SMILES: Brc1cc(-c2ccccc2)ccc1Cn1c2ccc(-c3ccccc3)cc2c2cc(-c3ccccc3)ccc21] | 94% |

### Synthesis of E6 in Example L1

149 g (305 mmol) of starting material E5 together with 10 g (46 mmol) of palladium acetate, 35 g (150 mmol) of benzyltrimethylammonium bromide and 63 g (460 mmol) of potassium carbonate are initially introduced in a 4 l flask, and 2 l of DMF are added. The reaction mixture is stirred for 48 h, and, after addition of 1 l of water, the product formed is precipitated. The residue is filtered off and washed by stirring in 1.5 l of ethanol. Drying in a vacuum drying cabinet gives 125 g (304 mmol, 99%) of the product E6.

| Starting materia E5 | Product E6 | Yield |
|---|---|---|
| 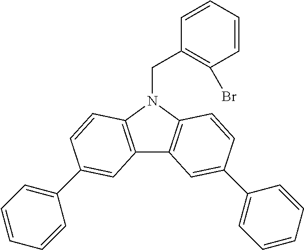 [SMILES: Brc1ccccc1Cn1c2ccc(-c3ccccc3)cc2c2cc(-c3ccccc3)ccc21] | 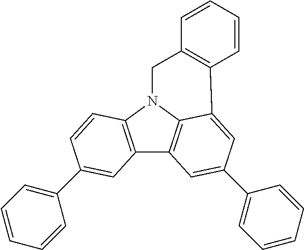 [SMILES: c1ccc(-c2ccc3c(c2)c2cc(-c4ccccc4)cc4c2n3Cc2ccccc2-4)cc1] | 99% |
| 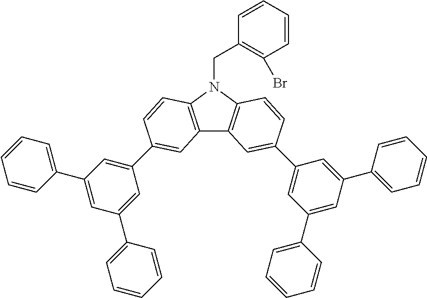 [SMILES: Brc1ccccc1Cn1c2ccc(-c3cc(-c4ccccc4)cc(-c4ccccc4)c3)cc2c2cc(-c3cc(-c4ccccc4)cc(-c4ccccc4)c3)ccc21] | 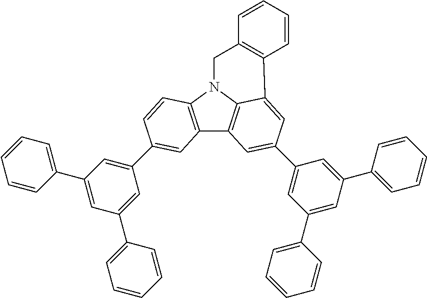 [SMILES: c1ccc(-c2cc(-c3ccccc3)cc(-c3ccc4c(c3)c3cc(-c5cc(-c6ccccc6)cc(-c6ccccc6)c5)cc5c3n4Cc3ccccc3-5)c2)cc1] | 97% |
| 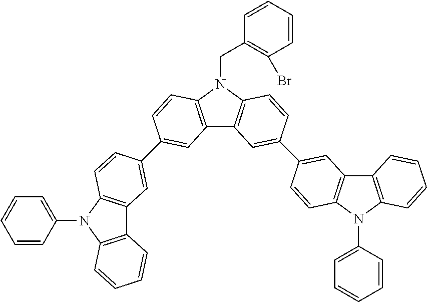 [SMILES: Brc1ccccc1Cn1c2ccc(-c3ccc4c(c3)c3ccccc3n4-c3ccccc3)cc2c2cc(-c3ccc4c(c3)c3ccccc3n4-c3ccccc3)ccc21] | 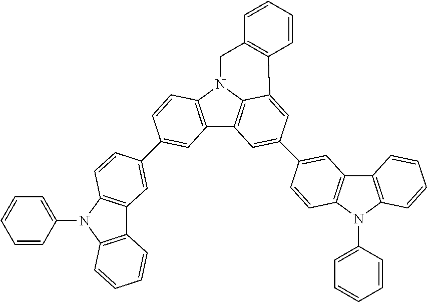 [SMILES: c1ccc(-n2c3ccccc3c3cc(-c4ccc5c(c4)c4cc(-c6ccc7c(c6)c6ccccc6n7-c6ccccc6)cc6c4n5Cc4ccccc4-6)ccc32)cc1] | 79% |
| 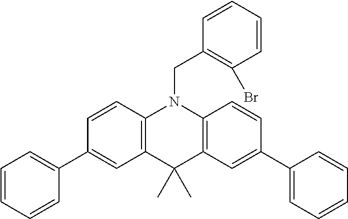 [SMILES: CC1(C)c2cc(-c3ccccc3)ccc2N(Cc2ccccc2Br)c2ccc(-c3ccccc3)cc21] | 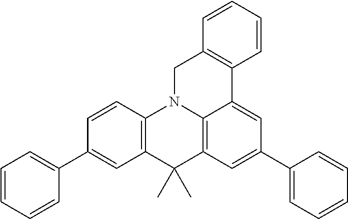 [SMILES: CC1(C)c2cc(-c3ccccc3)ccc2N2Cc3ccccc3-c3cc(-c4ccccc4)cc1c32] | 93% |
| 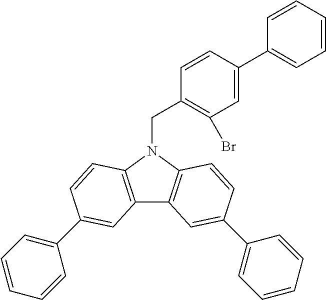 [SMILES: Brc1cc(-c2ccccc2)ccc1Cn1c2ccc(-c3ccccc3)cc2c2cc(-c3ccccc3)ccc21] | 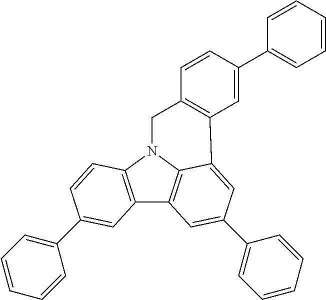 [SMILES: c1ccc(-c2ccc3c(c2)-c2cc(-c4ccccc4)cc4c5cc(-c6ccccc6)ccc5n(c24)C3)cc1] | 86% |

### Synthesis Example L1

124 g of starting material E6 together with 430 g (2700 mmol) of potassium permanganate and 28 g (109 mmol) of 18-crown-6 are dissolved in 31 of chloroform in a 4 l flask, and the suspension obtained is heated under reflux overnight. When the reaction is complete, the solid obtained is filtered off and repeatedly washed with chloroform. The combined organic phases are washed with 1N HCl and dried over sodium sulfate. The solid obtained is recrystallised a number of times from toluene until a purity of 99.9% (determined by means of HPLC) is reached. Sublimation gives 64 g (150 mmol, 49%) of the target compound L1.

| Starting material E6 | Product L | Yield |
|---|---|---|
| 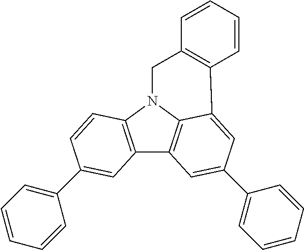 [SMILES: c1ccc(-c2ccc3c(c2)c2cc(-c4ccccc4)cc4c2n3Cc2ccccc2-4)cc1] | 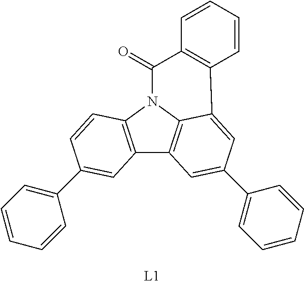 [SMILES: O=c1c2ccccc2c2cc(-c3ccccc3)cc3c4cc(-c5ccccc5)ccc4n1c23] | 49% |
| 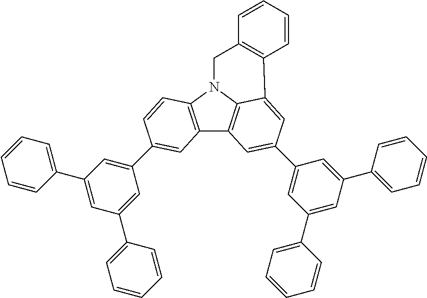 [SMILES: c1ccc(-c2cc(-c3ccccc3)cc(-c3ccc4c(c3)c3cc(-c5cc(-c6ccccc6)cc(-c6ccccc6)c5)cc5c3n4Cc3ccccc3-5)c2)cc1] | 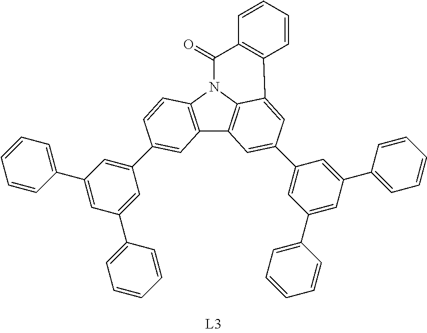 [SMILES: O=c1c2ccccc2c2cc(-c3cc(-c4ccccc4)cc(-c4ccccc4)c3)cc3c4cc(-c5cc(-c6ccccc6)cc(-c6ccccc6)c5)ccc4n1c23] | 36% |
| 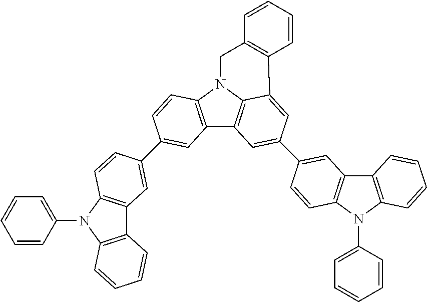 [SMILES: c1ccc(-n2c3ccccc3c3cc(-c4ccc5c(c4)c4cc(-c6ccc7c(c6)c6ccccc6n7-c6ccccc6)cc6c4n5Cc4ccccc4-6)ccc32)cc1] | 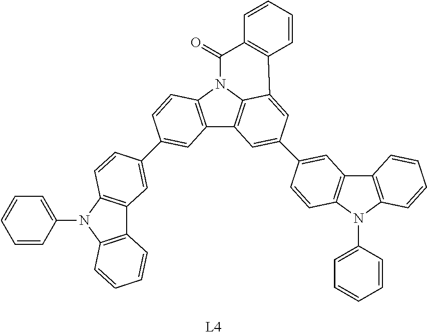 [SMILES: O=c1c2ccccc2c2cc(-c3ccc4c(c3)c3ccccc3n4-c3ccccc3)cc3c4cc(-c5ccc6c(c5)c5ccccc5n6-c5ccccc5)ccc4n1c23] | 56% |
| 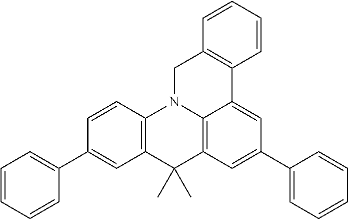 [SMILES: CC1(C)c2cc(-c3ccccc3)ccc2N2Cc3ccccc3-c3cc(-c4ccccc4)cc1c32] | 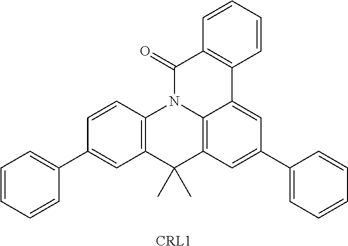 | 44% |
| 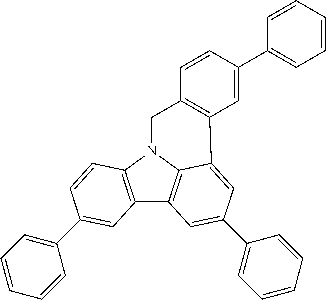 [SMILES: c1ccc(-c2ccc3c(c2)-c2cc(-c4ccccc4)cc4c5cc(-c6ccccc6)ccc5n(c24)C3)cc1] | 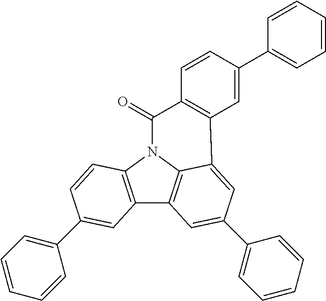 [SMILES: O=c1c2ccc(-c3ccccc3)cc2c2cc(-c3ccccc3)cc3c4cc(-c5ccccc5)ccc4n1c23] | 57% |

### Synthesis Examples L8 and L9

### A) 9-(2-Bromobenzyl)-3,6-diphenyl-9H-carbazole

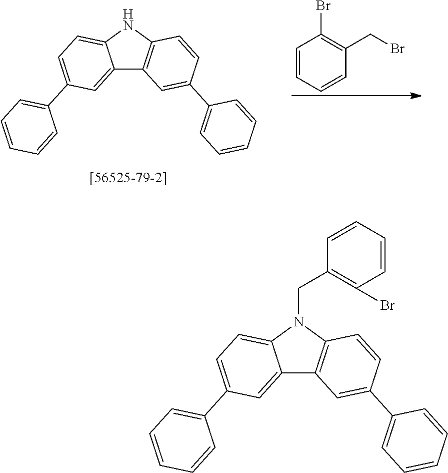 [SMILES: c1ccc(-c2ccc3[nH]c4ccc(-c5ccccc5)cc4c3c2)cc1 ; BrCc1ccccc1Br ; Brc1ccccc1Cn1c2ccc(-c3ccccc3)cc2c2cc(-c3ccccc3)ccc21]

9.7 g (224 mmol) of NaH (60% in mineral oil) are dissolved in 1000 ml of THF undera protective-gas atmosphere. 60 g (50 mmol) of 3,6-diphenyl-9H-carbazole and 11.5 g (52.5 mmol) of 15-crown-5, dissolved in 200 ml of THF, are added. After 1 h at room temperature, a solution of 61 g (224 mmol) of 2-bromobenzoyl bromide in 250 ml of THF is added dropwise. The reaction mixture is stirred at room temperature for 18 h. After this time, the reaction mixture is poured onto ice and extracted three times with dichloromethane. The combined organic phases are dried over Na₂SO₄ and evaporated. The residue is extracted with hot toluene and recrystallised from toluene/n-heptane. The yield is 73 g (80%).

The following compounds are obtained analogously:

| Ex. | Starting material | |
|---|---|---|
| A1 | 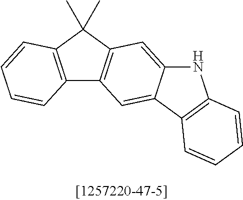 [SMILES: CC1(C)c2ccccc2-c2cc3c(cc21)[nH]c1ccccc13] | 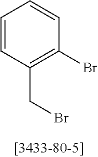 |
| A3 | 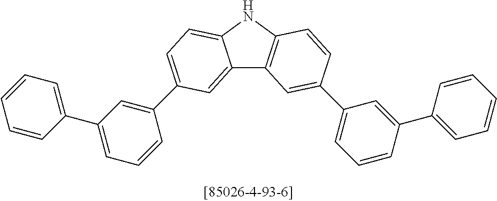 [SMILES: c1ccc(-c2cccc(-c3ccc4[nH]c5ccc(-c6cccc(-c7ccccc7)c6)cc5c4c3)c2)cc1] | 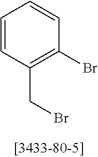 |
| A4 | 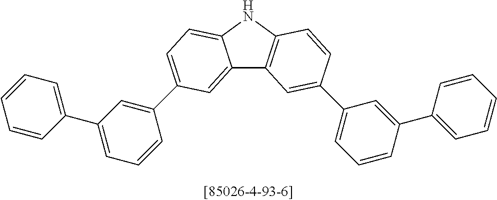 [SMILES: c1ccc(-c2cccc(-c3ccc4[nH]c5ccc(-c6cccc(-c7ccccc7)c6)cc5c4c3)c2)cc1] | 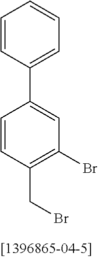 [SMILES: BrCc1ccc(-c2ccccc2)cc1Br] |

| Ex. | Product | Yield |
|---|---|---|
| A1 | 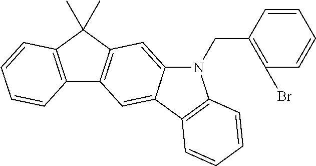 [SMILES: CC1(C)c2ccccc2-c2cc3c4ccccc4n(Cc4ccccc4Br)c3cc21] | 89% |
| A3 | 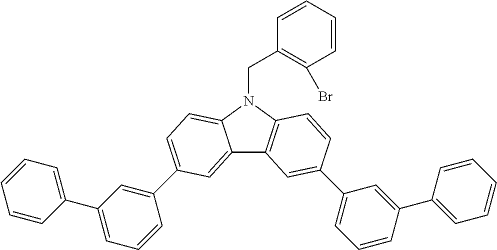 [SMILES: Brc1ccccc1Cn1c2ccc(-c3cccc(-c4ccccc4)c3)cc2c2cc(-c3cccc(-c4ccccc4)c3)ccc21] | 87% |
| A4 | 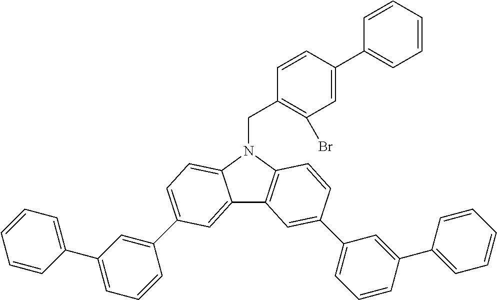 [SMILES: Brc1cc(-c2ccccc2)ccc1Cn1c2ccc(-c3cccc(-c4ccccc4)c3)cc2c2cc(-c3cccc(-c4ccccc4)c3)ccc21] | |

### B: Cyclisation

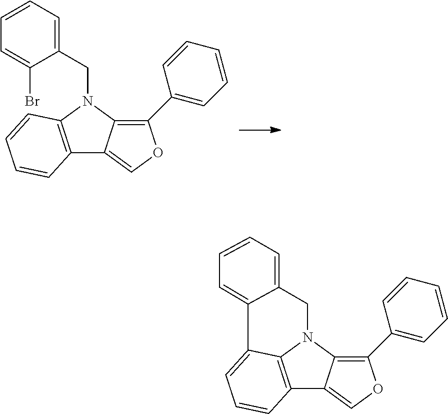 [SMILES: Brc1ccccc1Cn1c2ccccc2c2coc(-c3ccccc3)c21 ; c1ccc(-c2occ3c4cccc5c4n(c23)Cc2ccccc2-5)cc1]

Under a protective-gas atmosphere, 43 ml (16 mmol) of tributyltin hydride and 30 g (12.5 mmol) of 1,1′-azobis(cyclohexane-1-carbonitrile) in 600 ml of toluene are added dropwise over a period of 4 h to a boiling solution of 5.2 g (12.5 mmol) of 2-bromophenyl-(3-phenylfuro[3,4-b]indol-4-yl)methanone in 600 ml of toluene. The mixture is subsequently heated under reflux for 3 h. After this time, the reaction mixture is poured onto ice and extracted three times with dichloromethane. The combined organic phases are dried over Na₂SO₄ and evaporated. The residue is recrystallised from toluene. The yield is 3.1 g (76%).

The following compounds are obtained analogously.

| Ex. | Starting material 1 | Product 1 | Yield |
|---|---|---|---|
| B1 | 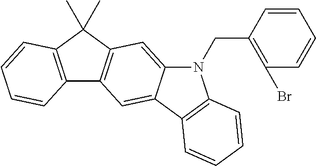 [SMILES: CC1(C)c2ccccc2-c2cc3c4ccccc4n(Cc4ccccc4Br)c3cc21] | 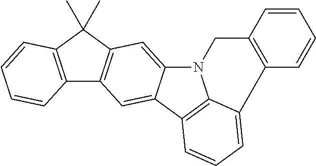 [SMILES: CC1(C)c2ccccc2-c2cc3c4cccc5c4n(c3cc21)Cc1ccccc1-5] | 75% |
| B3 | 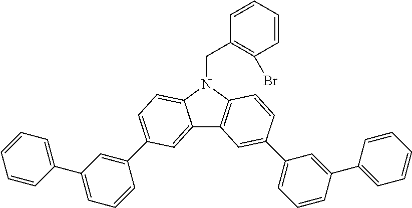 [SMILES: Brc1ccccc1Cn1c2ccc(-c3cccc(-c4ccccc4)c3)cc2c2cc(-c3cccc(-c4ccccc4)c3)ccc21] | 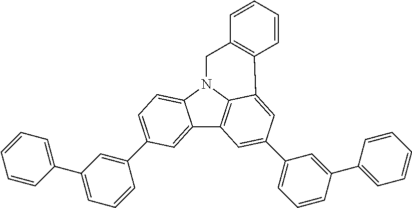 [SMILES: c1ccc(-c2cccc(-c3ccc4c(c3)c3cc(-c5cccc(-c6ccccc6)c5)cc5c3n4Cc3ccccc3-5)c2)cc1] | 80% |
| B4 | 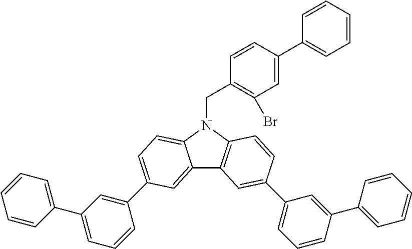 [SMILES: Brc1cc(-c2ccccc2)ccc1Cn1c2ccc(-c3cccc(-c4ccccc4)c3)cc2c2cc(-c3cccc(-c4ccccc4)c3)ccc21] | 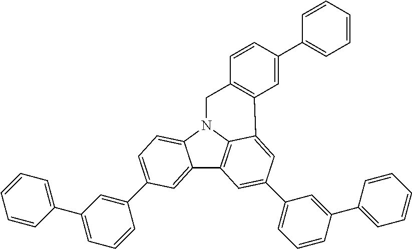 [SMILES: c1ccc(-c2cccc(-c3ccc4c(c3)c3cc(-c5cccc(-c6ccccc6)c5)cc5c3n4Cc3ccc(-c4ccccc4)cc3-5)c2)cc1] | 85% |

### C: Oxidation

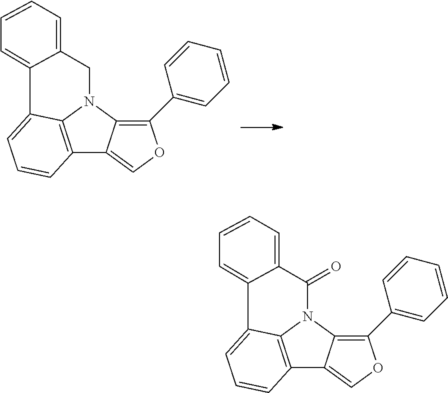 [SMILES: c1ccc(-c2occ3c4cccc5c4n(c23)Cc2ccccc2-5)cc1 ; O=c1c2ccccc2c2cccc3c4coc(-c5ccccc5)c4n1c23]

25 g (62 mmol) of benzyl derivative are dissolved in 1000 ml of dichloromethane. 98 g (625 mmol) of KMnO₄ are subsequently added, and the mixture is stirred at room temperature for 14 h. After this time, the residue is filtered off, dissolved in dichloromethane and passed through a silica-gel column. After evaporation, the residue is extracted with hot toluene, recrystallised from toluene and finally sublimed in a high vacuum. The yield after sublimation is 20 g (59 mmol, 77%) with a purity of 99.9%.

The following compounds are obtained analogously.

| Ex. | Starting material 1 | Product 1 | Yield |
|---|---|---|---|
| C1 | 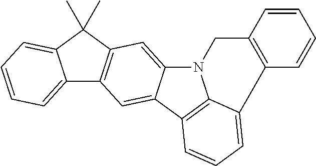 [SMILES: CC1(C)c2ccccc2-c2cc3c4cccc5c4n(c3cc21)Cc1ccccc1-5] | 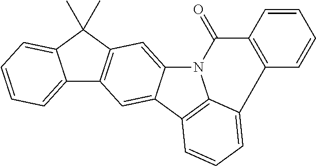 [SMILES: CC1(C)c2ccccc2-c2cc3c4cccc5c6ccccc6c(=O)n(c3cc21)c54] | 75% |
| C3 | 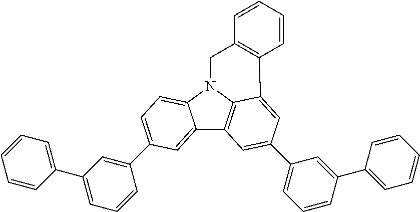 [SMILES: c1ccc(-c2cccc(-c3ccc4c(c3)c3cc(-c5cccc(-c6ccccc6)c5)cc5c3n4Cc3ccccc3-5)c2)cc1] | 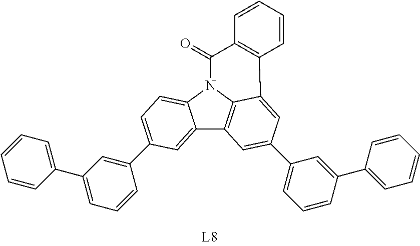 [SMILES: O=c1c2ccccc2c2cc(-c3cccc(-c4ccccc4)c3)cc3c4cc(-c5cccc(-c6ccccc6)c5)ccc4n1c23] | 80% |
| C4 | 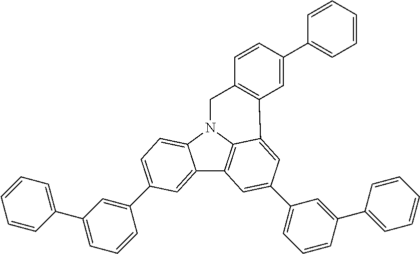 [SMILES: c1ccc(-c2cccc(-c3ccc4c(c3)c3cc(-c5cccc(-c6ccccc6)c5)cc5c3n4Cc3ccc(-c4ccccc4)cc3-5)c2)cc1] | 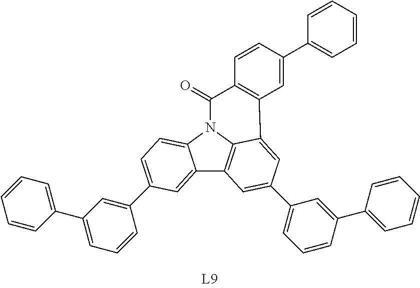 [SMILES: O=c1c2ccc(-c3ccccc3)cc2c2cc(-c3cccc(-c4ccccc4)c3)cc3c4cc(-c5cccc(-c6ccccc6)c5)ccc4n1c23] | |

### Synthesis Examples L6 and L7

### D: Monobromination

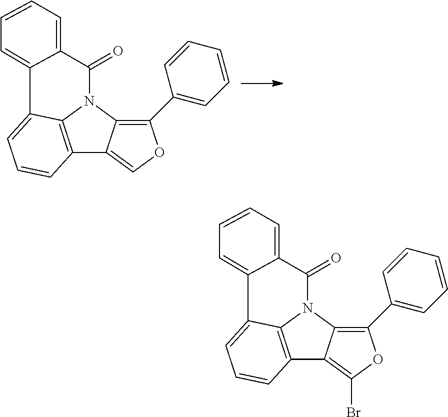 [SMILES: O=c1c2ccccc2c2cccc3c4coc(-c5ccccc5)c4n1c23 ; O=c1c2ccccc2c2cccc3c4c(Br)oc(-c5ccccc5)c4n1c23]

7.4 g (22.2 mmol) of 3a are initially introduced in 150 ml of CH₂Cl₂. A solution of 4 g (22.5 mmol) of NBS in 100 ml of acetonitrile is subsequently added dropwise at −15° C. with exclusion of light, the mixture is allowed to come to room temperature, and stirring is continued at this temperature for 4 h. 150 ml of water are subsequently added to the mixture, which is then extracted with CH₂Cl₂. The organic phase is dried over MgSO₄, and the solvents are removed in vacuo. The product is washed by stirring with hot hexane and filtered off with suction. Yield: 7.3 g (17.7 mmol), 80% of theory, purity according to ¹H-NMR about 97%.

The following compounds are obtained analogously:

| Ex. | Starting material 1 | Product 1 | Yield |
|---|---|---|---|
| D1 | 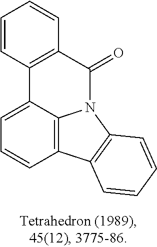 [SMILES: O=c1c2ccccc2c2cccc3c4ccccc4n1c23] | 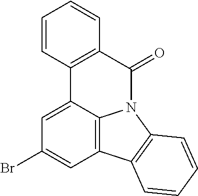 [SMILES: O=c1c2ccccc2c2cc(Br)cc3c4ccccc4n1c23] | 48% |
| D3 | 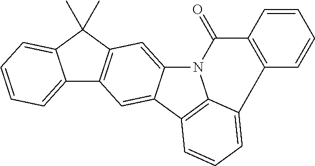 [SMILES: CC1(C)c2ccccc2-c2cc3c4cccc5c6ccccc6c(=O)n(c3cc21)c54] | 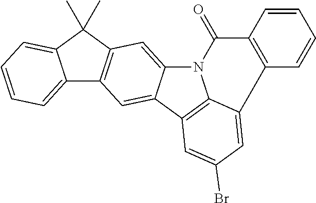 [SMILES: CC1(C)c2ccccc2-c2cc3c4cc(Br)cc5c6ccccc6c(=O)n(c3cc21)c54] | 69% |

### C: Suzuki Reaction

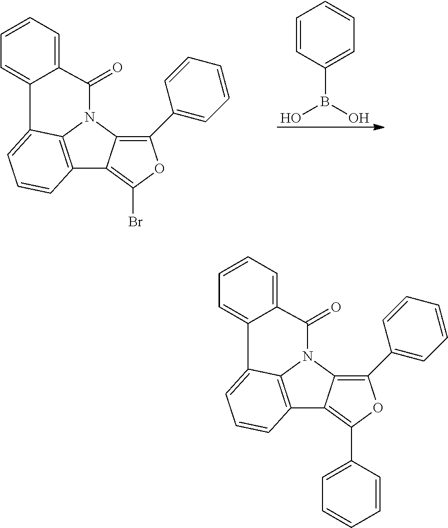 [SMILES: O=c1c2ccccc2c2cccc3c4c(Br)oc(-c5ccccc5)c4n1c23 ; OB(O)c1ccccc1 ; O=c1c2ccccc2c2cccc3c4c(-c5ccccc5)oc(-c5ccccc5)c4n1c23]

13.3 g (110.0 mmol) of phenylboronic acid, 45 g (110.0 mmol) of 4a and 44.6 g (210.0 mmol) of tripotassium phosphate are suspended in 500 ml of toluene, 500 ml of dioxane and 500 ml of water. 913 mg (3.0 mmol) of tri-o-tolylphosphine and then 112 mg (0.5 mmol) of palladium(II) acetate are added to this suspension, and the reaction mixture is heated under reflux for 16 h. After cooling, the organic phase is separated off, filtered through silica gel, washed three times with 200 ml of water and subsequently evaporated to dryness. The residue is recrystallised from toluene and from dichloromethane/isopropanol and finally sublimed in a high vacuum. The purity is 99.9%. The yield is 37 g (90 mmol), corresponding to 83% of theory.

The following compounds are obtained analogously:

| Ex. | Starting material 1 | Starting material 2 | Product | Yield |
|---|---|---|---|---|
| C1 | 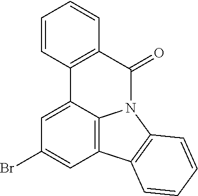 [SMILES: O=c1c2ccccc2c2cc(Br)cc3c4ccccc4n1c23] | 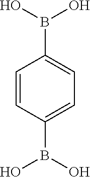 [SMILES: OB(O)c1ccc(B(O)O)cc1] | 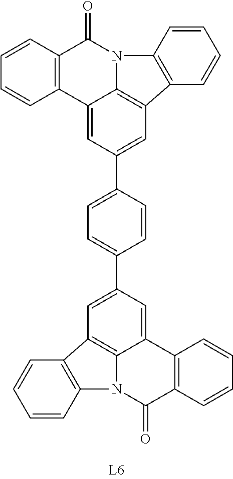 [SMILES: O=c1c2ccccc2c2cc(-c3ccc(-c4cc5c6ccccc6c(=O)n6c7ccccc7c(c4)c56)cc3)cc3c4ccccc4n1c23] | 64% |
| C2 | 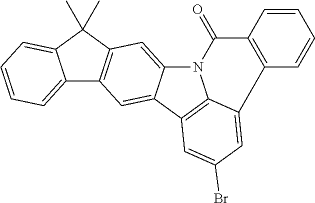 [SMILES: CC1(C)c2ccccc2-c2cc3c4cc(Br)cc5c6ccccc6c(=O)n(c3cc21)c54] | 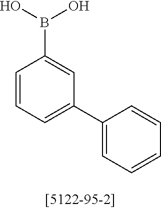 [SMILES: OB(O)c1cccc(-c2ccccc2)c1] | 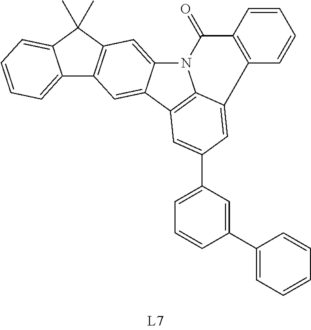 [SMILES: CC1(C)c2ccccc2-c2cc3c4cc(-c5cccc(-c6ccccc6)c5)cc5c6ccccc6c(=O)n(c3cc21)c54] | 87% |

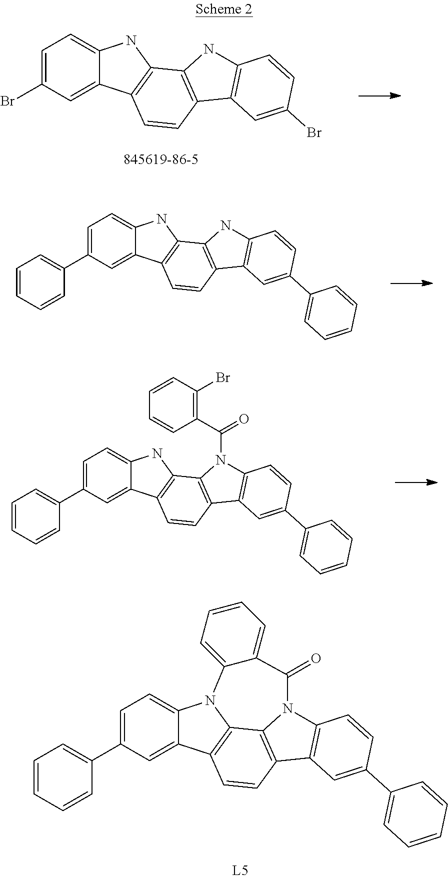 [SMILES: Brc1ccc2[nH]c3c(ccc4c5cc(Br)ccc5[nH]c43)c2c1 ; c1ccc(-c2ccc3[nH]c4c(ccc5c6cc(-c7ccccc7)ccc6[nH]c54)c3c2)cc1 ; O=C(c1ccccc1Br)n1c2ccc(-c3ccccc3)cc2c2ccc3c4cc(-c5ccccc5)ccc4[nH]c3c21 ; O=c1c2ccccc2n2c3ccc(-c4ccccc4)cc3c3ccc4c5cc(-c6ccccc6)ccc5n1c4c32]

### 1st step: 3-[(Z)-1-Eth-(E)-ylidenepenta-2,4-dienyl]-8-phenyl-11,12-dihydro-11,12-diazaindeno[2,1-a]fluorene

13.3 g (110 mmol) of phenylboronic acid, 20 g (50 mmol) of 3,8-dibromo-11,12-dihydroindolo[2,3-a]carbazole and 45 g (210 mmol) of tripotassium phosphate are suspended in 500 ml of toluene, 500 ml of dioxane and 500 ml of water. 910 mg (3.0 mmol) of tri-o-tolylphosphine and then 112 mg (0.5 mmol) of palladium(II) acetate are added to this suspension, and the reaction mixture is heated under reflux for 16 h. After cooling, the organic phase is separated off, filtered through silica gel, washed three times with 200 ml of water and subsequently evaporated to dryness. The residue is recrystallised from toluene and from dichloromethane/isopropanol. The yield is 16 g (39 mmol), corresponding to 80% of theory.

### 2nd step: (2-Bromophenyl)-(3,8-diphenyl-12H-11,12-diazaindeno[2,1-a]-fluoren-11-yl)methanone

2.1 g (53 mmol) of NaH (60% in mineral oil) are dissolved in 500 ml of THE under a protective atmosphere. 20 g (50 mmol) of 3-[(Z)-1-eth-(E)-ylidenepenta-2,4-dienyl]-8-phenyl-11,12-dihydro-11,12-diazaindeno[2,1-a]fluorene and 12 g (53 mmol) of 15-crown-5 dissolved in 200 ml of THE are added. After 1 h at room temperature, a solution of 12 g (55 mmol) of 2-bromobenzoyl chloride in 250 ml of THF is added dropwise. The reaction mixture is stirred at room temperature for 18 h. After this time, the reaction mixture is poured onto ice and extracted three times with dichloromethane. The combined organic phases are dried over Na₂SO₄ and evaporated. The residue is extracted with hot toluene and recrystallised from toluene/n-heptane. The yield is 22 g (75%).

### 3rd Step

### Example L5

150 ml of di-n-butyl ether are added to 85 g (145 mmol) of (2-bromophenyl)-(3,8-diphenyl-12H-11,12-diazaindeno[2,1-a]fluoren-11-yl)methanone, and the solution is degassed. 10 g (158 mmol) of copper powder, 1.38 g (7 mmol) of copper(I) iodide and 22 g (160 mmol) of K₂CO₃ are subsequently added to the mixture, which is then stirred at 144° C. under protective gas for 4 days. The organic phase is dried over MgSO₄, and the solvent is removed in vacuo. The residue is recrystallised from acetone and finally sublimed in a high vacuum. Yield: 63 g (124 mmol), 86% of theory, purity according to HPLC 99.9%.

### Synthesis of Triazine Derivatives IC4 and IC05 which are not Known from the Literature

### Precursor: (2-Chlorophenyl)-4-spiro-9,9′-bifluorenylamine

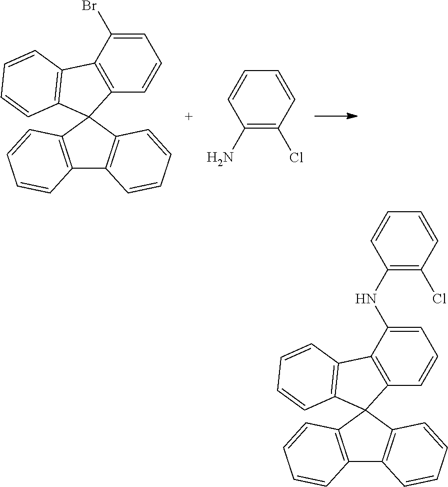 [SMILES: Brc1cccc2c1-c1ccccc1C21c2ccccc2-c2ccccc21 ; Nc1ccccc1Cl ; Clc1ccccc1Nc1cccc2c1-c1ccccc1C21c2ccccc2-c2ccccc21]

54 g (137 mmol) of 4-bromospiro-9,9′-bifluorene, 17.9 g (140 mmol) of 2-chloroaniline, 68.2 g (710 mmol) of sodium tert-butoxide, 613 mg (3 mmol) of palladium(II) acetate and 3.03 g (5 mmol) of dppf are dissolved in 1.3 l of toluene, and the mixture is stirred under reflux for 5 h. The reaction mixture is cooled to room temperature, extended with toluene and filtered through Celite. The filtrate is evaporated in vacuo, and the residue is recrystallised from toluene/heptane. The product is isolated as a colourless solid. Yield: 52.2 g (118 mmol), 86% of theory.

### Precursor: Spiro[9H-fluoren-9,7′(1′H)-indeno[1,2-a]carbazole]

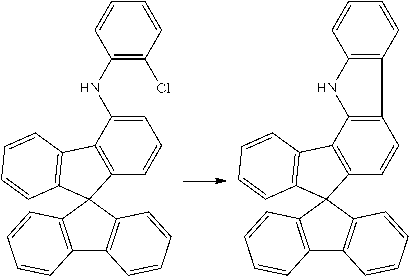 [SMILES: Clc1ccccc1Nc1cccc2c1-c1ccccc1C21c2ccccc2-c2ccccc21 ; c1ccc2c(c1)-c1ccccc1C21c2ccccc2-c2c1ccc1c2[nH]c2ccccc21]

45 g (102 mmol) of (2-chlorophenyl)-4-spiro-9,9′-bifluorenylamine, 56 g (409 mmol) of potassium carbonate, 4.5 g (12 mmol) of tricyclohexylphosphine tetrafluoroborate, 1.38 g (6 mmol) of palladium(II) acetate are suspended in 500 ml of dimethylacetamide, and the mixture is stirred under reflux for 6 h.

After cooling, 300 ml of water are added to the reaction mixture, and the organic phase is extended with 600 ml of dichloromethane. The mixture is stirred for a further 30 min., the organic phase is separated off, filtered through a short Celite bed, and the solvent is then removed in vacuo. The crude product is extracted with hot toluene and recrystallised from toluene. The product is isolated as a beige solid (32.5 g, 80 mmol, 78% of theory).

### Synthesis of IC4 (spiro[9H-fluoren-9,7′(12′H)-indeno[1,2-a]carbazole]-12′-[2-(4,6-diphenyl-1,3,5-triazin-2-yl)])

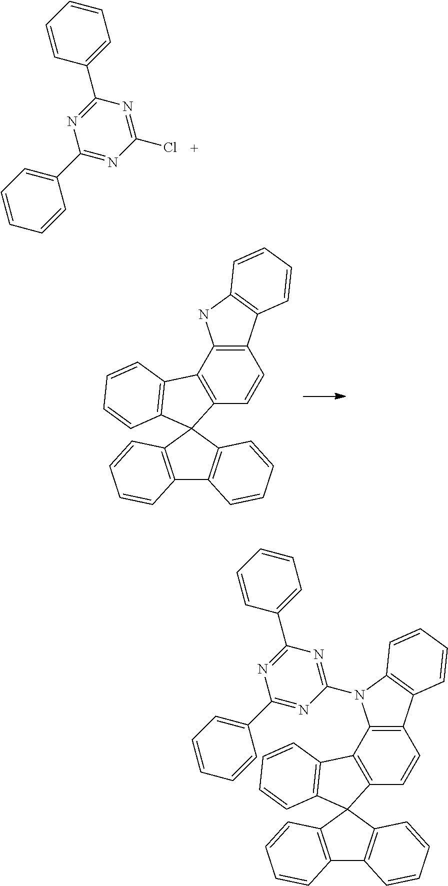 [SMILES: Clc1nc(-c2ccccc2)nc(-c2ccccc2)n1 ; c1ccc2c(c1)-c1ccccc1C21c2ccccc2-c2c1ccc1c2[nH]c2ccccc21 ; c1ccc(-c2nc(-c3ccccc3)nc(-n3c4ccccc4c4ccc5c(c43)-c3ccccc3C53c4ccccc4-c4ccccc43)n2)cc1]

4.2 g of 60% NaH in mineral oil (0.106 mol) are dissolved in 300 ml of dimethylformamide under a protective atmosphere. 43 g (0.106 mol) of spiro[9H-fluoren-9,7′(1′H)-indeno[1,2-a]carbazole] are dissolved in 250 ml of DMF and added dropwise to the reaction mixture. After 1 h at room temperature, a solution of 2-chloro-4,6-diphenyl-1,3,5-triazine (34.5 g, 0.122 mol) in 200 ml of THF is added dropwise. The reaction mixture is then stirred at room temperature for 12 h and then poured onto ice. After warming to room temperature, the precipitated solid is filtered off and washed with ethanol and heptane. The residue is extracted with hot toluene, recrystallised from toluene/n-heptane and finally sublimed in a high vacuum. The purity is 99.9%. The yield is 28.4 g (44.5 mmol; 42%).

### Synthesis of IC5

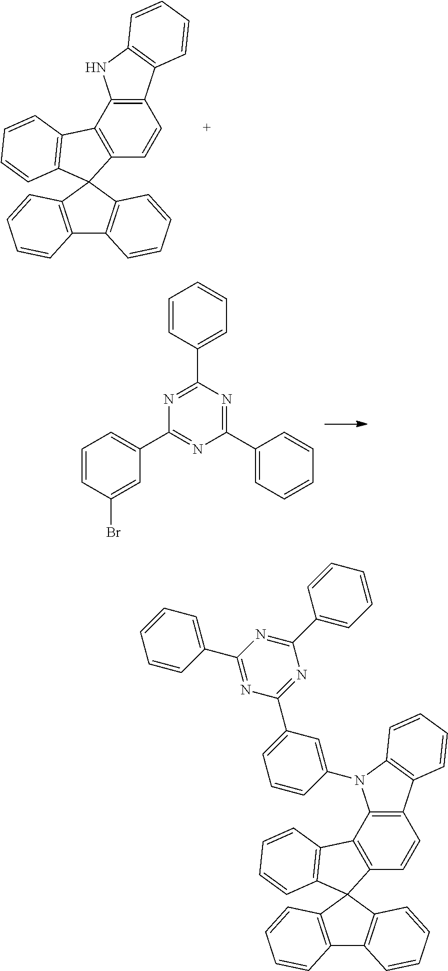 [SMILES: c1ccc2c(c1)-c1ccccc1C21c2ccccc2-c2c1ccc1c2[nH]c2ccccc21 ; Brc1cccc(-c2nc(-c3ccccc3)nc(-c3ccccc3)n2)c1 ; c1ccc(-c2nc(-c3ccccc3)nc(-c3cccc(-n4c5ccccc5c5ccc6c(c54)-c4ccccc4C64c5ccccc5-c5ccccc54)c3)n2)cc1]

20.9 g (51.5 mmol) of spiro[9H-fluoren-9,7′(1′H)-indeno[1,2-a]carbazole], 20 g (51.5 mmol) of 2-(3-bromophenyl)-4,6-diphenyl-1,3,5-triazine (CAS 864377-31-1) and 15 g of NaOtBu are suspended in 11 of p-xylene. 0.23 g (1 mmol) of Pd(OAc)₂ and 2 ml of a 1M tri-tert-butylphosphine solution are added to this suspension. The reaction mixture is heated under reflux for 16 h. After cooling, the organic phase is separated off, washed three times with 200 ml of water and subsequently evaporated to dryness. The residue is extracted with hot toluene, recrystallised from toluene and finally sublimed in a high vacuum. The purity is 99.9% with a yield of 13.8 g (19.3 mmol; 38%).

### Production of OLEDs

The data for various OLEDs are presented in Examples V1 to E93 below (see Tables 1 and 2).

### Pretreatment for Examples E1-E25

Cleaned glass plates (cleaning in Miele laboratory dishwasher, Merck Extran detergent) which have been coated with structured ITO (indium tin oxide) in a thickness of 50 nm are coated with 20 nm of PEDOT:PSS (poly(3,4-ethylenedioxythiophene) poly(styrene sulfonate), purchased as CLEVIOS™ P VP AI 4083 from Heraeus Precious Metals GmbH, Germany, applied from aqueous solution by spin coating) for improved processing. The samples are subsequently dried by heating at 180° C. for 10 min. These coated glass plates form the substrates to which the OLEDs are applied.

### Pretreatment for Examples E26-E64

Cleaned glass plates (cleaning in Miele laboratory dishwasher, Merck Extran detergent) which have been coated with structured ITO (indium tin oxide) in a thickness of 50 nm are treated with an oxygen plasma for 130 s. These plasma-treated glass plates form the substrates to which the OLEDs are applied. The substrates remain under vacuum before the coating. The coating begins within 10 min after the plasma treatment.

### Pretreatment for Examples E65-E93

Cleaned glass plates (cleaning in Miele laboratory dishwasher, Merck Extran detergent) which have been coated with structured ITO (indium tin oxide) in a thickness of 50 nm are treated with an oxygen plasma for 130 s and subsequently with an argon plasma for 150 s. These plasma-treated glass plates form the substrates to which the OLEDs are applied. The substrates remain under vacuum before the coating. The coating begins within 10 min after the plasma treatment.

The OLEDs basically have the following layer structure: substrate/hole-transport layer (HTL)/optional interlayer (IL)/electron-blocking layer (EBL)/emission layer (EML)/optional hole-blocking layer (HBL)/electron-transport layer (ETL)/optional electron-injection layer (EIL) and finally a cathode. The cathode is formed by an aluminium layer with a thickness of 100 nm. The precise structure of the OLEDs is shown in Table 1. The materials required for the production of the OLEDs are shown in Table 3. The LUMO values and T₁ levels of the compounds are summarised in Table 4.

All materials are applied by thermal vapour deposition in a vacuum chamber. The emission layer here always consists of at least one matrix material (host material) and an emitting dopant (emitter), which is admixed with the matrix material or matrix materials in a certain proportion by volume by co-evaporation. An expression such as ST1:L2:TEG1 (55%:35%:10%) here means that material ST1 is present in the layer in a proportion by volume of 55%, L2 is present in the layer in a proportion of 35% and TEG1 is present in the layer in a proportion of 10%. Analogously, the electron-transport layer may also consist of a mixture of two materials.

The OLEDs are characterised by standard methods. For this purpose, the electroluminescence spectra, the current efficiency (measured in cd/A), the power efficiency (measured in Im/W) and the external quantum efficiency (EQE, measured in percent) as a function of the luminous density, calculated from current/voltage/luminous density characteristic lines (IUL characteristic lines) assuming Lambert emission characteristics, and the lifetime are determined. The electroluminescence spectra are determined at a luminous density of 1000 cd/m², and the CIE 1931 x and y colour coordinates are calculated therefrom. The term U1000 in Table 2 denotes the voltage required for a luminous density of 1000 cd/m². CE1000 and PE1000 denote the current and power efficiency respectively which are achieved at 1000 cd/m². Finally, EQE1000 denotes the external quantum efficiency at an operating luminous density of 1000 cd/m². The lifetime LT is defined as the time after which the luminous density has dropped to a certain proportion L1 from the initial luminous density on operation at constant current density j₀. An expression L1=80% in Table 2 means that the lifetime indicated in column LT corresponds to the time after which the luminous density has dropped to 80% of its initial value.

The data for the various OLEDs are summarised in Table 2. Examples V1-V8 are comparative examples in accordance with the prior art, Examples E1-E93 show data of OLEDs according to the invention.

Some of the examples are explained in greater detail below in order to illustrate the advantages of the OLEDs according to the invention.

### Use of Mixtures According to the Invention in the Emission Layer of Phosphorescent OLEDs

The use of compounds according to the invention in combination with the wide bandgap material WB1 enables good external quantum efficiencies to be achieved (Examples V1-V8). On use of an electron-conducting second component, only a slight improvement in the EQE, owing to the lower voltage, but significantly improved power efficiencies of up to about 30% more are obtained (Examples V1, E7). Furthermore, excellent improvements with respect to the lifetime by more than double are obtained (Examples V2, E15).

Excellent lifetimes are obtained, in particular, with a mixture of compounds IC4 and L8 (Example E45), and excellent efficiency is obtained with CbzT4 and L1 (Example E61).

Furthermore, excellent performance data are obtained with mixtures of various lactams, electron-conducting compounds and phosphorescent emitters, which demonstrates the broad applicability of the layers according to the invention.

Use of Mixtures According to the Invention as Electron-Transport Layer

If, instead of a mixture of L1 and LiQ in accordance with the prior art, a mixture according to the invention of L1 and ST1 is used as electron-transport layer, a significantly better voltage and better efficiency and lifetime are obtained (Examples V3, E25).

TABLE 1
Structure of the OLEDs

| | HTL | IL | EBL | EML | HBL | ETL | EIL |
|---|---|---|---|---|---|---|---|
| Ex. | Thickness | Thickness | Thickness | Thickness | Thickness | Thickness | Thickness |
| V1 | SpA1 | HATCN | SpMA1 | L1:WB1:TEG1 | — | ST2:LiQ (50%:50%) | — |
| | 70 nm | 5 nm | 90 nm | (45%:45%:10%) 40 nm | | 30 nm | |
| V2 | SpA1 | HATCN | SpMA1 | L1:WB1:TEG1 | IC1 | ST2:LiQ (50%:50%) | — |
| | 70 nm | 5 nm | 90 nm | (45%:45%:10%) 40 nm | 5 nm | 25 nm | |
| V3 | SpA1 | HATCN | SpMA1 | IC1:TEG1 | — | L1:LiQ (50%:50%) | LiQ |
| | 70 nm | 5 nm | 90 nm | (90%:10%) 30 nm | | 40 nm | 3 nm |
| V4 | SpA1 | HATCN | SpMA1 | L1:TEG1 | — | ST2:LiQ (50%:50%) | — |
| | 70 nm | 5 nm | 90 nm | (90%:10%) 40 nm | | 30 nm | |
| V5 | SpA1 | HATCN | SpMA1 | IC1:TEG1 | — | ST2:LiQ (50%:50%) | — |
| | 70 nm | 5 nm | 90 nm | (90%:10%) 40 nm | | 30 nm | |
| V6 | SpA1 | HATCN | SpMA1 | IC3:TER1 | — | ST2:LiQ (50%:50%) | — |
| | 90 nm | 5 nm | 130 nm | (92%:8%) 40 nm | | 40 nm | |
| V7 | SpA1 | HATCN | SpMA1 | L2:WB1:TEG1 | — | ST2:LiQ (50%:50%) | — |
| | 70 nm | 5 nm | 90 nm | (45%:45%:10%) 40 nm | | 30 nm | |
| V8 | SpA1 | HATCN | SpMA1 | L2:WB1:TEG1 | — | ST2 | LiQ |
| | 70 nm | 5 nm | 90 nm | (45%:45%:10%) 40 nm | | 30 nm | 3 nm |
| E1 | SpA1 | HATCN | SpMA1 | L1:IC1:TEG1 | — | ST2:LiQ (50%:50%) | — |
| | 70 nm | 5 nm | 90 nm | (45%:45%:10%) 40 nm | | 30 nm | |
| E2 | SpA1 | HATCN | SpMA1 | L1:IC1:TEG1 | IC1 | ST2:LiQ (50%:50%) | — |
| | 70 nm | 5 nm | 90 nm | (45%:45%:10%) 40 nm | 5 nm | 25 nm | |
| E3 | SpA1 | HATCN | SpMA1 | L1:IC3:TEG1 | — | ST2:LiQ (50%:50%) | — |
| | 70 nm | 5 nm | 90 nm | (45%:45%:10%) 40 nm | | 30 nm | |
| E4 | SpA1 | HATCN | SpMA1 | L1:IC2:TEG1 | — | ST2:LiQ (50%:50%) | — |
| | 70 nm | 5 nm | 90 nm | (45%:45%:10%) 40 nm | | 30 nm | |
| E5 | SpA1 | HATCN | SpMA1 | L1:IC3:TEG1 | — | ST2 | LiQ |
| | 70 nm | 5 nm | 90 nm | (45%:45%:10%) 40 nm | | 30 nm | 3 nm |
| E6 | SpA1 | HATCN | SpMA1 | L1:CbzT1:TEG1 | — | ST2 | LiQ |
| | 70 nm | 5 nm | 90 nm | (45%:45%:10%) 40 nm | | 30 nm | 3 nm |
| E7 | SpA1 | HATCN | SpMA1 | L1:CbzT1:TEG1 | — | ST2:LiQ (50%:50%) | — |
| | 70 nm | 5 nm | 90 nm | (45%:45%:10%) 40 nm | | 30 nm | |
| E8 | SpA1 | HATCN | SpMA1 | L2:CbzT1:TEG1 | — | ST2 | LiQ |
| | 70 nm | 5 nm | 90 nm | (45%:45%:10%) 40 nm | | 30 nm | 3 nm |
| E9 | SpA1 | HATCN | SpMA1 | L2:CbzT1:TEG1 | — | ST2:LiQ (50%:50%) | — |
| | 70 nm | 5 nm | 90 nm | (45%:45%:10%) 40 nm | | 30 nm | |
| E10 | SpA1 | HATCN | SpMA1 | L2:IC3:TEG1 | — | ST2:LiQ (50%:50%) | — |
| | 70 nm | 5 nm | 90 nm | (45%:45%:10%) 40 nm | | 30 nm | |
| E11 | SpA1 | HATCN | SpMA1 | L2:IC3:TEG1 | — | ET1 | LiF |
| | 70 nm | 5 nm | 90 nm | (45%:45%:10%) 40 nm | | 30 nm | 1.5 nm |
| E12 | SpA1 | HATCN | SpMA1 | L2:IC3:TEG1 | IC1 | ET2:LiQ(50%:50%) | — |
| | 70 nm | 5 nm | 90 nm | (45%:45%:10%) 30 nm | 10 nm | 30 nm | |
| E13 | SpA1 | HATCN | SpMA1 | L2:IC3:TEG1 | — | ST2 | LiQ |
| | 70 nm | 5 nm | 90 nm | (45%:45%:10%) 40 nm | | 30 nm | 3 nm |
| E14 | SpA1 | HATCN | SpMA1 | L1:IC3:TER1 | — | ST2:LiQ (50%:50%) | — |
| | 70 nm | 5 nm | 130 nm | (46%:46%:8%) 40 nm | | 30 nm | |
| E15 | SpA1 | HATCN | SpMA1 | L1:CRL1:TEG1 | IC1 | ST2:LiQ (50%:50%) | — |
| | 70 nm | 5 nm | 90 nm | (45%:45%:10%) 40 nm | 5 nm | 25 nm | |
| E16 | SpA1 | HATCN | SpMA1 | L3:IC3:TEG1 | — | ST2:LiQ (50%:50%) | — |
| | 70 nm | 5 nm | 90 nm | (45%:45%:10%) 40 nm | | 30 nm | |
| E17 | SpA1 | HATCN | SpMA1 | L4:IC3:TEG1 | — | ST2:LiQ (50%:50%) | — |
| | 70 nm | 5 nm | 90 nm | (45%:45%:10%) 40 nm | | 30 nm | |
| E18 | SpA1 | HATCN | SpMA1 | L5:IC3:TEG1 | — | ST2:LiQ (50%:50%) | — |
| | 70 nm | 5 nm | 90 nm | (45%:45%:10%) 40 nm | | 30 nm | |
| E19 | SpA1 | HATCN | SpMA1 | L5:IC3:TEG1 | — | ST2 | LiQ |
| | 70 nm | 5 nm | 90 nm | (45%:45%:10%) 40 nm | | 30 nm | 3 nm |
| E20 | SpA1 | HATCN | SpMA1 | L6:IC3:TEG1 | — | ST2:LiQ (50%:50%) | — |
| | 70 nm | 5 nm | 90 nm | (45%:45%:10%) 40 nm | | 30 nm | |
| E21 | SpA1 | HATCN | SpMA1 | L7:IC3:TEG1 | ST2 | ST2:LiQ (50%:50%) | |
| | 70 nm | 5 nm | 90 nm | (45%:45%:10%) 30 nm | 10 nm | 30 nm | |
| E22 | SpA1 | HATCN | SpMA1 | L1:ST1:TEG1 | — | ST2:LiQ (50%:50%) | — |
| | 70 nm | 5 nm | 90 nm | (45%:45%:10%) 40 nm | | 30 nm | |
| E23 | SpA1 | HATCN | SpMA1 | L1:CbzT2:TEG1 | IC1 | ST2:LiQ (50%:50%) | — |
| | 70 nm | 5 nm | 90 nm | (45%:45%:10%) 40 nm | 5 nm | 25 nm | |
| E24 | SpA1 | HATCN | SpMA1 | L1:CbzT3:TEG1 | IC1 | ST2:LiQ (50%:50%) | — |
| | 70 nm | 5 nm | 90 nm | (45%:45%:10%) 40 nm | 5 nm | 25 nm | |
| E25 | SpA1 | HATCN | SpMA1 | IC1:TEG1 | — | L1:ST1 (50%:50%) | LiQ |
| | 70 nm | 5 nm | 90 nm | (90%:10%) 30 nm | | 40 nm | 3 nm |
| E26 | HATCN | SpMA1 | SpMA2 | IC3:L1:TEY1 | — | ST2:LiQ (50%:50%) | — |
| | 5 nm | 75 nm | 15 nm | (45%:45%:10%) 25 nm | | 45 nm | |
| E27 | HATCN | SpMA1 | SpMA2 | IC3:L1:TEY1 | — | ST2:LiQ (50%:50%) | — |
| | 5 nm | 75 nm | 15 nm | (60%:30%:10%) 25 nm | | 45 nm | |
| E28 | HATCN | SpMA1 | SpMA2 | IC3:L1:TEY1 | — | ST2:LiQ (50%:50%) | — |
| | 5 nm | 75 nm | 15 nm | (30%:60%:10%) 25 nm | | 45 nm | |
| E29 | HATCN | SpMA1 | SpMA2 | IC3:L1:TEY1 | — | ST2:LiQ (50%:50%) | — |
| | 5 nm | 75 nm | 15 nm | (20%:70%:10%) 25 nm | | 45 nm | |
| E30 | HATCN | SpMA1 | SpMA2 | IC3:L1:TEY1 | — | ST2:LiQ (50%:50%) | — |
| | 5 nm | 75 nm | 15 nm | (48%:47%:5%) 25 nm | | 45 nm | |
| E31 | HATCN | SpMA1 | SpMA2 | IC3:L1:TEY1 | — | ST2:LiQ (50%:50%) | — |
| | 5 nm | 75 nm | 15 nm | (47%:46%:7%) 25 nm | | 45 nm | |
| E32 | HATCN | SpMA1 | SpMA2 | IC3:L1:TEY1 | — | ST2:LiQ (50%:50%) | — |
| | 5 nm | 75 nm | 15 nm | (43%:42%:15%) 25 nm | | 45 nm | |
| E33 | HATCN | SpMA1 | SpMA2 | IC3:L1:TEY1 | — | ST2 | LiQ |
| | 5 nm | 75 nm | 15 nm | (45%:45%:10%) 25 nm | | 45 nm | 3 nm |
| E34 | HATCN | SpMA1 | SpMA2 | IC3:L1:TEY1 | — | ST2 | LiQ |
| | 5 nm | 75 nm | 15 nm | (60%:30%:10%) 25 nm | | 45 nm | 3 nm |
| E35 | HATCN | SpMA1 | SpMA2 | IC3:L1:TEY1 | — | ST2 | LiQ |
| | 5 nm | 75 nm | 15 nm | (30%:60%:10%) 25 nm | | 45 nm | 3 nm |
| E36 | HATCN | SpMA1 | SpMA2 | IC3:L1:TEY1 | — | ST2 | LiQ |
| | 5 nm | 75 nm | 15 nm | (20%:70%:10%) 25 nm | | 45 nm | 3 nm |
| E37 | HATCN | SpMA1 | SpMA2 | IC3:L1:TEY1 | — | ST2 | LiQ |
| | 5 nm | 75 nm | 15 nm | (48%:47%:5%) 25 nm | | 45 nm | 3 nm |
| E38 | HATCN | SpMA1 | SpMA2 | IC3:L1:TEY1 | — | ST2 | LiQ |
| | 5 nm | 75 nm | 15 nm | (47%:46%:7%) 25 nm | | 45 nm | 3 nm |
| E39 | HATCN | SpMA1 | SpMA2 | IC3:L1:TEY1 | — | ST2 | LiQ |
| | 5 nm | 75 nm | 15 nm | (43%:42%:15%) 25 nm | | 45 nm | 3 nm |
| E40 | HATCN | — | SpMA2 | IC3:L7:TEY2 | — | ST1 | LiQ |
| | 5 nm | | 90 m | (40%:50%:10%) 30 nm | | 40 nm | 3 nm |
| E41 | HATCN | — | SpMA2 | IC3:L8:TEY2 | — | ST1 | LiQ |
| | 5 nm | | 90 m | (45%:45%:10%) 30 nm | | 40 nm | 3 nm |
| E42 | HATCN | — | SpMA2 | IC3:L8:TEY2 | — | ST1 | LiQ |
| | 5 nm | | 90 m | (47%:48%:15%) 30 nm | | 40 nm | 3 nm |
| E43 | HATCN | SpMA1 | SpMA2 | L1:L8:TEY2 | — | ST1 | LiQ |
| | 5 nm | 75 nm | 15 nm | (45%:45%:10%) 30 nm | | 40 nm | 3 nm |
| E44 | HATCN | — | SpMA2 | L8:IC4:TEY2 | — | ST1 | LiQ |
| | 5 nm | | 90 m | (45%:45%:10%) 30 nm | | 40 nm | 3 nm |
| E45 | HATCN | — | SpMA5 | L8:IC4:TEY2 | — | ST1 | LiQ |
| | 5 nm | | 90 m | (45%:45%:10%) 30 nm | | 40 nm | 3 nm |
| E46 | HATCN | — | SpMA4 | L8:IC4:TEY2 | — | ST1 | LiQ |
| | 5 nm | | 90 m | (45%:45%:10%) 30 nm | | 40 nm | 3 nm |
| E47 | HATCN | — | SpMA6 | L8:IC4:TEY2 | — | ST1 | LiQ |
| | 5 nm | | 90 m | (45%:45%:10%) 30 nm | | 40 nm | 3 nm |
| E48 | HATCN | — | SpMA2 | L8:CbzT3:TEY2 | — | ST1 | LiQ |
| | 5 nm | | 90 m | (45%:45%:10%) 30 nm | | 40 nm | 3 nm |
| E49 | HATCN | — | SpMA2 | L8:IC6:TEY2 | — | ST1 | LiQ |
| | 5 nm | | 90 m | (45%:45%:10%) 30 nm | | 40 nm | 3 nm |
| E50 | HATCN | — | SpMA5 | L8:IC6:TEY2 | — | ST1 | LiQ |
| | 5 nm | | 90 m | (45%:45%:10%) 30 nm | | 40 nm | 3 nm |
| E51 | HATCN | — | SpMA4 | L8:IC6:TEY2 | — | ST1 | LiQ |
| | 5 nm | | 90 m | (45%:45%:10%) 30 nm | | 40 nm | 3 nm |
| E52 | HATCN | — | SpMA6 | L8:IC6:TEY2 | — | ST1 | LiQ |
| | 5 nm | | 90 m | (45%:45%:10%) 30 nm | | 40 nm | 3 nm |
| E53 | HATCN | SpMA1 | SpMA2 | IC3:L9:TEY2 | — | ST2 | LiQ |
| | 5 nm | 75 nm | 10 nm | (45%:45%:10%) 25 nm | | 45 nm | 3 nm |
| E54 | HATCN | SpMA1 | SpMA2 | IC3:L1:TEY2 | — | ST2 | LiQ |
| | 5 nm | 75 nm | 10 nm | (45%:45%:10%) 25 nm | | 45 nm | 3 nm |
| E55 | HATCN | SpMA1 | SpMA2 | CbzT1:L1:TEY2 | — | ST2 | LiQ |
| | 5 nm | 70 nm | 15 nm | (45%:45%:10%) 30 nm | | 40 nm | 3 nm |
| E56 | HATCN | SpMA7 | SpMA2 | CbzT1:L1:TEY2 | — | ST2 | LiQ |
| | 5 nm | 70 nm | 15 nm | (45%:45%:10%) 30 nm | | 40 nm | 3 nm |
| E57 | HATCN | SpMA1 | SpMA8 | CbzT1:L1:TEY2 | — | ST2 | LiQ |
| | 5 nm | 70 nm | 15 nm | (45%:45%:10%) 30 nm | | 40 nm | 3 nm |
| E58 | HATCN | SpMA7 | SpMA8 | CbzT1:L1:TEY2 | — | ST2 | LiQ |
| | 5 nm | 70 nm | 15 nm | (45%:45%:10%) 30 nm | | 40 nm | 3 nm |
| E59 | HATCN | CbzA1 | SpMA2 | CbzT1:L1:TEY2 | — | ST2 | LiQ |
| | 5 nm | 70 nm | 15 nm | (45%:45%:10%) 30 nm | | 40 nm | 3 nm |
| E60 | HATCN | SpMA9 | SpMA2 | CbzT1:L1:TEY2 | — | ST2 | LiQ |
| | 5 nm | 70 nm | 15 nm | (45%:45%:10%) 30 nm | | 40 nm | 3 nm |
| E61 | HATCN | SpMA1 | SpMA2 | CbzT4:L1:TEY2 | — | ST2 | LiQ |
| | 5 nm | 70 nm | 15 nm | (45%:45%:10%) 25 nm | | 45 nm | 3 nm |
| E62 | HATCN | SpMA1 | SpMA2 | CbzT5:L1:TEY2 | — | ST2 | LiQ |
| | 5 nm | 70 nm | 15 nm | (45%:45%:10%) 25 nm | | 45 nm | 3 nm |
| E63 | HATCN | SpMA1 | SpMA2 | CbzT1:L1:TEY1 | — | ST2:LiQ (50%:50%) | — |
| | 5 nm | 75 nm | 15 nm | (45%:45:10%) 25 nm | | 45 nm | |
| E64 | HATCN | SpMA1 | SpMA2 | CbzT1:L1:TEY1 | — | ST2 | LiQ |
| | 5 nm | 75 nm | 15 nm | (45%:45:10%) 25 nm | | 45 nm | 3 nm |
| E65 | SpMA1:F4T | SpMA1 | SpMA3 | IC4:L1:TEG2 | ST2 | ST2:LiQ (50%:50%) | LiQ |
| | (95%:5%) 20 nm | 200 nm | 20 nm | (53%:30%:17%) 30 nm | 10 nm | 30 nm | 1 nm |
| E66 | SpMA1:F4T | SpMA1 | SpMA3 | IC4:L1:TEG2 | ST2 | ST2:LiQ (50%:50%) | LiQ |
| | (95%:5%) 20 nm | 200 nm | 20 nm | (38%:50%:12%) 30 nm | 10 nm | 30 nm | 1 nm |
| E67 | SpMA1:F4T | SpMA1 | SpMA3 | IC4:L1:TEG2 | ST2 | ST2:LiQ (50%:50%) | LiQ |
| | (95%:5%) 20 nm | 200 nm | 20 nm | (33%:50%:17%) 30 nm | 10 nm | 30 nm | 1 nm |
| E68 | SpMA1:F4T | SpMA1 | SpMA3 | IC5:L1:TEG2 | ST2 | ST2:LiQ (50%:50%) | LiQ |
| | (95%:5%) 20 nm | 200 nm | 20 nm | (53%:30%:17%) 30 nm | 10 nm | 30 nm | 1 nm |
| E69 | SpMA1:F4T | SpMA1 | SpMA3 | IC5:L1:TEG2 | ST2 | ST2:LiQ (50%:50%) | LiQ |
| | (95%:5%) 20 nm | 200 nm | 20 nm | (38%:50%:12%) 30 nm | 10 nm | 30 nm | 1 nm |
| E70 | SpMA1:F4T | SpMA1 | SpMA3 | L8:IC5:TEG2 | ST2 | ST2:LiQ (50%:50%) | LiQ |
| | (95%:5%) 20 nm | 200 nm | 20 nm | (58%:25%:17%) 30 nm | 10 nm | 30 nm | 1 nm |
| E71 | SpMA1:F4T | SpMA1 | SpMA10 | L8:IC5:TEG2 | ST2 | ST2:LiQ (50%:50%) | LiQ |
| | (95%:5%) 20 nm | 200 nm | 20 nm | (58%:25%:17%) 30 nm | 10 nm | 30 nm | 1 nm |
| E72 | SpMA1:F4T | SpMA1 | SpMA3 | IC5:L7:TEG2 | ST2 | ST2:LiQ (50%:50%) | LiQ |
| | (95%:5%) 20 nm | 200 nm | 20 nm | (63%:25%:12%) 30 nm | 10 nm | 30 nm | 1 nm |
| E73 | SpMA1:F4T | SpMA1 | SpMA3 | IC5:L7:TEG2 | ST2 | ST2:LiQ (50%:50%) | LiQ |
| | (95%:5%) 20 nm | 200 nm | 20 nm | (23%:65%:12%) 30 nm | 10 nm | 30 nm | 1 nm |
| E74 | SpMA1:F4T | SpMA1 | SpMA3 | IC3:L9:TEG2 | — | ST2:LiQ (50%:50%) | — |
| | (95%:5%) 20 nm | 210 nm | 10 nm | (40%:45%:15%) 30 nm | | 40 nm | |
| E75 | SpMA1:F4T | SpMA1 | SpMA3 | IC3:L9:TEG2 | — | ST2:LiQ (50%:50%) | — |
| | (95%:5%) 20 nm | 210 nm | 10 nm | (45%:45%:10%) 30 nm | | 40 nm | |
| E76 | SpMA1:F4T | SpMA1 | SpMA2 | IC3:L9:TEG1 | — | ST2:LiQ (50%:50%) | — |
| | (95%:5%) 20 nm | 220 nm | 10 nm | (45%:45%:10%) 30 nm | | 40 nm | |
| E77 | SpMA1:F4T | — | SpMA1 | IC4:L9:TEG2 | — | ST2:LiQ (50%:50%) | — |
| | (95%:5%) 20 nm | | 220 nm | (35%:45%:20%) | | 40 nm | |
| E78 | SpMA1:F4T | — | SpMA1 | IC4:L9:TEG2 | — | ST2:LiQ (50%:50%) | — |
| | (95%:5%) 20 nm | | 220 nm | (45%:45%:10%) | | 40 nm | |
| E79 | SpMA1:F4T | — | SpMA1 | IC4:L9:TEG2 | — | ST2:LiQ (50%:50%) | — |
| | (95%:5%) 20 nm | | 220 nm | (40%:45%:15%) | | 40 nm | |
| E80 | SpMA1:F4T | SpMA1 | SpMA2 | IC4:L9:TEG2 | — | ST2:LiQ (50%:50%) | — |
| | (95%:5%) 20 nm | 210 nm | 10 nm | (35%:45%:20%) | | 40 nm | |
| E81 | SpMA1:F4T | SpMA1 | SpMA2 | IC4:L9:TEG2 | — | ST2:LiQ (50%:50%) | — |
| | (95%:5%) 20 nm | 210 nm | 10 nm | (40%:45%:15%) | | 40 nm | |
| E82 | SpMA1:F4T | SpMA1 | SpMA2 | L8:IC4:TEG2 | ST2 | ST2:LiQ (50%:50%) | LiQ |
| | (95%:5%) 20 nm | 200 nm | 20 nm | (63%:25%:12%) | 10 nm | 30 nm | 1 nm |
| E83 | SpMA1:F4T | SpMA1 | SpMA2 | L8:IC4:TEG2 | ST2 | ST2:LiQ (50%:50%) | LiQ |
| | (95%:5%) 20 nm | 200 nm | 20 nm | (58%:25%:17%) | 10 nm | 30 nm | 1 nm |
| E84 | SpMA1:F4T | SpMA1 | SpMA2 | L8:IC4:TEG2 | ST2 | ST2:LiQ (50%:50%) | LiQ |
| | (95%:5%) 20 nm | 200 nm | 20 nm | (38%:45%:17%) | 10 nm | 30 nm | 1 nm |
| E85 | SpMA1:F4T | SpMA1 | SpMA2 | L8:IC4:TEG2 | ST2 | ST2:LiQ (50%:50%) | LiQ |
| | (95%:5%) 20 nm | 200 nm | 20 nm | (18%:65%:17%) | 10 nm | 30 nm | 1 nm |
| E86 | SpMA1:F4T | SpMA1 | SpMA4 | L8:IC4:TEG2 | ST2 | ST2:LiQ (50%:50%) | LiQ |
| | (95%:5%) 20 nm | 200 nm | 20 nm | (63%:25%:12%) | 10 nm | 30 nm | 1 nm |
| E87 | SpMA1:F4T | SpMA1 | SpMA4 | L8:IC4:TEG2 | ST2 | ST2:LiQ (50%:50%) | LiQ |
| | (95%:5%) 20 nm | 200 nm | 20 nm | (43%:45%:12%) | 10 nm | 30 nm | 1 nm |
| E88 | SpMA1:F4T | SpMA1 | SpMA4 | L8:IC4:TEG2 | ST2 | ST2:LiQ (50%:50%) | LiQ |
| | (95%:5%) 20 nm | 200 nm | 20 nm | (58%:25%:17%) | 10 nm | 30 nm | 1 nm |
| E89 | SpMA1:F4T | SpMA1 | SpMA4 | L8:IC4:TEG2 | ST2 | ST2:LiQ (50%:50%) | LiQ |
| | (95%:5%) 20 nm | 200 nm | 20 nm | (38%:45%:17%) | 10 nm | 30 nm | 1 nm |
| E90 | SpMA1:F4T | SpMA1 | SpMA4 | L8:IC4:TEG2 | ST2 | ST2:LiQ (50%:50%) | LiQ |
| | (95%:5%) 20 nm | 200 nm | 20 nm | (18%:65%:17%) | 10 nm | 30 nm | 1 nm |
| E91 | SpMA1:F4T | SpMA1 | SpMA2 | L8:L7:TEG2 | ST2 | ST2:LiQ (50%:50%) | LiQ |
| | (95%:5%) 20 nm | 200 nm | 20 nm | (58%:25%:17%) | 10 nm | 30 nm | 1 nm |
| E92 | SpMA1:F4T | SpMA1 | SpMA4 | L8:L7:TEG2 | ST2 | ST2:LiQ (50%:50%) | LiQ |
| | (95%:5%) 20 nm | 200 nm | 20 nm | (58%:25%:17%) | 10 nm | 30 nm | 1 nm |
| E93 | SpMA1:F4T | SpMA1 | SpMA4 | L8:L7:TEG2 | ST2 | ST2:LiQ (50%:50%) | LiQ |
| | (95%:5%) 20 nm | 200 nm | 20 nm | (38%:45%:17%) | 10 nm | 30 nm | 1 nm |

TABLE 2
Data for the OLEDs

| | U1000 | CE1000 | PE1000 | EQE | CIE x/y at | | | LT |
|---|---|---|---|---|---|---|---|---|
| Ex. | (V) | (cd/A) | (lm/W) | 1000 | 1000 cd/m² | j₀ | L1 % | (h) |
| V1 | 4.0 | 64 | 51 | 17.1% | 0.33/0.62 | 20 mA/cm² | 80 | 130 |
| V2 | 3.9 | 62 | 50 | 16.9% | 0.32/0.63 | 20 mA/cm² | 80 | 125 |
| V3 | 3.8 | 56 | 46 | 15.6% | 0.33/0.62 | 20 mA/cm² | 80 | 120 |
| V4 | 3.4 | 58 | 54 | 16.1% | 0.33/0.62 | 20 mA/cm² | 80 | 140 |
| V5 | 3.6 | 56 | 49 | 15.7% | 0.33/0.62 | 20 mA/cm² | 80 | 145 |
| V6 | 4.5 | 11.2 | 7.8 | 12.1% | 0.67/0.33 | 40 mA/cm² | 80 | 340 |
| V7 | 3.5 | 60 | 55 | 16.2% | 0.33/0.62 | 20 mA/cm² | 80 | 120 |
| V8 | 3.3 | 58 | 55 | 16.0% | 0.33/0.62 | 20 mA/cm² | 80 | 100 |
| E1 | 3.3 | 61 | 58 | 16.5% | 0.33/0.62 | 20 mA/cm² | 80 | 205 |
| E2 | 3.3 | 62 | 59 | 16.6% | 0.33/0.63 | 20 mA/cm² | 80 | 210 |
| E3 | 3.1 | 63 | 63 | 17.3% | 0.33/0.62 | 20 mA/cm² | 80 | 230 |
| E4 | 3.2 | 61 | 60 | 17.0% | 0.32/0.62 | 20 mA/cm² | 80 | 190 |
| E5 | 2.9 | 62 | 67 | 17.1% | 0.33/0.62 | 20 mA/cm² | 80 | 155 |
| E6 | 2.7 | 61 | 70 | 16.9% | 0.33/0.62 | 20 mA/cm² | 80 | 170 |
| E7 | 2.9 | 62 | 67 | 17.2% | 0.33/0.62 | 20 mA/cm² | 80 | 260 |
| E8 | 2.6 | 59 | 71 | 16.4% | 0.32/0.62 | 20 mA/cm² | 80 | 165 |
| E9 | 3.0 | 62 | 65 | 17.2% | 0.33/0.62 | 20 mA/cm² | 80 | 140 |
| E10 | 2.9 | 57 | 61 | 15.8% | 0.32/0.63 | 20 mA/cm² | 80 | 200 |
| E11 | 4.0 | 49 | 38 | 13.6% | 0.32/0.62 | 20 mA/cm² | 80 | 260 |
| E12 | 3.5 | 58 | 52 | 16.0% | 0.33/0.62 | 20 mA/cm² | 80 | 235 |
| E13 | 2.7 | 57 | 66 | 15.9% | 0.32/0.63 | 20 mA/cm² | 80 | 135 |
| E14 | 4.2 | 12.0 | 8.9 | 13.0% | 0.67/0.33 | 40 mA/cm² | 80 | 455 |
| E15 | 3.0 | 52 | 55 | 14.7% | 0.32/0.62 | 20 mA/cm² | 80 | 290 |
| E16 | 3.2 | 61 | 60 | 16.7% | 0.32/0.62 | 20 mA/cm² | 80 | 175 |
| E17 | 3.3 | 57 | 55 | 16.0% | 0.33/0.62 | 20 mA/cm² | 80 | 130 |
| E18 | 3.4 | 58 | 54 | 16.2% | 0.32/0.62 | 20 mA/cm² | 80 | 145 |
| E19 | 3.2 | 58 | 57 | 16.1% | 0.33/0.62 | 20 mA/cm² | 80 | 120 |
| E20 | 3.0 | 59 | 62 | 16.5% | 0.32/0.62 | 20 mA/cm² | 80 | 255 |
| E21 | 3.2 | 60 | 59 | 16.0% | 0.32/0.62 | 20 mA/cm² | 80 | 240 |
| E22 | 3.1 | 60 | 60 | 16.5% | 0.32/0.62 | 20 mA/cm² | 80 | 155 |
| E23 | 3.5 | 53 | 48 | 14.8% | 0.32/0.63 | 20 mA/cm² | 80 | 190 |
| E24 | 3.4 | 55 | 51 | 15.4% | 0.33/0.63 | 20 mA/cm² | 80 | 215 |
| E25 | 3.3 | 58 | 54 | 15.4% | 0.33/0.62 | 20 mA/cm² | 80 | 140 |
| E26 | 2.8 | 72 | 80 | 20.6% | 0.44/0.55 | 50 mA/cm² | 95 | 110 |
| E27 | 2.8 | 73 | 81 | 20.8% | 0.44/0.55 | 50 mA/cm² | 95 | 90 |
| E28 | 2.9 | 72 | 78 | 20.8% | 0.44/0.55 | 50 mA/cm² | 95 | 105 |
| E29 | 3.0 | 72 | 77 | 20.7% | 0.44/0.55 | 50 mA/cm² | 95 | 105 |
| E30 | 2.8 | 72 | 79 | 20.0% | 0.42/0.57 | 50 mA/cm² | 95 | 85 |
| E31 | 2.8 | 72 | 79 | 20.3% | 0.43/0.56 | 50 mA/cm² | 95 | 105 |
| E32 | 2.9 | 63 | 68 | 18.4% | 0.45/0.55 | 50 mA/cm² | 95 | 100 |
| E33 | 2.6 | 75 | 89 | 21.5% | 0.44/0.55 | 50 mA/cm² | 95 | 42 |
| E34 | 2.6 | 74 | 90 | 21.6% | 0.44/0.55 | 50 mA/cm² | 95 | 43 |
| E35 | 2.7 | 74 | 87 | 21.5% | 0.44/0.55 | 50 mA/cm² | 95 | 45 |
| E36 | 2.7 | 75 | 86 | 21.6% | 0.44/0.55 | 50 mA/cm² | 95 | 50 |
| E37 | 2.6 | 74 | 89 | 20.7% | 0.43/0.56 | 50 mA/cm² | 95 | 50 |
| E38 | 2.6 | 74 | 89 | 20.9% | 0.43/0.56 | 50 mA/cm² | 95 | 48 |
| E39 | 2.7 | 68 | 81 | 19.8% | 0.45/0.54 | 50 mA/cm² | 95 | 40 |
| E40 | 3.0 | 84 | 87 | 24.9% | 0.44/0.55 | 50 mA/cm² | 90 | 165 |
| E41 | 2.7 | 76 | 89 | 22.4% | 0.44/0.55 | 50 mA/cm² | 90 | 350 |
| E42 | 2.7 | 75 | 87 | 22.0% | 0.44/0.55 | 50 mA/cm² | 90 | 375 |
| E43 | 2.6 | 86 | 103 | 24.9% | 0.43/0.56 | 50 mA/cm² | 90 | 100 |
| E44 | 2.9 | 87 | 95 | 25.6% | 0.44/0.55 | 50 mA/cm² | 90 | 345 |
| E45 | 2.8 | 86 | 96 | 25.5% | 0.45/0.55 | 50 mA/cm² | 90 | 480 |
| E46 | 2.9 | 88 | 94 | 26.0% | 0.44/0.55 | 50 mA/cm² | 90 | 210 |
| E47 | 2.9 | 85 | 92 | 25.1% | 0.44/0.55 | 50 mA/cm² | 90 | 210 |
| E48 | 3.0 | 86 | 90 | 25.3% | 0.44/0.55 | 50 mA/cm² | 90 | 130 |
| E49 | 2.7 | 84 | 97 | 24.4% | 0.44/0.55 | 50 mA/cm² | 90 | 190 |
| E50 | 2.9 | 83 | 91 | 24.6% | 0.44/0.55 | 50 mA/cm² | 90 | 225 |
| E51 | 3.0 | 86 | 91 | 25.4% | 0.44/0.55 | 50 mA/cm² | 90 | 140 |
| E52 | 2.9 | 80 | 86 | 23.5% | 0.44/0.55 | 50 mA/cm² | 90 | 180 |
| E53 | 2.6 | 78 | 93 | 22.8% | 0.45/0.55 | 50 mA/cm² | 90 | 195 |
| E54 | 2.7 | 82 | 94 | 23.8% | 0.44/0.55 | 50 mA/cm² | 90 | 115 |
| E55 | 2.7 | 81 | 95 | 23.8% | 0.44/0.55 | 50 mA/cm² | 90 | 255 |
| E56 | 2.5 | 82 | 102 | 23.9% | 0.44/0.55 | 50 mA/cm² | 90 | 330 |
| E57 | 2.9 | 84 | 92 | 24.3% | 0.44/0.55 | 50 mA/cm² | 90 | 190 |
| E58 | 2.7 | 85 | 100 | 24.8% | 0.44/0.55 | 50 mA/cm² | 90 | 300 |
| E59 | 2.9 | 79 | 85 | 23.5% | 0.45/0.54 | 50 mA/cm² | 90 | 110 |
| E60 | 2.9 | 85 | 91 | 24.7% | 0.43/0.56 | 50 mA/cm² | 90 | 170 |
| E61 | 2.8 | 90 | 103 | 26.0% | 0.43/0.56 | 50 mA/cm² | 90 | 105 |
| E62 | 2.8 | 88 | 93 | 25.9% | 0.45/0.55 | 50 mA/cm² | 90 | 140 |
| E63 | 2.9 | 66 | 73 | 19.0% | 0.43/0.56 | 50 mA/cm² | 95 | 125 |
| E64 | 2.7 | 69 | 81 | 19.6% | 0.44/0.56 | 50 mA/cm² | 95 | 48 |
| E65 | 3.3 | 71 | 68 | 18.9% | 0.35/0.62 | 40 mA/cm² | 80 | 235 |
| E66 | 3.4 | 70 | 65 | 18.8% | 0.35/0.62 | 40 mA/cm² | 80 | 170 |
| E67 | 3.3 | 71 | 68 | 18.9% | 0.34/0.63 | 40 mA/cm² | 80 | 270 |
| E68 | 3.2 | 74 | 72 | 19.7% | 0.34/0.63 | 40 mA/cm² | 80 | 210 |
| E69 | 3.3 | 74 | 71 | 19.7% | 0.34/0.63 | 40 mA/cm² | 80 | 165 |
| E70 | 3.4 | 59 | 55 | 16.6% | 0.32/0.63 | 40 mA/cm² | 80 | 345 |
| E71 | 3.4 | 56 | 52 | 15.6% | 0.32/0.63 | 40 mA/cm² | 80 | 370 |
| E72 | 3.4 | 82 | 77 | 22.2% | 0.33/0.63 | 40 mA/cm² | 80 | 190 |
| E73 | 3.7 | 78 | 66 | 20.9% | 0.33/0.63 | 40 mA/cm² | 80 | 225 |
| E74 | 3.1 | 60 | 60 | 16.1% | 0.31/0.64 | 20 mA/cm² | 90 | 410 |
| E75 | 3.1 | 61 | 63 | 16.9% | 0.30/0.64 | 20 mA/cm² | 90 | 235 |
| E76 | 3.2 | 63 | 62 | 17.3% | 0.33/0.63 | 20 mA/cm² | 80 | 340 |
| E77 | 3.1 | 52 | 53 | 14.4% | 0.31/0.64 | 20 mA/cm² | 90 | 395 |
| E78 | 3.2 | 53 | 52 | 14.4% | 0.31/0.64 | 20 mA/cm² | 90 | 420 |
| E79 | 3.1 | 58 | 60 | 16.0% | 0.31/0.64 | 20 mA/cm² | 90 | 460 |
| E80 | 3.3 | 58 | 56 | 15.7% | 0.31/0.64 | 20 mA/cm² | 90 | 365 |
| E81 | 3.2 | 65 | 64 | 17.9% | 0.31/0.64 | 20 mA/cm² | 90 | 300 |
| E82 | 3.5 | 69 | 63 | 18.4% | 0.35/0.62 | 40 mA/cm² | 80 | 235 |
| E83 | 3.4 | 65 | 60 | 17.3% | 0.35/0.62 | 40 mA/cm² | 80 | 405 |
| E84 | 3.3 | 68 | 64 | 18.2% | 0.35/0.62 | 40 mA/cm² | 80 | 320 |
| E85 | 3.3 | 71 | 69 | 19.0% | 0.35/0.62 | 40 mA/cm² | 80 | 220 |
| E86 | 3.2 | 67 | 67 | 18.0% | 0.35/0.62 | 40 mA/cm² | 80 | 325 |
| E87 | 3.1 | 70 | 71 | 18.8% | 0.35/0.61 | 40 mA/cm² | 80 | 245 |
| E88 | 3.1 | 67 | 69 | 18.0% | 0.35/0.62 | 40 mA/cm² | 80 | 425 |
| E89 | 3.2 | 67 | 67 | 18.1% | 0.35/0.61 | 40 mA/cm² | 80 | 315 |
| E90 | 3.0 | 69 | 72 | 18.5% | 0.35/0.61 | 40 mA/cm² | 80 | 220 |
| E91 | 3.2 | 73 | 71 | 19.6% | 0.33/0.64 | 40 mA/cm² | 80 | 155 |
| E92 | 3.0 | 73 | 77 | 19.4% | 0.33/0.63 | 40 mA/cm² | 80 | 185 |
| E93 | 3.0 | 78 | 81 | 20.8% | 0.33/0.63 | 40 mA/cm² | 80 | 160 |

TABLE 3
Structural formulae of the materials for the OLEDs

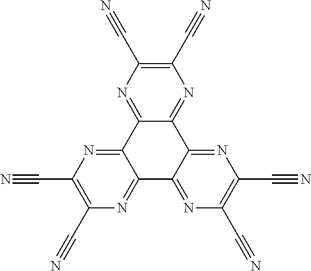 [SMILES: N#Cc1nc2c3nc(C#N)c(C#N)nc3c3nc(C#N)c(C#N)nc3c2nc1C#N]

HATCN

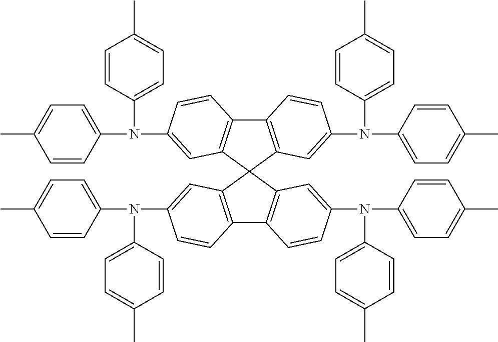

SpA1

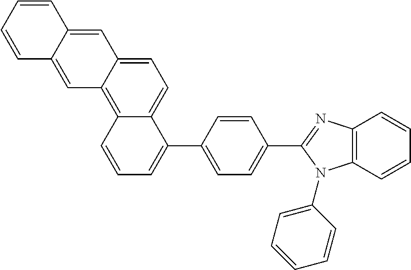 [SMILES: c1ccc(-n2c(-c3ccc(-c4cccc5c4ccc4cc6ccccc6cc45)cc3)nc3ccccc32)cc1]

ET1

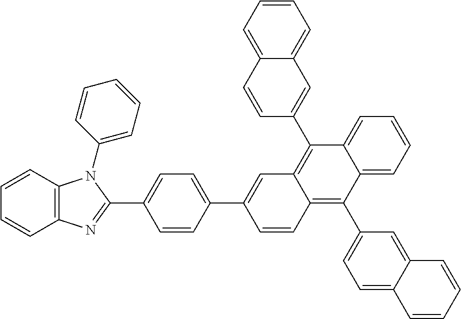 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1]

ET2

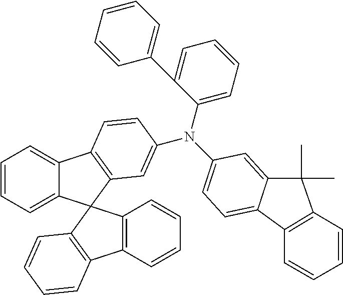 [SMILES: CC1(C)c2ccccc2-c2ccc(N(c3ccc4c(c3)C3(c5ccccc5-c5ccccc53)c3ccccc3-4)c3ccccc3-c3ccccc3)cc21]

SpMA1

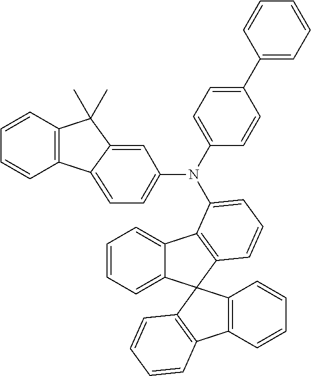 [SMILES: CC1(C)c2ccccc2-c2ccc(N(c3ccc(-c4ccccc4)cc3)c3cccc4c3-c3ccccc3C43c4ccccc4-c4ccccc43)cc21]

SpMA2

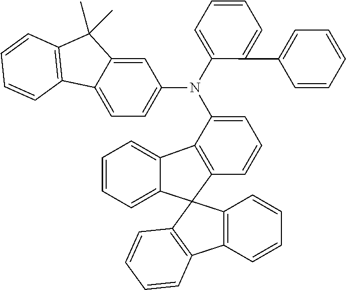 [SMILES: CC1(C)c2ccccc2-c2ccc(N(c3ccccc3-c3ccccc3)c3cccc4c3-c3ccccc3C43c4ccccc4-c4ccccc43)cc21]

SpMA3

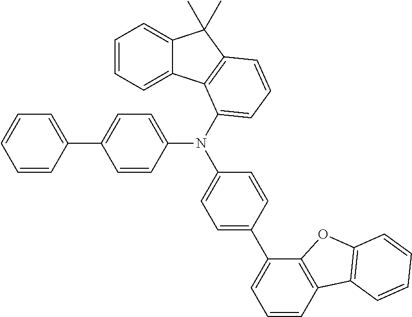 [SMILES: CC1(C)c2ccccc2-c2c(N(c3ccc(-c4ccccc4)cc3)c3ccc(-c4cccc5c4oc4ccccc45)cc3)cccc21]

SpMA4

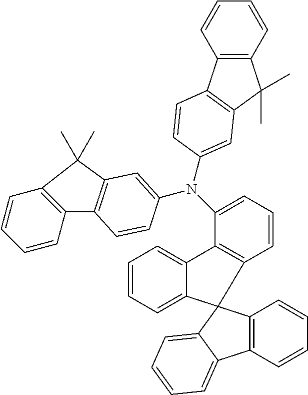 [SMILES: CC1(C)c2ccccc2-c2ccc(N(c3ccc4c(c3)C(C)(C)c3ccccc3-4)c3cccc4c3-c3ccccc3C43c4ccccc4-c4ccccc43)cc21]

SpMA5

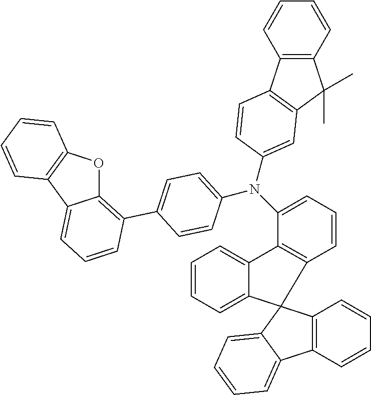 [SMILES: CC1(C)c2ccccc2-c2ccc(N(c3ccc(-c4cccc5c4oc4ccccc45)cc3)c3cccc4c3-c3ccccc3C43c4ccccc4-c4ccccc43)cc21]

SpMA6

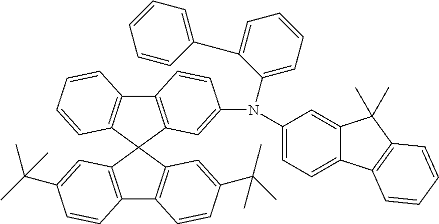 [SMILES: CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

SpMA7

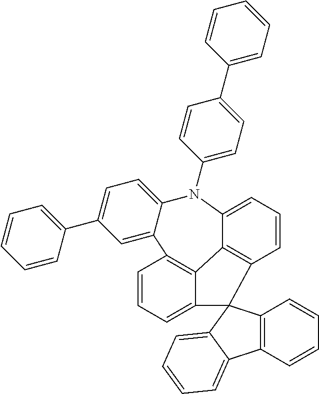 [SMILES: c1ccc(-c2ccc(N3c4ccc(-c5ccccc5)cc4-c4cccc5c4-c4c3cccc4C53c4ccccc4-c4ccccc43)cc2)cc1]

SpMA8

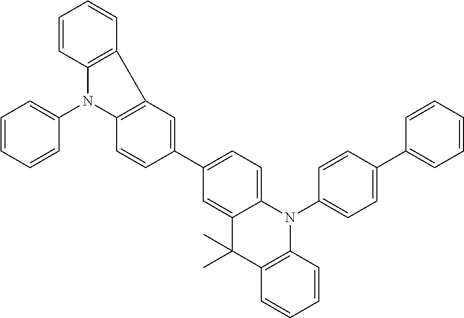 [SMILES: CC1(C)c2ccccc2N(c2ccc(-c3ccccc3)cc2)c2ccc(-c3ccc4c(c3)c3ccccc3n4-c3ccccc3)cc21]

CbzA1

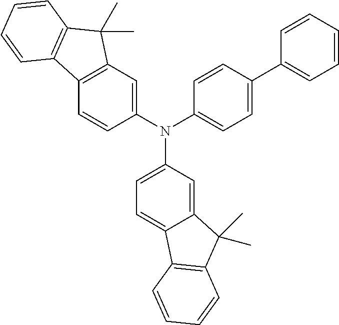 [SMILES: CC1(C)c2ccccc2-c2ccc(N(c3ccc(-c4ccccc4)cc3)c3ccc4c(c3)C(C)(C)c3ccccc3-4)cc21]

SpMA9

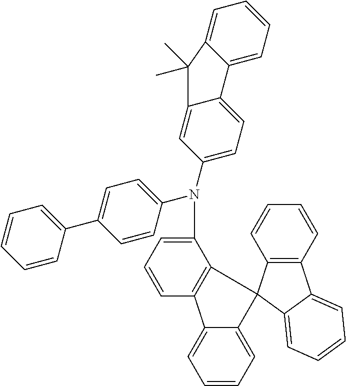 [SMILES: CC1(C)c2ccccc2-c2ccc(N(c3ccc(-c4ccccc4)cc3)c3cccc4c3C3(c5ccccc5-c5ccccc53)c3ccccc3-4)cc21]

SpMA10

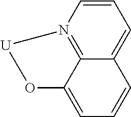

LiQ

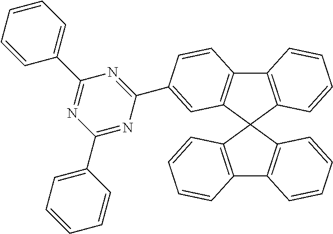 [SMILES: c1ccc(-c2nc(-c3ccccc3)nc(-c3ccc4c(c3)C3(c5ccccc5-c5ccccc53)c3ccccc3-4)n2)cc1]

ST1

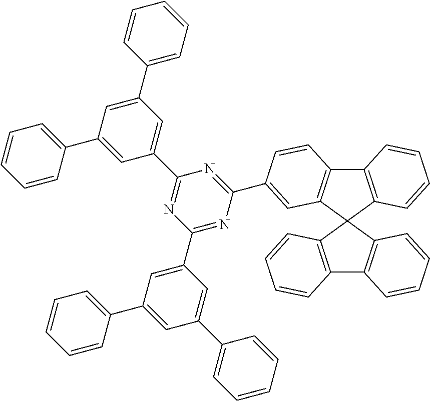 [SMILES: c1ccc(-c2cc(-c3ccccc3)cc(-c3nc(-c4cc(-c5ccccc5)cc(-c5ccccc5)c4)nc(-c4ccc5c(c4)C4(c6ccccc6-c6ccccc64)c4ccccc4-5)n3)c2)cc1]

ST2

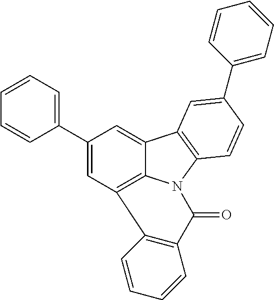 [SMILES: O=c1c2ccccc2c2cc(-c3ccccc3)cc3c4cc(-c5ccccc5)ccc4n1c23]

L1

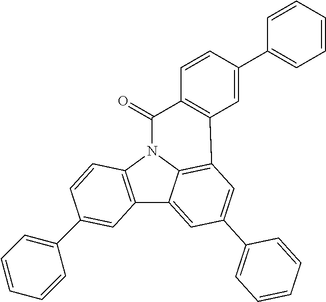 [SMILES: O=c1c2ccc(-c3ccccc3)cc2c2cc(-c3ccccc3)cc3c4cc(-c5ccccc5)ccc4n1c23]

L2

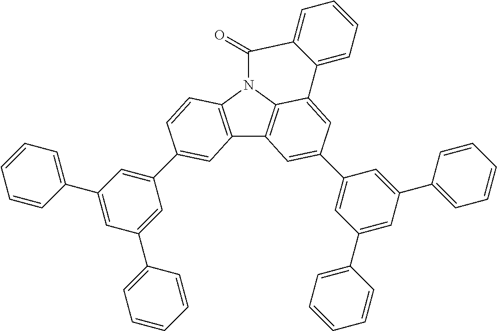 [SMILES: O=c1c2ccccc2c2cc(-c3cc(-c4ccccc4)cc(-c4ccccc4)c3)cc3c4cc(-c5cc(-c6ccccc6)cc(-c6ccccc6)c5)ccc4n1c23]

L3

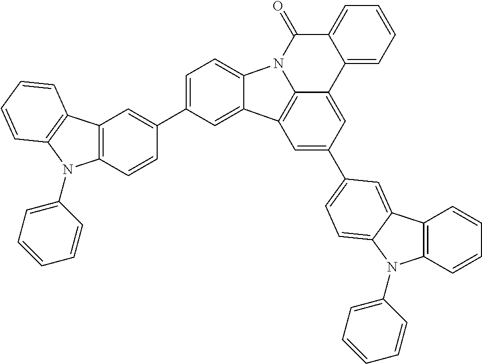 [SMILES: O=c1c2ccccc2c2cc(-c3ccc4c(c3)c3ccccc3n4-c3ccccc3)cc3c4cc(-c5ccc6c(c5)c5ccccc5n6-c5ccccc5)ccc4n1c23]

L4

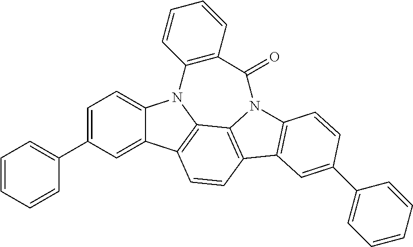 [SMILES: O=c1c2ccccc2n2c3ccc(-c4ccccc4)cc3c3ccc4c5cc(-c6ccccc6)ccc5n1c4c32]

L5

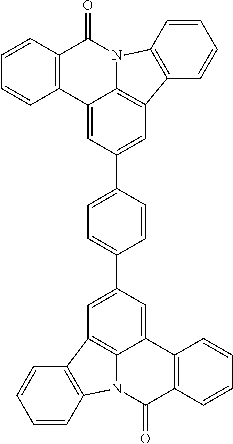 [SMILES: O=c1c2ccccc2c2cc(-c3ccc(-c4cc5c6ccccc6c(=O)n6c7ccccc7c(c4)c56)cc3)cc3c4ccccc4n1c23]

L6

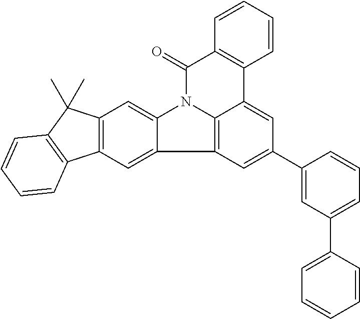 [SMILES: CC1(C)c2ccccc2-c2cc3c4cc(-c5cccc(-c6ccccc6)c5)cc5c6ccccc6c(=O)n(c3cc21)c54]

L7

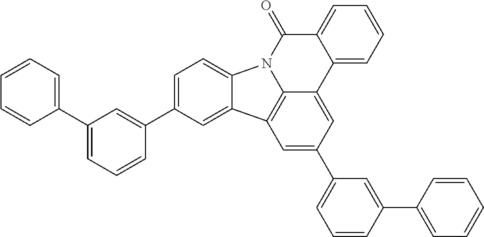 [SMILES: O=c1c2ccccc2c2cc(-c3cccc(-c4ccccc4)c3)cc3c4cc(-c5cccc(-c6ccccc6)c5)ccc4n1c23]

L8

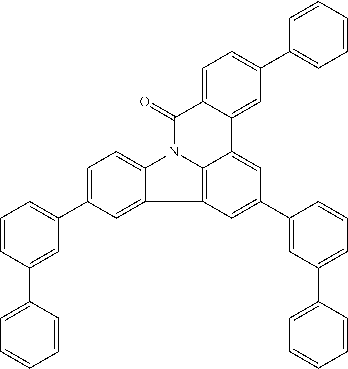 [SMILES: O=c1c2ccc(-c3ccccc3)cc2c2cc(-c3cccc(-c4ccccc4)c3)cc3c4cc(-c5cccc(-c6ccccc6)c5)ccc4n1c23]

L9

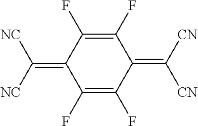 [SMILES: N#CC(C#N)=c1c(F)c(F)c(=C(C#N)C#N)c(F)c1F]

F4T

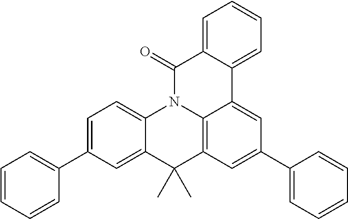 [SMILES: CC1(C)c2cc(-c3ccccc3)ccc2-n2c(=O)c3ccccc3c3cc(-c4ccccc4)cc1c32]

CRL1

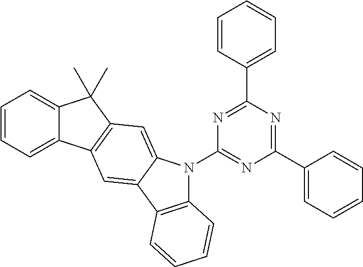 [SMILES: CC1(C)c2ccccc2-c2cc3c4ccccc4n(-c4nc(-c5ccccc5)nc(-c5ccccc5)n4)c3cc21]

IC1

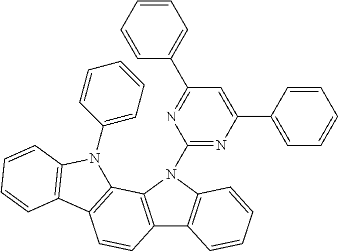 [SMILES: c1ccc(-c2cc(-c3ccccc3)nc(-n3c4ccccc4c4ccc5c6ccccc6n(-c6ccccc6)c5c43)n2)cc1]

IC2

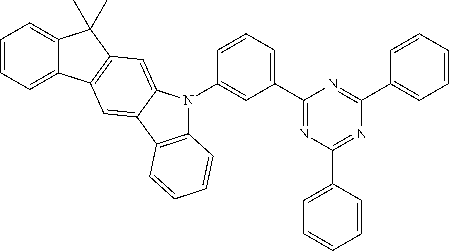 [SMILES: CC1(C)c2ccccc2-c2cc3c4ccccc4n(-c4cccc(-c5nc(-c6ccccc6)nc(-c6ccccc6)n5)c4)c3cc21]

IC3

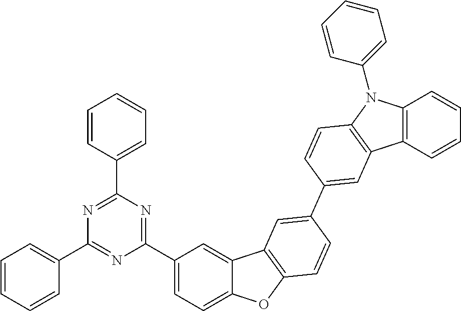 [SMILES: c1ccc(-c2nc(-c3ccccc3)nc(-c3ccc4oc5ccc(-c6ccc7c(c6)c6ccccc6n7-c6ccccc6)cc5c4c3)n2)cc1]

CbzT1

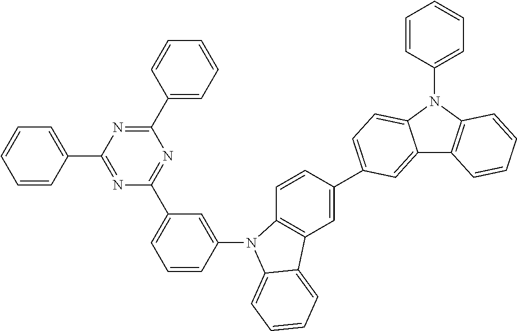 [SMILES: c1ccc(-c2nc(-c3ccccc3)nc(-c3cccc(-n4c5ccccc5c5cc(-c6ccc7c(c6)c6ccccc6n7-c6ccccc6)ccc54)c3)n2)cc1]

CbzT2

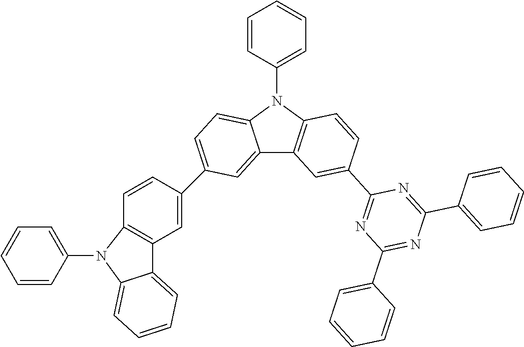 [SMILES: c1ccc(-c2nc(-c3ccccc3)nc(-c3ccc4c(c3)c3cc(-c5ccc6c(c5)c5ccccc5n6-c5ccccc5)ccc3n4-c3ccccc3)n2)cc1]

CbzT3

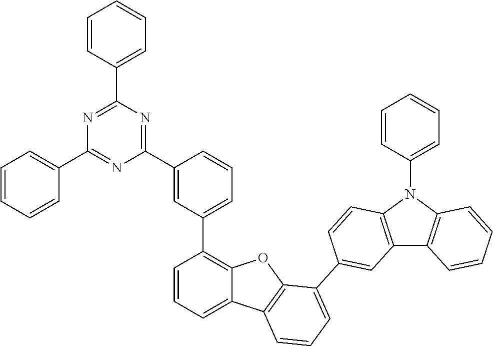 [SMILES: c1ccc(-c2nc(-c3ccccc3)nc(-c3cccc(-c4cccc5c4oc4c(-c6ccc7c(c6)c6ccccc6n7-c6ccccc6)cccc45)c3)n2)cc1]

CbzT4

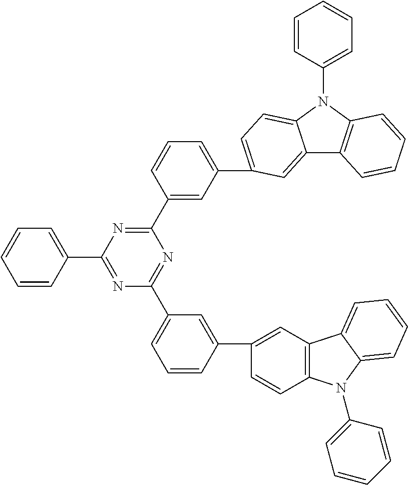 [SMILES: c1ccc(-c2nc(-c3cccc(-c4ccc5c(c4)c4ccccc4n5-c4ccccc4)c3)nc(-c3cccc(-c4ccc5c(c4)c4ccccc4n5-c4ccccc4)c3)n2)cc1]

CbzT5

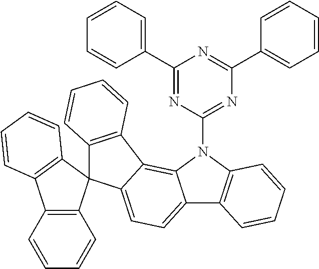 [SMILES: c1ccc(-c2nc(-c3ccccc3)nc(-n3c4ccccc4c4ccc5c(c43)-c3ccccc3C53c4ccccc4-c4ccccc43)n2)cc1]

IC4

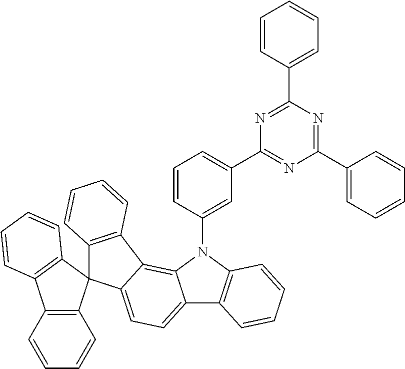 [SMILES: c1ccc(-c2nc(-c3ccccc3)nc(-c3cccc(-n4c5ccccc5c5ccc6c(c54)-c4ccccc4C64c5ccccc5-c5ccccc54)c3)n2)cc1]

IC5

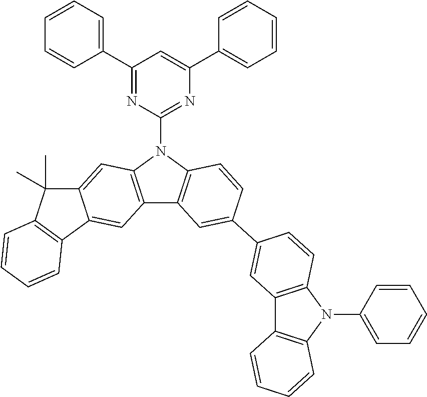 [SMILES: CC1(C)c2ccccc2-c2cc3c4cc(-c5ccc6c(c5)c5ccccc5n6-c5ccccc5)ccc4n(-c4nc(-c5ccccc5)cc(-c5ccccc5)n4)c3cc21]

IC6

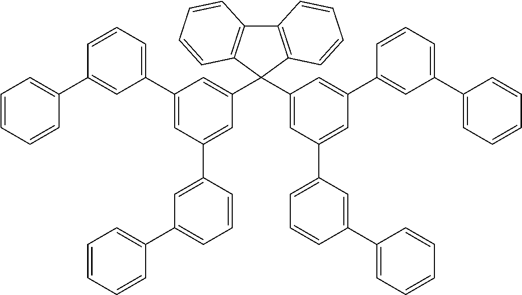 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1]

WB1

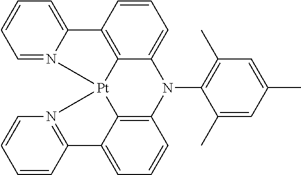

TER1

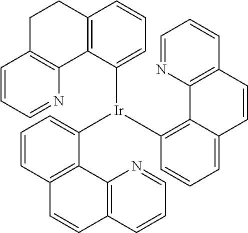

TEY1

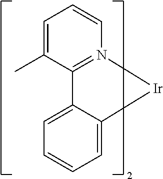

TEG1

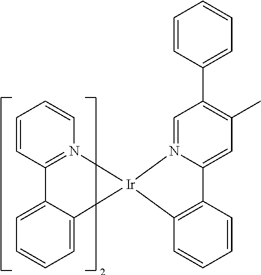

TEG2

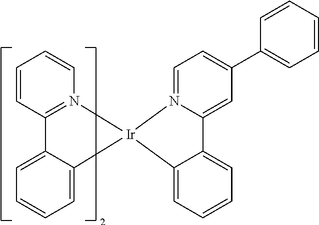

TEY2

TABLE 4
LUMO values

| Material | LUMO (eV) | T1 (eV) | Method |
|---|---|---|---|
| IC1 | −2.83 | 2.69 | org. |
| IC2 | −2.68 | 2.79 | org. |
| IC3 | −2.87 | 2.72 | org. |
| IC4 | −2.85 | 2.72 | org. |
| IC5 | −2.87 | 2.72 | org. |
| IC6 | −2.74 | 2.73 | org. |
| CRL1 | −2.59 | 2.71 | org, |
| CbzT1 | −2.76 | 2.84 | org. |
| CbzT2 | −2.85 | 2.72 | org. |
| CbzT3 | −2.68 | 2.80 | org. |
| CbzT4 | −2.76 | 2.83 | org. |
| CbzT5 | −2.73 | 2.90 | org. |
| WB1 | −2.24 | 2.95 | org. |
| LiQ | −2.30 | 1.81 | organomet. |
| TEG1 | −2.26 | 2.68 | organomet. |
| TEG2 | −2.31 | 2.71 | organomet. |
| TER1 | −2.64 | 2.03 | organomet. |
| TEY1 | −2.51 | 2.60 | organomet. |
| TEY2 | −2.52 | 2.57 | organomet. |
| L1 | −2.82 | 2.68 | org. |
| L7 | −2.80 | 2.58 | org. |
| L8 | −2.83 | 2.68 | org. |

1.-15. (canceled)

16. An organic electroluminescent device comprising cathode, anode and at least one layer which comprises the following compounds:
a) at least one electron-transporting compound which has an LUMO ≦−2.4 eV; and
b) at least one compound of the following formula (1) or (1a), 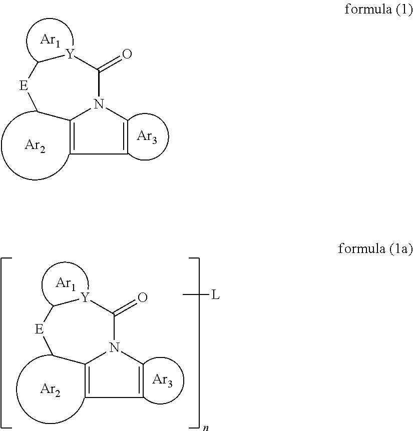
where the following applies to the symbols and indices used:
E is a single bond or NAr⁴;
Y is C if Ar¹ represents a 6-membered aryl ring group or 6-membered heteroaryl ring group or is C or N if Ar¹ represents a 5-membered heteroaryl ring group;
Ar¹ is, together with the group Y and the carbon atom explicitly depicted, an aromatic or heteroaromatic ring system having 5 to 30 aromatic ring atoms, which is optionally substituted by one or more radicals R;
Ar² and Ar³ are, identically or differently on each occurrence, together with the carbon atoms explicitly depicted, an aromatic or heteroaromatic ring system having 5 to 30 aromatic ring atoms, which is optionally substituted by one or more radicals R;
Ar⁴ is an aromatic or heteroaromatic ring system having 5 to 30 aromatic ring atoms, which is optionally substituted by one or more radicals R; Ar⁴ here may also be linked to Ar² or Ar¹ by a single bond;
L is, for n=2, a single bond or a divalent group, or, for n=3, a trivalent group or, for n=4, a tetravalent group, each of which is bonded to Ar¹, Ar², Ar³ or Ar⁴ at any desired position;
R is selected on each occurrence, identically or differently, from the group consisting of H, D, F, Cl, Br, I, CN, NO₂, N(Ar⁵)₂, N(R¹)₂, C(═O)Ar⁵, C(═O)R¹, P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R¹, where one or more non-adjacent CH₂ groups is optionally replaced by R¹C═CR¹, C≡C, Si(R¹)₂, Ge(R¹)₂, Sn(R¹)₂, C═O, C═S, C═Se, C═NR¹, P(═O)(R¹), SO, SO₂, NR¹, O, S or CONR¹ and where one or more H atoms is optionally replaced by D, F, Cl, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which is optionally substituted by one or more radicals R¹, or a combination of these systems, where two or more adjacent substituents R may optionally form a monocyclic or polycyclic, aliphatic, aromatic or heteroaromatic ring system, which is optionally substituted by one or more radicals R¹;
R¹ is selected on each occurrence, identically or differently, from the group consisting of H, D, F, Cl, Br, I, CN, NO₂, N(Ar³)₂, N(R²)₂, C(═O)Ar⁵, C(═O)R², P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which is optionally substituted by one or more radicals R², or a combination of these systems, where two or more adjacent substituents R may optionally form a monocyclic or polycyclic, aliphatic, aromatic or heteroaromatic ring system, which is optionally substituted by one or more radicals R²;
Ar⁵ is on each occurrence, identically or differently, an aromatic or heteroaromatic ring system having 5-30 aromatic ring atoms, which is optionally substituted by one or more non-aromatic radicals R²; two radicals Ar⁵ here which are bonded to the same N atom or P atom may also be bridged to one another by a single bond or a bridge selected from N(R²), C(R²)₂ or O;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms is optionally replaced by D, F, Cl, Br, I or CN, where two or more adjacent substituents R² may form a mono- or polycyclic, aliphatic, aromatic or heteroaromatic ring system with one another; and
n is 2, 3 or 4.

17. The organic electroluminescent device according to claim 16, wherein the layer which comprises the electron-transporting compound having an LUMO ≦−2.4 eV and the compound of the formula (1) or (1a) is an emitting layer, an electron-transport or electron-injection layer or a hole-blocking layer.

18. The organic electroluminescent device according to claim 16, wherein the ratio of the electron-transporting compound having an LUMO ≦−2.4 eV to the compound of the formula (1) or (1a) is between 10:90 and 90:10.

19. The organic electroluminescent device according to claim 16, wherein the ratio of the electron-transporting compound having an LUMO ≦−2.4 eV to the compound of the formula (1) or (1a) is between 40:60 and 60:40.

20. The organic electroluminescent device according to claim 16, wherein the group Ar¹ in compounds of the formula (1) or (1a) stands for a group of the formula (2), (3), (4), (5) or (6), 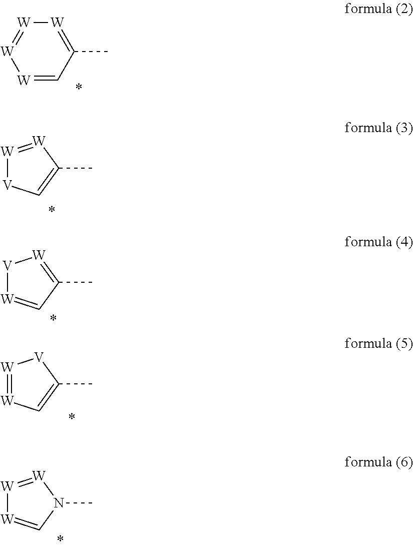
where the dashed bond indicates the link to the carbonyl group, * indicates the position of the link to E, and furthermore:
W is, identically or differently on each occurrence, CR or N; or two adjacent groups W stand for a group of the following formula (7) or (8), 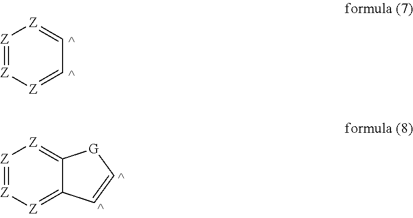
where G stands for CR₂, NR, O or S, Z stands, identically or differently on each occurrence, for CR or N, and ̂ indicates the corresponding adjacent groups W in the formulae (2) to (6);
V is NR, O or S;
and in that the group Ar² stands for a group of one of the formulae (9), (10) or (11), 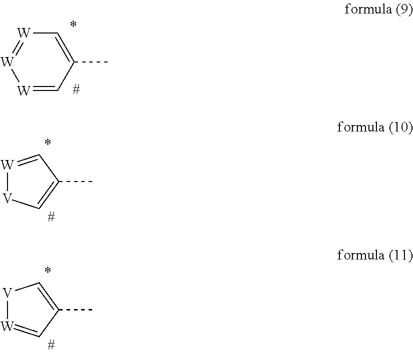
where the dashed bond indicates the link to N, # indicates the position of the link to Ar³, * indicates the link to E, and W and V have the meanings given above;
and in that the group Ar³ stands for a group of one of the formulae (12), (13), (14) or (15), 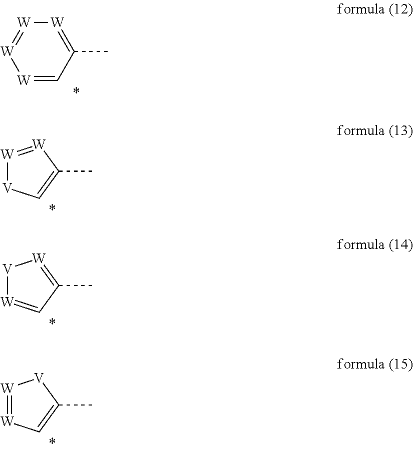
where the dashed bond indicates the link to N, * indicates the link to Ar², and W and V have the meanings given above.

21. The organic electroluminescent device according to claim 16, wherein the compound of the formula (1) is selected from the compounds of the formulae (16) to (32), 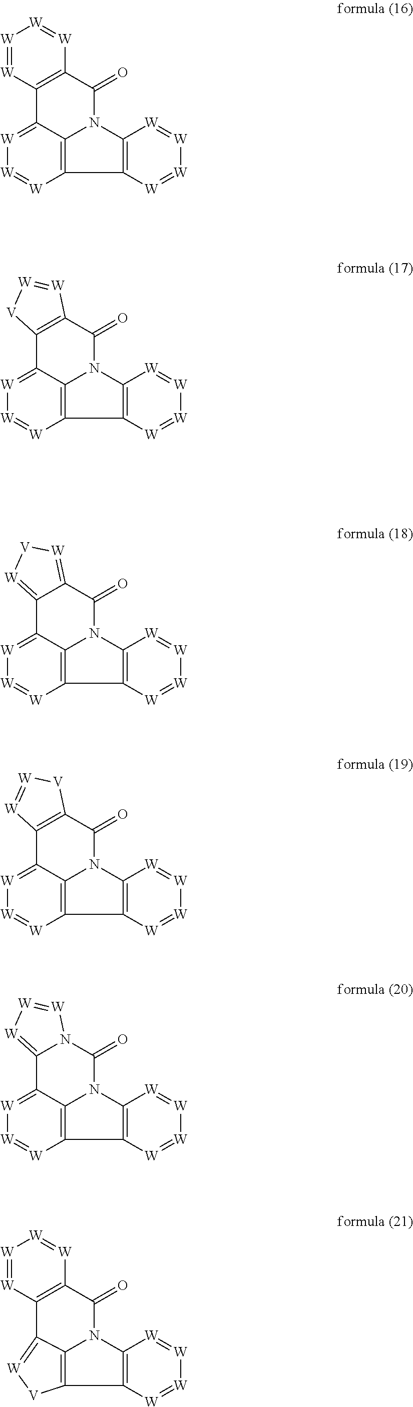 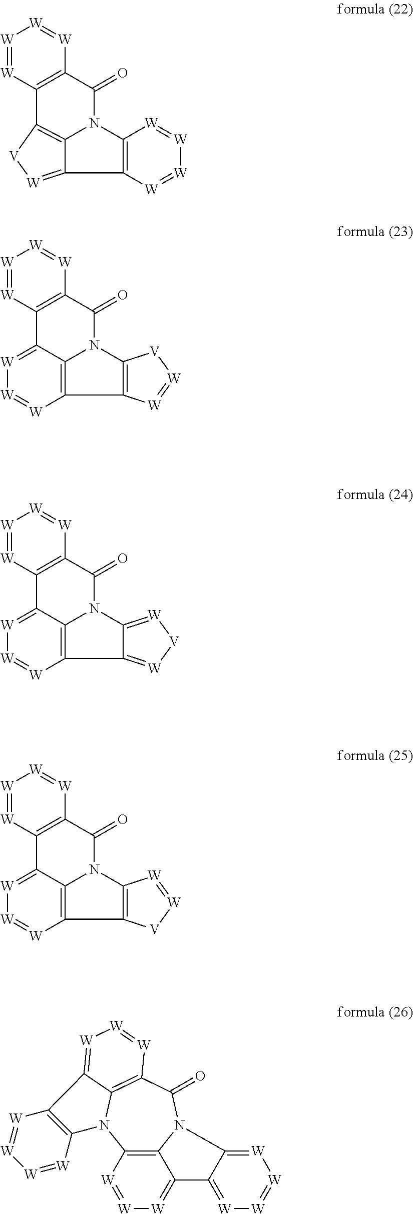 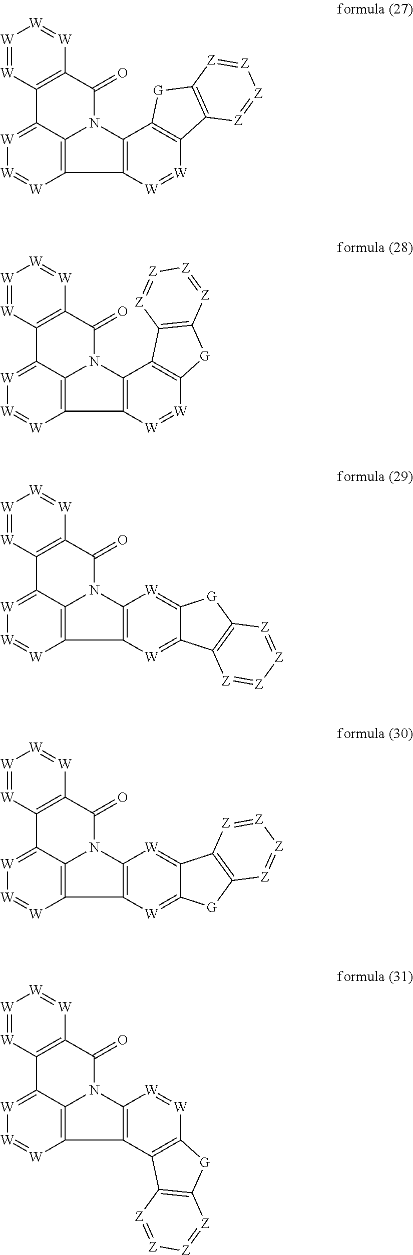 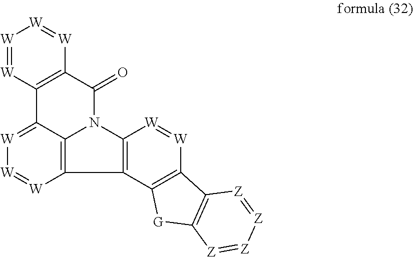
where the symbols used have the meanings given in claim 16.

22. The organic electroluminescent device according to claim 16, wherein the compound of the formula (1) is selected from the compounds of the formulae (16a) to (32a), 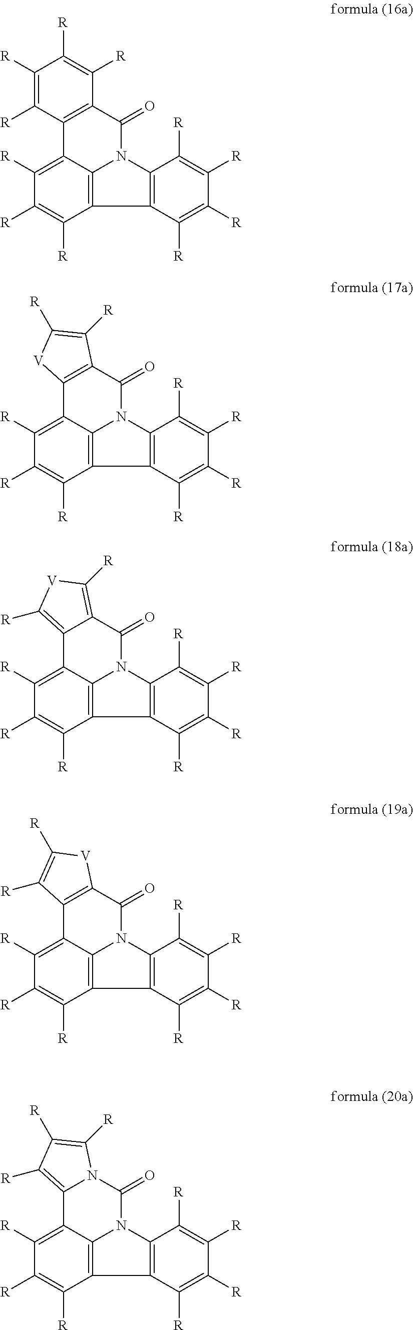 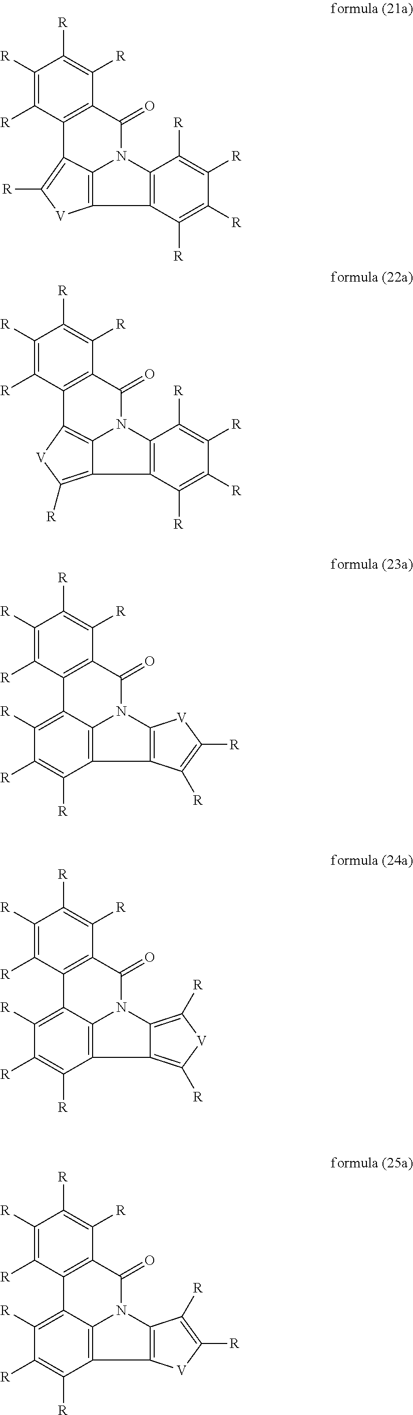 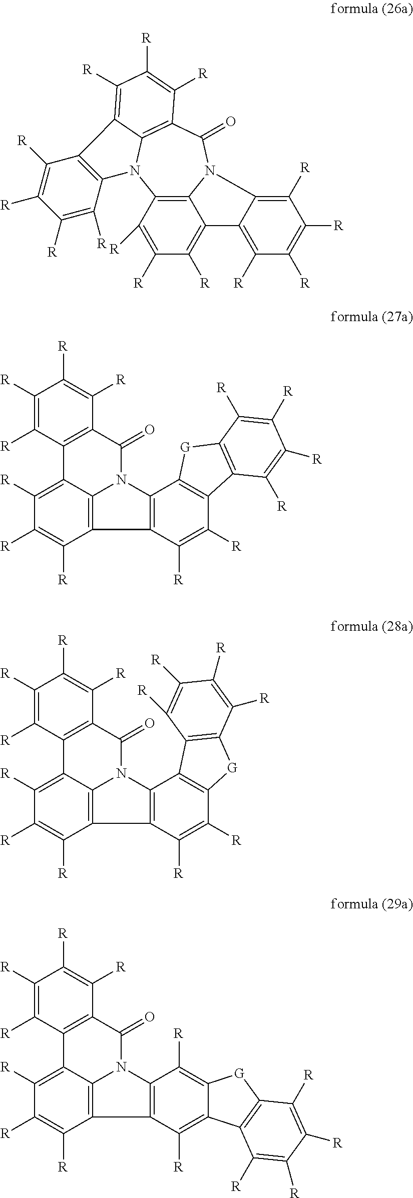 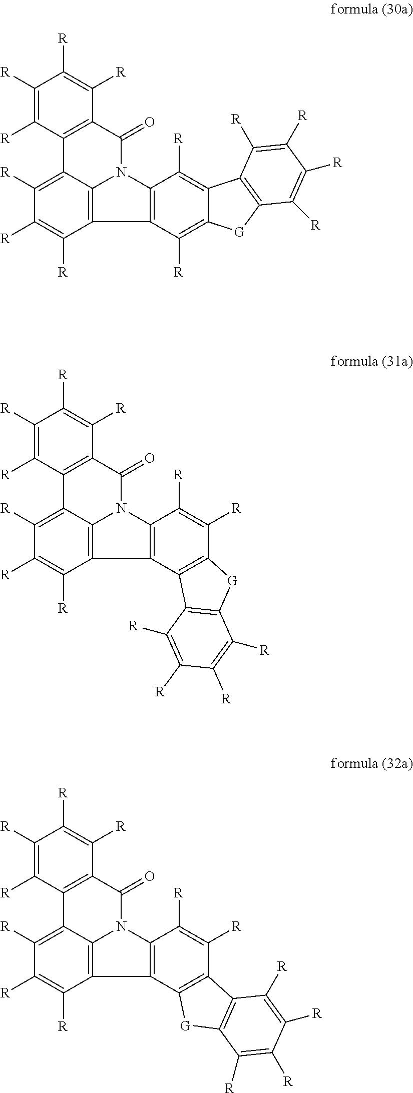
where the symbols used have the meanings given in claim 16.

23. The organic electroluminescent device according to claim 16, wherein the compound of the formula (1) is selected from the compounds of the formulae (16b) to (32b), 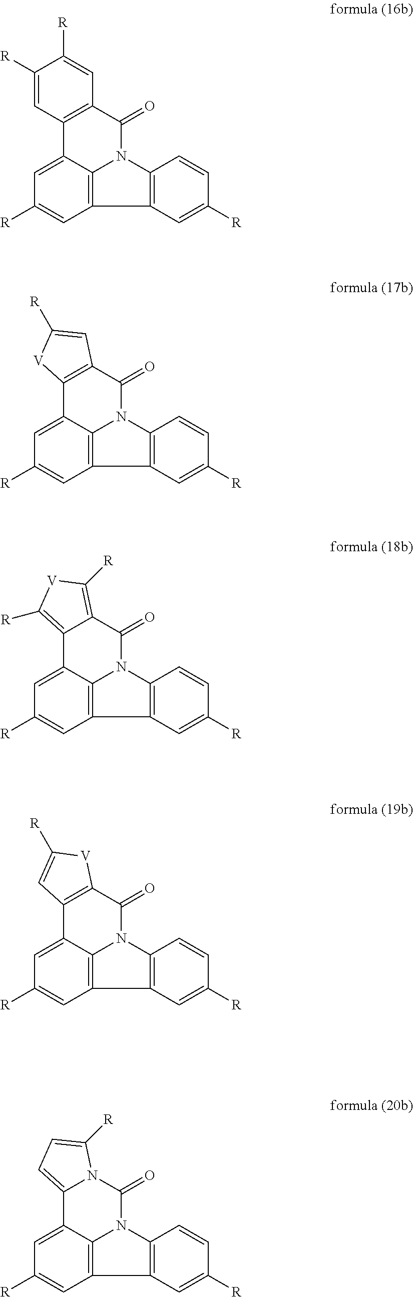 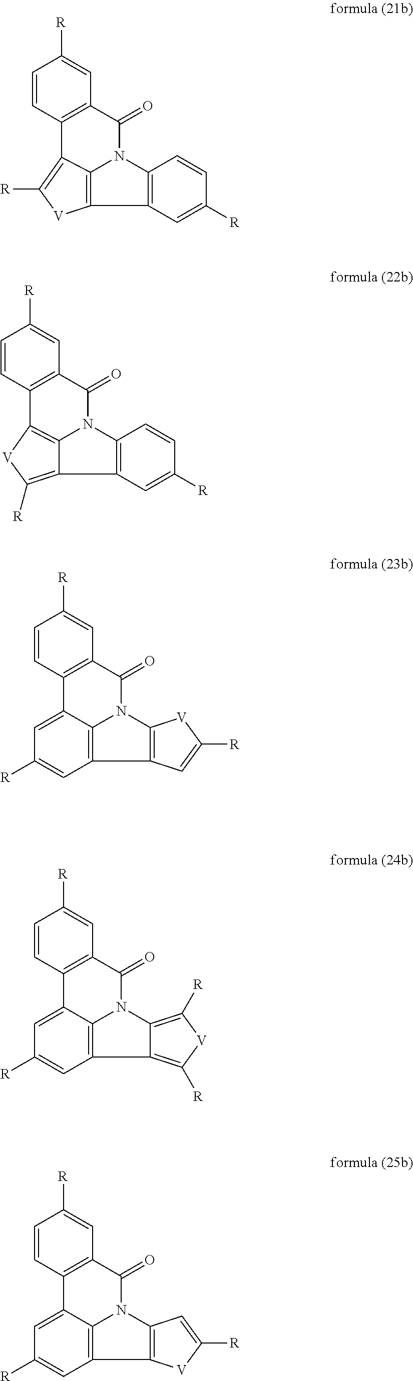 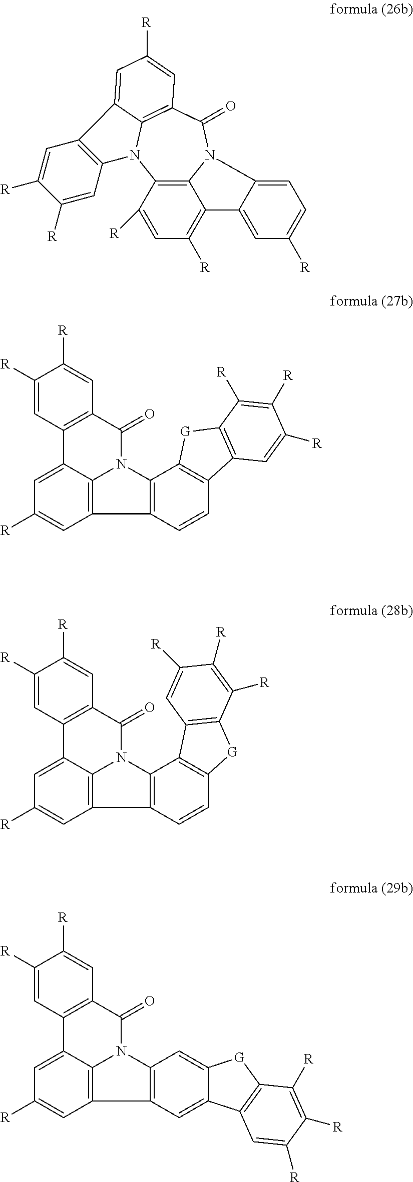 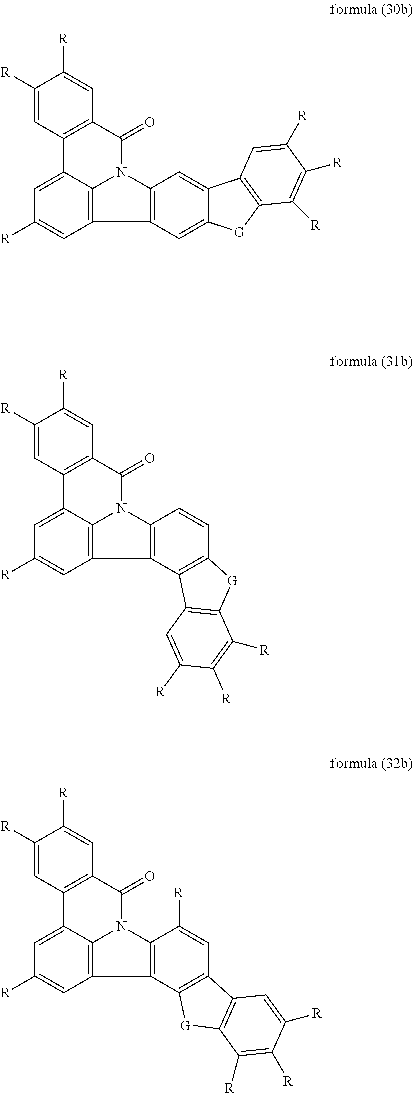
where the symbols used have the meanings given in claim 16.

24. The organic electroluminescent device according to claim 16, wherein the electron-transporting compound having an LUMO ≦−2.4 eV has an LUMO of ≦−2.5 eV.

25. The organic electroluminescent device according to claim 16, wherein the electron-transporting compound having an LUMO ≦−2.4 eV contains at least one lactam group, at least one triazine group of the formula (T-1) or at least one pyrimidine group of the formula (P-1), (P-2) or (P-3), 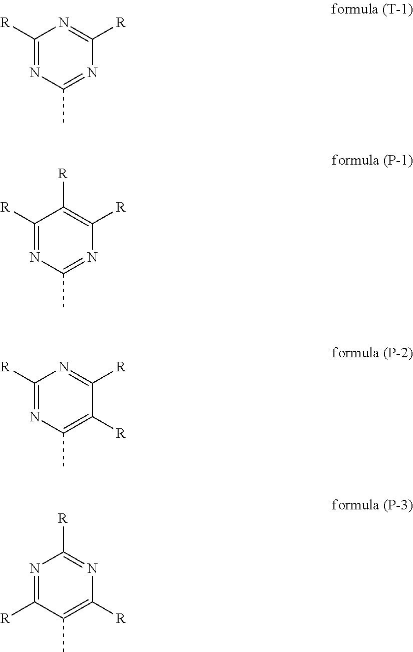
where
R is selected on each occurrence, identically or differently, from the group consisting of H, D, F, Cl, Br, I, CN, NO₂, N(Ar⁵)₂, N(R¹)₂, C(═O)Ar⁵, C(═O)R¹, P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R¹, where one or more non-adjacent CH₂ groups is optionally replaced by R¹C═CR¹, C♦C, Si(R¹)₂, Ge(R¹)₂, Sn(R¹)₂, C═O, C═S, C═Se, C═NR¹, P(═O)(R¹), SO, SO₂, NR¹, O, S or CONR¹ and where one or more H atoms is optionally replaced by D, F, Cl, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which is optionally substituted by one or more radicals R¹, or a combination of these systems, where two or more adjacent substituents R may optionally form a monocyclic or polycyclic, aliphatic, aromatic or heteroaromatic ring system, which is optionally substituted by one or more radicals R¹;
R¹ is selected on each occurrence, identically or differently, from the group consisting of H, D, F, Cl, Br, I, CN, NO₂, N(Ar⁵)₂, N(R²)₂, C(═O)Ar⁵, C(═O)R², P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which is optionally substituted by one or more radicals R², or a combination of these systems, where two or more adjacent substituents R may optionally form a monocyclic or polycyclic, aliphatic, aromatic or heteroaromatic ring system, which is optionally substituted by one or more radicals R²;
Ar⁵ is on each occurrence, identically or differently, an aromatic or heteroaromatic ring system having 5-30 aromatic ring atoms, which is optionally substituted by one or more non-aromatic radicals R²; two radicals Ar⁵ here which are bonded to the same N atom or P atom may also be bridged to one another by a single bond or a bridge selected from N(R²), C(R²)₂ or O;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms is optionally replaced by D, F, Cl, Br, I or CN, where two or more adjacent substituents R² may form a mono- or polycyclic, aliphatic, aromatic or heteroaromatic ring system with one another; and
the dashed bond represents the linking of this group.

26. The organic electroluminescent device according to claim 25, wherein the electron-transporting compound having an LUMO ≦−2.4 eV contains a triazine group of the formula (T-1) or a pyrimidine group of the formula (P-1), (P-2) or (P-3) which is bonded directly or via a bridging group to an indenocarbazole group, an indolocarbazole group or a carbazole group, where both the triazine or pyrimidine group and also the indenocarbazole or indolocarbazole or carbazole group is optionally substituted by one or more radicals R, and
R is selected on each occurrence, identically or differently, from the group consisting of H, D, F, Cl, Br, I, CN, NO₂, N(Ar⁵)₂, N(R¹)₂, C(═O)Ar⁵, C(═O)R¹, P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R¹, where one or more non-adjacent CH₂ groups is optionally replaced by R¹C═CR¹, C≡C, Si(R¹)₂, Ge(R¹)₂, Sn(R¹)₂, C═O, C═S, C═Se, C═NR¹, P(═O)(R¹), SO, SO₂, NR¹, O, S or CONR¹ and where one or more H atoms is optionally replaced by D, F, Cl, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which is optionally substituted by one or more radicals R¹, or a combination of these systems, where two or more adjacent substituents R may optionally form a monocyclic or polycyclic, aliphatic, aromatic or heteroaromatic ring system, which is optionally substituted by one or more radicals R¹;
R¹ is selected on each occurrence, identically or differently, from the group consisting of H, D, F, Cl, Br, I, CN, NO₂, N(Ar⁵)₂, N(R²)₂, C(═O)Ar⁵, C(═O)R², P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which is optionally substituted by one or more radicals R², or a combination of these systems, where two or more adjacent substituents R may optionally form a monocyclic or polycyclic, aliphatic, aromatic or heteroaromatic ring system, which is optionally substituted by one or more radicals R²;
Ar⁵ is on each occurrence, identically or differently, an aromatic or heteroaromatic ring system having 5-30 aromatic ring atoms, which is optionally substituted by one or more non-aromatic radicals R²; two radicals Ar⁵ here which are bonded to the same N atom or P atom may also be bridged to one another by a single bond or a bridge selected from N(R²), C(R²)₂ or O;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms is optionally replaced by D, F, Cl, Br, I or CN, where two or more adjacent substituents R² may form a mono- or polycyclic, aliphatic, aromatic or heteroaromatic ring system with one another.

27. The organic electroluminescent device according to claim 26, wherein the indenocarbazole group, the indolocarbazole group or the carbazole group is selected from the structures of the following formulae (indeno-1), (indeno-2), (indolo-1), (carb-1) and (spiro-1), 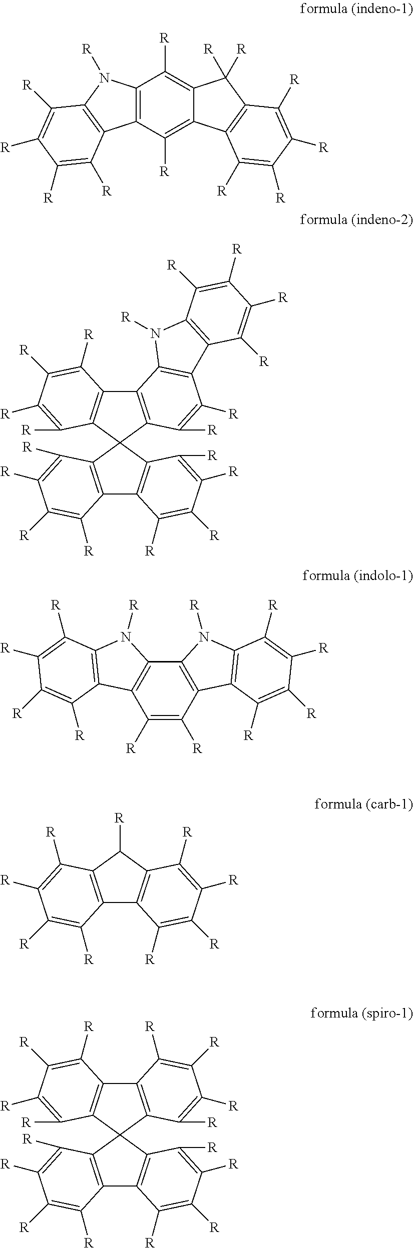
where
R is selected on each occurrence, identically or differently, from the group consisting of H, D, F, Cl, Br, I, CN, NO₂, N(Ar⁵)₂, N(R¹)₂, C(═O)Ar⁵, C(═O)R¹, P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R¹, where one or more non-adjacent CH₂ groups is optionally replaced by R¹C═CR¹, C≡C, Si(R¹)₂, Ge(R¹)₂, Sn(R¹)₂, C═O, C═S, C═Se, C═NR¹, P(═O)(R¹), SO, SO₂, NR¹, O, S or CONR¹ and where one or more H atoms is optionally replaced by D, F, Cl, Br, I, CN or NO₂, an aromatic or heteroaromatic ring system having 5 to 80, preferably 5 to 60, aromatic ring atoms, which may in each case be substituted by one or more radicals R¹, an aryloxy or heteroaryloxy group having 5 to 60 aromatic ring atoms, which is optionally substituted by one or more radicals R¹, or a combination of these systems, where two or more adjacent substituents R may optionally form a monocyclic or polycyclic, aliphatic, aromatic or heteroaromatic ring system, which is optionally substituted by one or more radicals R¹;
R¹ is selected on each occurrence, identically or differently, from the group consisting of H, D, F, Cl, Br, I, CN, NO₂, N(Ar⁵)₂, N(R²)₂, C(═O)Ar⁵, C(═O)R², P(═O)(Ar⁵)₂, a straight-chain alkyl, alkoxy or thioalkyl group having 1 to 40 C atoms or a branched or cyclic alkyl, alkoxy or thioalkyl group having 3 to 40 C atoms or an alkenyl or alkynyl group having 2 to 40 C atoms, each of which is optionally substituted by one or more radicals R², where one or more non-adjacent CH₂ groups is optionally replaced by R²C═CR², C≡C, Si(R²)₂, Ge(R²)₂, Sn(R²)₂, C═O, C═S, C═Se, C═NR², P(═O)(R²), SO, SO₂, NR², O, S or CONR² and where one or more H atoms is optionally replaced by D, F, Cl, Br, I, CN or NO₂, an aromatic or heteroaromatic ring system having 5 to 60 aromatic ring atoms, which may in each case be substituted by one or more radicals R², an aryloxy or heteroaryloxy group having 5 to 60 aromatic ring atoms, which is optionally substituted by one or more radicals R², or a combination of these systems, where two or more adjacent substituents R may optionally form a monocyclic or polycyclic, aliphatic, aromatic or heteroaromatic ring system, which is optionally substituted by one or more radicals R²;
Ar⁵ is on each occurrence, identically or differently, an aromatic or heteroaromatic ring system having 5-30 aromatic ring atoms, which is optionally substituted by one or more non-aromatic radicals R²; two radicals Ar⁵ here which are bonded to the same N atom or P atom may also be bridged to one another by a single bond or a bridge selected from N(R²), C(R²)₂ or O;
R² is selected from the group consisting of H, D, F, CN, an aliphatic hydrocarbon radical having 1 to 20 C atoms, an aromatic or heteroaromatic ring system having 5 to 30 aromatic ring atoms, in which one or more H atoms is optionally replaced by D, F, Cl, Br, I or CN, where two or more adjacent substituents R² may form a mono- or polycyclic, aliphatic, aromatic or heteroaromatic ring system with one another; and
instead of one of the radicals R, these groups have a bond to the pyrimidine or triazine group or to the bridging group, which is in turn bonded to the pyrimidine or triazine group.

28. The organic electroluminescent device according to claim 16, wherein the electron-transporting compound having an LUMO ≦−2.4 eV and the compound of the formula (1) or (1a) are employed in an emitting layer together with a phosphorescent compound, and in that the phosphorescent compound is a compound which contains iridium, platinum or copper.

29. A process for the production of the organic electroluminescent device according to claim 16, which comprises applying at least one layer by means of a sublimation process and/or in that at least one layer is applied by means of an OVPD (organic vapour phase deposition) process or with the aid of carrier-gas sublimation and/or in that at least one layer is applied from solution, by spin coating or by means of a printing process.

30. A mixture comprising
a) at least one electron-transporting compound which has an LUMO ≦−2.4 eV; and
b) at least one compound of the formula (1) or formula (1a) according to claim 16.

31. A formulation comprising a mixture according to claim 30 and at least one solvent.
